(19) United States
(12) Patent Application Publication
(10) Pub. No.: US 2024/0201296 A1
(43) Pub. Date: Jun. 20, 2024

(54) Magnetic Resonance Spectroscopy Frequency and Phase Correction

(71) Applicant: The Trustees of Columbia University in the City of New York, New York, NY (US)

(72) Inventors: Scott A. SMALL, New York, NY (US); Jia GUO, New York, NY (US)

(73) Assignees: The Trustees of Columbia University in the City of New York, New York, NY (US); The Research Foundation for Mental Hygiene, Inc., Menands, NY (US)

(21) Appl. No.: 18/481,551

(22) Filed: Oct. 5, 2023

Related U.S. Application Data
(63) Continuation of application No. PCT/US2022/025201, filed on Apr. 18, 2022.
(60) Provisional application No. 63/304,211, filed on Jan. 28, 2022.
(60) Provisional application No. 63/293,290, filed on Dec. 23, 2021.
(60) Provisional application No. 63/289,785, filed on Dec. 15, 2021.
(60) Provisional application No. 63/255,196, filed on Oct. 13, 2021.
(60) Provisional application No. 63/175,872, filed on Apr. 16, 2021.

(51) Int. Cl. G01R 33/46; G01R 33/485; G01R 33/56

(52) U.S. Cl. CPC G01R 33/4625; G01R 33/485; G01R 33/5608

(57) ABSTRACT

Methods for performing frequency and phase correction of magnetic resonance spectroscopy (MRS) data in quantifying one or more metabolites involved in the pathology of schizophrenia and related disorders.

### CROSS-REFERENCE TO RELATED APPLICATIONS

This is a continuation of International Patent Application No. PCT/US2022/025201 filed Apr. 18, 2022, which claims the benefit of U.S. Provisional Applications Nos. 63/175,872 filed Apr. 16, 2021, 63/255,196 filed Oct. 13, 2021, 63/289,785 filed Dec. 15, 2021, 63/293,290 filed Dec. 23, 2021, and 63/304,211 filed Jan. 28, 2022, each of which are hereby incorporated by reference in their entirety.

### STATEMENT REGARDING FEDERALLY SPONSORED RESEARCH OR DEVELOPMENT

This invention was made with government support under MH093398, awarded by the National Institutes of Health. The government has certain rights in the invention.

### TECHNICAL FIELD OF THE INVENTION

This disclosure generally relates to the fields of medicine, machine learning, and scan analysis for the detection and/or treatment of a medical condition.

### BACKGROUND OF THE INVENTION

Medical imaging and scanning technology has experienced progression over the years. Improvements in scan analysis have led to several medical breakthroughs, from the detection of mental disorders to the detection and treatment of brain cancer. For example, schizophrenia is a mental disorder that impacts the way people think, feel, and behave. Schizophrenia can have a major impact on patients' daily lives. While there has been progress on treating Schizophrenia, detection remains elusive, especially at early stages. Because early-stage treatment, prior to the development of serious complications, can positively impact outcomes, advances in Schizophrenia detection can have a significant positive impact on patient's lives. Innovations in brain scan analysis can serve this purpose and support several other advances in medicine.

### BRIEF SUMMARY OF THE INVENTION

The present disclosure relates to the detection of indicia of schizophrenia and other related disorders.

In one embodiment, a method, system, and/or computer readable medium is provided for performing frequency and phase correction of magnetic resonance spectroscopy (MRS) data to quantify one or more metabolites. Spectrum data related to a plurality of metabolites generated using magnetic resonance spectroscopy of a subject's brain can be received. Corrected on-spectrum data and corrected off-spectrum data can be generated by inputting the received spectrum data to a trained machine learning model, wherein the trained machine learning model estimates frequency corrections and phase corrections for the input spectrum data. One or more of the metabolites can be quantified according to the corrected on-spectrum data and corrected off-spectrum data.

In some embodiments, the trained machine learning model is a convolutional neural network with a plurality of convolutional layers. In some embodiments, the trained machine learning model is a dual stream convolutional neural network. In some embodiments, the dual stream convolutional neural network includes a first stream for frequency correction and a second stream for phase correction. In some embodiments, the first stream includes a plurality of convolutional layers and the second stream includes a plurality of convolutional layers. In some embodiments, the first stream is the same architecture as the second stream. In some embodiments, input to the first stream is magnitude spectrum data and input to the second stream is real spectrum data.

In some embodiments, the trained machine learning model is a transformer network with a plurality of multi-head attention blocks. In some embodiments, the trained machine learning model is an encoder that includes a multi-head attention block and a decoder that includes at least two multi-head attention blocks.

In some embodiments, the trained machine learning model is at least one of a convolutional neural network, a dual stream convolutional neural network, or a transformer network with a plurality of multi-head attention blocks.

In some embodiments, the received spectrum data includes on-spectrum data and off-spectrum data. In some embodiments, generating the corrected on-spectrum data and the corrected off-spectrum includes applying the estimated frequency corrections to the received on-spectrum data and the received off-spectrum data; and applying the estimated phase corrections to the received on-spectrum data and the received off-spectrum data. In some embodiments, the estimated frequency corrections are applied to the received on-spectrum data and the received off-spectrum data, and the estimated phase corrections are applied to the on-spectrum data and the off-spectrum data with the applied frequency corrections.

In some embodiments, the received spectrum data comprises single voxel MEGA-PRESS MRS data. In some embodiments, the quantified metabolite is quantified over at least a portion of the subject's brain. In some embodiments, the quantified metabolite is GABA, glutamate and/or glutamine. In some embodiments, a therapeutic agent is administered to the subject based on the quantified glutamate or glutamine, where the therapeutic agent reduces, decreases or inhibit glutamate or glutamine. In some embodiments, quantifying one or more of the metabolites according to the corrected on-spectrum data and corrected off-spectrum data includes calculating a difference between the off-spectrum data and the on-spectrum data.

In one embodiment, a method, system, and/or computer readable medium is provided for performing frequency and phase correction of magnetic resonance spectroscopy (MRS) data to quantify one or more metabolites. Spectrum data related to a plurality of metabolites generated using magnetic resonance spectroscopy of a subject's brain can be received. Corrected on-spectrum data and corrected off-spectrum data can be generated by inputting the received spectrum data to a trained machine learning model, wherein the trained machine learning model is a dual stream convolutional neural network that estimates frequency corrections and phase corrections for the input spectrum data. One or more of the metabolites can be quantified by calculating a difference between the off-spectrum data and the on-spectrum data.

In one embodiment, a method, system, and/or computer readable medium is provided for performing frequency and phase correction of magnetic resonance spectroscopy (MRS) data to quantify one or more metabolites. Spectrum data related to a plurality of metabolites generated using magnetic resonance spectroscopy of a subject's brain can be received. Corrected on-spectrum data and corrected off-spectrum data can be generated by inputting the received spectrum data to a trained machine learning model, where the trained machine learning model estimates frequency corrections and phase corrections for the input spectrum data. One or more of the metabolites can be quantified by calculating a difference between the off-spectrum data and the on-spectrum data, wherein the quantified metabolite comprises GABA, glutamate, or glutamine.

In one embodiment, a method, system, and/or computer readable medium is provided for detecting schizophrenia in a subject. At least one scan of a subject's brain can be received. The at least one scan can be processed to generate one or more processed scans. An approximate mapping of the subject's brain can be generated by inputting the processed scan into a first trained machine learning model. A schizophrenia prediction for the subject's brain can be generated, where the schizophrenia prediction can be generated by inputting the processed scan of the subject's brain and the approximate mapping of the subject's brain into a dual-stream trained machine learning model.

In some embodiments, the at least one scan is a three-dimensional image of the subject's brain. In some embodiments, the at least one scan is a plurality of two-dimensional image slices of the subject's brain. In some embodiments, the at least one scan is at least one magnetic resonance image scan of the subject's brain. In some embodiments, the at least one scan is a T1 weighted image scan of the subject's brain.

In some embodiments, the approximate mapping is an approximation of a functional mapping of the subject's brain. In some embodiments, the approximate mapping is an artificial cerebral blood volume mapping. In some embodiments, the approximate mapping is a three-dimensional image. In some embodiments, the approximate mapping is a voxel level approximation of cerebral blood volume.

In some embodiments, the first trained machine learning model is a convolutional neural network with an encoding path that includes a plurality of convolution blocks and a decoding path that includes a plurality of convolution blocks.

In some embodiments, processing the at least one scan to generate one or more processed scans includes: generating a first registration by registering the at least one scan of the subject's brain to a first template, where the first registration is input to the first trained machine learning model to generate the approximate mapping of the subject's brain; and generating a second registration by registering the at least one scan of the subject's brain to a second template, where the second registration is input to the dual-stream trained machine learning model to generate the schizophrenia prediction for the subject's brain.

In some embodiments, the dual-stream trained machine learning model includes a first stream of convolutional blocks for the processed scan of the subject's brain and as second stream of convolutional blocks for the approximate mapping of the subject's brain. In some embodiments, the first stream has an identical architecture to the second stream. In some embodiments, a convolution block includes a convolution, a batch normalization, and a squeeze and excitation operation. In some embodiments, the squeeze and excitation operation scales data channels after the convolution and batch normalization. In some embodiments, a convolution block includes a 3D convolution, a 3D batch normalization, a 3D max pooling, and a 3D squeeze and excitation operation.

In some embodiments, the output from the first stream and the second stream are concatenated and input into one or more fully connected layers. In some embodiments, the output from the fully connected layers is the schizophrenia prediction. In some embodiments, the output from the first stream and the second stream are concatenated and input into the one or more fully connected layers. In some embodiments, the output from the first stream and the second stream are combined using one or more weights learned by the dual-stream trained machine learning model during training.

In some embodiments, the schizophrenia prediction is a score indicative of the probability that the subject has schizophrenia.

In one embodiment, a method, system, and/or computer readable medium is provided for detecting schizophrenia in a subject. At least one three-dimensional scan of a subject's brain can be received. The at least one three-dimensional scan can be processed to generate one or more processed scans. An approximate three-dimensional mapping of the subject's brain can be generated by inputting the processed scan into a first trained machine learning model. A schizophrenia prediction for the subject's brain can be generated, where the schizophrenia prediction can be generated by inputting the processed scan of the subject's brain and the approximate mapping of the subject's brain into a dual-stream trained machine learning model.

In one embodiment, a method, system, and/or computer readable medium is provided for detecting schizophrenia in a subject. At least one scan of a subject's brain can be received, where the at least one scan is a T1 weighted image scan of the subject's brain. The at least one scan can be processed to generate one or more processed scans. An artificial cerebral blood volume mapping of the subject's brain can be generated by inputting the processed scan into a first trained machine learning model. A schizophrenia prediction for the subject's brain can be generated, where the schizophrenia prediction can be generated by inputting the processed scan of the subject's brain and the artificial cerebral blood volume mapping of the subject's brain into a dual-stream trained machine learning model.

The foregoing is a summary and thus contains, by necessity, simplifications, generalizations, and omissions of detail; consequently, those skilled in the art will appreciate that the summary is illustrative only and is not intended to be in any way limiting. Other aspects, features, and advantages of the methods, compositions and/or devices and/or other subject matter described herein will become apparent in the teachings set forth herein. The summary is provided to introduce a selection of concepts in a simplified form that are further described below in the Detailed Description of the Invention. This summary is not intended to identify key features or essential features of the claimed subject matter, nor is it intended to be used as an aid in determining the scope of the claimed subject matter.

### BRIEF DESCRIPTION OF THE SEVERAL VIEWS OF THE DRAWINGS

For illustrative purposes, there are depicted in drawings certain embodiments. However, the disclosure is not limited to the precise arrangements and instrumentalities of the embodiments depicted in the drawings.

FIGS. 1A-1C illustrate imaging of the three hippocampal pathophysiologies. FIG. 1A shows the results of a magnetic resonance spectroscopy measured hippocampal glutamate/glutamine (GLX). The voxel placed over the left hippocampus (indicated in red) is shown in sagittal (left upper image) and coronal (right upper image) scans. An example of the spectra is shown; the amplitude of GLX (left spectra), choline (Cho) (right spectra), and creatine (Cr) (right spectra) was measured post-acquisition. FIG. 1B shows image structural magnetic resonance imaging measured volume of the CA1 and other hippocampal regions. As shown in the example of a single subject, FreeSurfer was used post-acquisition to measure the volume of the CA1 region, the CA3 region, the dentate gyrus (DG), and the subiculum (Sub). FIG. 1C shows a functional magnetic resonance imaging cerebral blood volume estimates basal metabolism. The automated template is shown, which was used to measure CA1 cerebral blood volume and cerebral blood volume in other hippocampal regions.

FIGS. 2A-2C illustrate a hippocampal pathophysiology of clinical high-risk patients vs. control subjects. FIG. 2A is a graph showing that compared with control subjects, patients were found to have dominant elevations of glutamate/glutamine (GLX) (left graph) as well as elevations in CA1 cerebral blood volume (CBV) (middle graph). No difference was found for CA1 volume (right graph). Bars indicate standard error of the mean. FIGS. 2B and 2C are spectra of a patient (red) and control subject (blue) illustrating GLX elevation in patients and no difference in choline (FIG. 2B) and creatine (FIG. 2C). * p<0.05; **p<0.01. a.u., arbitrary units; ICV, intracranial volume.

FIGS. 3A-3C illustrate focal hippocampal volume differences in prodromal psychosis. FIG. 3A are example images illustrating the rendered (using PARAVIEW® 5.3.0 using default parameters) CA1 volume of patient who converted to psychosis at follow-up (left panel) with lower CA1 volume at baseline compared with a patient who did not convert (right panel). FIG. 3B is a graph of adjusted probabilities and 95% confidence intervals from Cox proportional hazards model (controlling for age and sex) of remaining a nonconverter from time of baseline scan (in days) for subjects with highest (blue line) and lowest (red line) baseline CA1 volume. FIG. 3C are graphs of mean values of cerebral blood volume (CBV) (left graph) and CA1 volume (right graph) of control subjects, converters, and nonconverters. Bars indicate standard error of the mean. ICV, intracranial volume.

FIG. 4 shows that hippocampal glutamate characterizes an attenuated psychosis disorder. Box plots illustrate the distribution of hippocampal glutamate/glutamine (GLX) in converters, nonconverters, and control subjects (box outlines the first quartile to the third quartile [25%-75%], the line in the box is the median, and the diamond in the box is the mean). Compared with control subjects, both converters and nonconverters were found to have a significant elevation in GLX. Applying an upper cutoff based on control subjects, 61% of nonconverters had elevations in GLX. CHR, clinical high risk.

FIG. 5 illustrates a network structure of a CNN model (left) with description of the implemented model for each layer (right). Both the frequency and phase offset were predicted using the same architecture where 2 hidden convolutional layers, 2 max pooling layers and 3 fully-connected layers. Hidden layers were each followed by a rectified linear unit (ReLU) activation function and the output fully connected layer by a linear activation function that generated the predicted offset. Simulated spectra manipulated from FID-A with frequency or phase offsets were used as training data for the network. Each network was trained through 300 epochs with early stopping if the following 40 epochs does not improve than the lowest validation loss.

FIG. 6 illustrates the network structure of a Transformer model. Both the frequency and phase offset were predicted using a same architecture with one input linear layer, one encoder composed of one multi-head attention block and one feed-forward block, one decoder composed of two multi-head attention blocks and one feed-forward block, and three fully connected layers with 1024, 512 and 1 node respectively. The two hidden layers were followed by a rectified linear unit activation. The fully connected output layer generated the predicted offset. Simulated spectra manipulated from FID-A with frequency or phase offsets were used as training data for both networks. Each network was trained through 500 epochs.

FIGS. 7A-7D illustrate the results of visualizing the performance of the MLP-based approach (FIG. 7A) and the proposed CNN-based approach (FIG. 7B) for frequency and phase correction of the “Off Spectra” using the published simulated dataset. The scatter plots in the top panel show the correction errors between the ground truths and model predictions at different frequency and phase offsets. The CNN model has smaller correction errors (i.e., smaller mean absolute error and standard deviation) for both frequency and phase offset estimation compared to the MLP-based approach. The spectra below the scatter plots demonstrate the deep learning (DL) model predictions and the ground truth of the MEGA-PRESS “Diff Spectra”. When visualizing the results generated from a single transient “Diff Spectra” example, it is clear that the deep learning model has smaller residues (i.e., the difference between the model prediction and the ground truth) highlighted in the dotted blue boxes. (FIG. 7C) Zoom in view of the residues between the ground truths and the MLP model prediction. (FIG. 7D) Zoom in view of the residues between the ground truths and the CNN model prediction.

FIGS. 8A-8B illustrate the comparison between the MLP-based approach and the proposed CNN-based approach for frequency and phase correction of the “On Spectra”. (FIG. 8A) Bar graph showing the frequency estimation error (in Hz) of the MLP-based method and the proposed method at varying SNRs. (FIG. 8B) Bar graph showing the phase estimation error (in Degree) of the MLP-based method and the proposed method at varying SNRs.

FIGS. 9A-9B illustrate the comparison between the MLP-based approach and the proposed CNN-based approach for frequency and phase correction of the “Off Spectra”. (FIG. 9A) Bar graph showing the frequency estimation error (in Hz) of the MLP-based method and the proposed method at varying SNRs. (FIG. 9B) Bar graph showing the phase estimation error (in Degree) of the MLP-based method and the proposed method at varying SNRs.

FIGS. 10A-10C illustrate a comparison between the MLP-based approach and the proposed CNN-based approach for frequency and phase correction of both the “On Spectra” and the “Off Spectra”. (FIG. 10A) Bar graph showing the mean absolute error between the corrected “On Spectra” and the ground truth of the MLP-based method and the proposed method at varying SNRs. (FIG. 10B) Bar graph showing the mean absolute error between the corrected “Off Spectra” and the ground truth of the MLP-based method and the proposed method at varying SNRs. (FIG. 10C) Bar graph showing the mean absolute error between the corrected “Diff Spectra” (i.e., Diff Spectra=On Spectra−Off Spectra) and the ground truth of the MLP-based method and the proposed method at varying SNRs. FIGS. 1-10 relate to Examples 1-8 described hereinbelow.

FIGS. 11A-11B illustrate a network structure, the pipeline for assessment and sample outputs of embodiments of a proposed deep learning model. (FIG. 11A) The network architecture of the CNN model. Both the frequency and phase offset were predicted with separate models where the input for the F-model was the magnitude spectrum and the input for the P-model was the real spectrum. Both models have the same architecture of 2 hidden 1D convolutional layers, 2 1D max-pooling layers, and 3 fully connected layers. The convolutional layer included 4 kernels with a size of 3, and the max-pooling layer had a pool size of 2 with a stride of. Furthermore, two fully-connected layers (FC) with 1024 and 512 nodes respectively followed by a final fully-connected linear output layer of 1 node, were implemented. All hidden layers were each followed by a rectified linear unit (ReLU) activation function and the output fully connected layer by a linear activation function that generated the predicted offset. Simulated spectra manipulated from FID-A with artificially generated frequency or phase offsets were used as training data for the network (F-model and P-model). Each network was trained through 300 epochs with early stopping implemented when 40 consecutive epochs did not improve the lowest validation loss. (FIG. 11B) Flow chart of computation to determine the Diff spectra with details of the input and output from the network architecture.

FIGS. 12A-12H illustrate a visualization of the performance of the MLP-based approach and the proposed CNN-based approach for frequency and phase correction using the published simulated dataset for varying SNRs. The scatter plots show the correction errors between the ground truths and model predictions at different frequency and phase offsets. The spectra below the scatter plots demonstrate the deep learning model predictions (MLP or CNN), the true MEGA-PRESS difference spectrum, and the subtraction of the MLP/CNN and true difference spectrum (Single Diff Spectra). (FIG. 12A) Output of MLP-based approach on the original test set (SNR of 20). (FIG. 12B) Output of MLP-based approach on the test set with SNR of 10. (FIG. 12C) Output of MLP-based approach on the test set with SNR of 5. (FIG. 12D) Output of MLP-based approach on the test set with SNR of 2.5. (FIG. 12E) Output of the CNN-based approach on the original test set. (FIG. 12F) Output of the CNN-based approach on the test set with SNR of 10. (FIG. 12G) Output of the CNN-based approach on the test set with SNR of 5. (FIG. 12H) Output of the CNN-based approach on the test set with SNR of 2.5.

FIGS. 13A-13I illustrate a comparison between the MLP-based approach and the proposed CNN model for frequency-and-phase correction of both the Off spectra and On spectra at varying SNRs. (FIG. 13A) Bar graph showing the frequency estimation error (in Hz) of the MLP-based model and the CNN model at varying SNRs of the On spectra. (FIG. 13B) Bar graph showing the phase estimation error (in degrees) of the MLP-based model and the CNN model at varying SNRs of the On spectra. (FIG. 13C) Bar graph showing the frequency estimation error (in Hz) of the MLP-based model and the CNN model at varying SNRs of the Off spectra. (FIG. 13D) Bar graph showing the phase estimation error (in degrees) of the MLP-based model and the CNN model at varying SNRs of the Off spectra. (FIG. 13E) Bar graph showing the GABA residual spectra mean absolute error of the MLP-based model and the CNN model of the difference spectra. (FIG. 13F) Bar graph showing the Glx residual spectra mean absolute error of the MLP-based model and the CNN model of the difference spectra. (FIG. 13G) Bar graph showing the residual spectra mean absolute error of the MLP-based model and the CNN model of the On spectra. (FIG. 13H) Bar graph showing the residual spectra mean absolute error of the MLP-based model and the CNN model of the Off spectra. (FIG. 13I) Bar graph showing the residual spectra mean absolute error of the MLP-based model and the CNN model of the difference spectra. The two-tailed p-value was used and is less than 0.0001**** for the comparisons between the MLP-based approach and the CNN model.

FIGS. 14A-14D illustrate diff spectra and performance scores comparing the MLP-based approach to SR, the CNN approach to SR and the CNN approach to the MLP-based approach for the 33 in vivo datasets. The Diff spectra were generated without any FPC (Original), using the network shown in FIG. 11 (MLP-based approach and the CNN approach) and using SR (spectral registration). (FIG. 14A) Results of applying corrections to the in vivo data without further manipulation, and with additional frequency and phase offsets applied to the same 33 datasets: small offsets (0-5 Hz; 0-20°), medium offsets (5-10 Hz; 20-45°), and large offsets (10-20 Hz; 45-90°). (FIG. 14B) Comparative performance scores P and Q for the MLP-based approach and SR for each dataset. A score above 0.5 indicated that the MLP-based approach performed better than SR, whereas a score below 0.5 (50%) indicated that SR performed better than the MLP-based approach in terms of alignment. (FIG. 14C) Comparative performance scores P and Q for the CNN approach and SR for each dataset. (FIG. 14D) Comparative performance scores P and Q for the CNN approach and the MLP-based approach for each dataset.

FIGS. 15A-15C illustrate P score and Q score analysis using tables and heat map. (FIG. 15A) Table of the P score percentages and the average Q scores comparing the MLP-based approach to SR, the CNN approach to SR and the CNN approach to the MLP-based approach with no additional offsets and three magnitudes of additional offsets (C1. 0≤|Δf|≤5 Hz and 0°≤|Δϕ|≤20°; C2. 5≤|Δf≤10 Hz and 20°≤|Δϕ|≤45°; C3. 10≤|Δf≤|20 Hz and 45°≤|Δϕ|≤90°). Quantification method comparison heat map for (FIG. 15B) P scores and (FIG. 15C) Q scores, where each cell is the result of the vertical method vs the horizontal method.

FIG. 16 illustrates a table of MLP and CNN Mean Absolute Errors. Table of mean absolute errors of the MLP-based approach and the proposed CNN approach for frequency and phase correction of the On spectra and Off spectra, of the resulting On and Off spectra, and of the corresponding Diff spectra at varying SNRs. FIGS. 11-16 relate to Examples 9-12 set forth hereinbelow.

FIGS. 17A-17B illustrate sample characteristics, distribution of public schizophrenia MRI datasets and a preprocessing pipeline. (FIG. 17A). Scan parameters of the T1W MR data and the patient demographic information of each dataset. In BrainGluSchi, COBRE, NMorphCH dataset, normal scans included whole head structural TIW MR images obtained from healthy control subjects and schizophrenia scans included whole head structural T1W MR images obtained from schizophrenia and schizoaffective disorder patients. In the Columbia CHR dataset, the patients' scans included structural TIW MR images obtained from subjects in clinical high risk of schizophrenia separately in first-year scanning and follow-up scanning. CHR stable: subjects with high risk of schizophrenia do not progress to schizophrenia. CHR converted: subjects with high risk of schizophrenia do progress to schizophrenia. (FIG. 17B). Data preprocessing pipeline to generate the input of different schizophrenia classification deep learning models. The preprocessing of structural TIW MR data can remove unwanted artifacts and transform the data into a standard format before training a deep learning model. For each MRI structural MRI, the T1W 3D volume is processed through a standardized pipeline that includes of seven steps: (1) whole head TIW affine registration to the MNI152 template space; (2) skull stripping; (3) whole brain affine registration to the MNI152 template space; (4) whole brain affine registration to the DeepContrast CU TIW MRI template space; (5) histogram matching to the DeepContrast CU TIW MRI; (6) generating the artificial CBV (aCBV) maps; (7) up-sampling the aCBV maps to 1 mm isotropic resolution. VS: voxel size.

FIGS. 18A-18C illustrate architectures of deep learning models. (FIG. 18A). Proposed model 1 modified 3D VGG-11 network with squeeze-and-excitation (SE) block and batch-normalization (SE-VGG-11BN) that uses TIW MRI as the model input. The class of one given TIW scan is predicted by two steps in the model: 1) extracting hierarchical features; 2) classifying these features. In the feature extractor part, the data is firstly under-sampled ×2 and goes through several convolution blocks including 3D convolution, 3D batch normalization, 3D max pooling and 3D SE operation. The classifier includes several dense layers that could yield the final prediction result. (FIG. 18B). The architecture of the DeepContrast model. Pre-trained DeepContrast model is used to generate a synthesized artificial CBV (aCBV) maps from T1W scans. (FIG. 18C). Proposed model 2 modified SE-VGG-11BN network with double encoding streams (dual stream SE-VGG-11BN) uses both TIW MRI data and the aCBV maps as the model input. Separate streams in the dual stream SE-VGG-11BN network have the same layer structure. The class of one given TIW scan and aCBV map is predicted by two steps in the model: 1) extracting hierarchical features; 2) fusing features and classifying these features. In the feature extractor part (either in T1W structure stream or aCBV function stream), the data can go through the same flow as SE-VGG-11BN. The classifier that includes several dense layers could yield the final prediction result.

FIGS. 19A-19D illustrate the performance of three candidate models in schizophrenia classification. (FIG. 19A). Receiver operating characteristics (ROC) curves for schizophrenia classification on the dataset. The green line represents the ROC curve of the benchmark model with the input of TIW WH scans. The blue line represents the ROC curve of the SE-VGG-11BN with the input of T1W WB scans. The red line represents the ROC curve of the dual stream SE-VGG-11BN with the input of TIW WB scans and aCBV scans. (FIG. 19B). Classification performance of models in terms of Accuracy (at threshold=0.5), Sensitivity, Specificity and AUROC. (FIG. 19C). Table quantitatively summarizing the performance of different models. The p-value of ROC test (DeLong's test) indicated the proposed dual stream model is better than the benchmark model at the level of 0.05. (FIG. 19D). Generalizability of the three models trained by COBRE and NMorphCH dataset on unseen BrainGluSchi test dataset. Both SE-VGG-11BN and dual stream SE-VGG-11BN exhibit better performance than the benchmark model.

FIG. 20 illustrates a workflow of class activation map (CAM) generation in a high performing model. In the dual stream SE-VGG-11BN model, the class of one given T1W scan and aCBV map is predicted by two steps in the model: 1) extracting hierarchical features; 2) fusing features and classifying these features. In the feature extractor part (either in TIW structure stream or aCBV function stream), feature maps generated by filters in each convolutional layer are used for the generation of class activation maps by weighting them with channel-wise average gradients at different layer (e.g., the last convolution layer).

FIGS. 21A-21F illustrate a visualization of discriminative regions of the dual stream SE-VGG-11BN. (FIG. 21A). The 2D discriminative regions in the sagittal, axial, and coronal view derived from TIW feature maps in a last convolutional layer. The color bar ranges from 0.1 to 1. The bigger the value, the more important the region. (FIG. 21B). The 2D most discriminative regions in the sagittal, axial, and coronal view derived from TIW feature maps in a last convolutional layer. The color bar ranges from 0.85 to 1. The colored decision-making regions in the TIW sub-stream primarily lie in the temporal lobe and frontal lobe. (FIG. 21C). The 3D most discriminative regions in the sagittal, axial, and coronal view derived from T1W feature maps in a last convolutional layer. The color bar ranges from 0.85 to 1. The colored decision-making regions in the TIW sub-stream primarily lie in the temporal lobe and frontal lobe. (FIG. 21D). The 2D discriminative regions in the sagittal, axial and coronal view derived from aCBV feature maps in a last convolutional layer. (FIG. 21E). The 2D most discriminative regions in the sagittal, axial, and coronal view derived from aCBV maps in a last convolutional layer. The color bar ranges from 0.85 to 1. The colored decision-making regions in the function stream mainly lie in the parietal lobe and ventricle area. (FIG. 21F). The 3D most discriminative regions in the sagittal, axial, and coronal view derived from aCBV maps in a last convolutional layer. The color bar ranges from 0.85 to 1. The colored decision-making regions in the function stream mainly lie in the parietal lobe and ventricle area. A notable point is that the hippocampus is also within the activation regions and helps the model make decisions derived from both TIW and aCBV feature maps. The color bar ranges from 0.85 to 1 and the area with bigger value is more important in decision making.

FIGS. 22A-22C illustrate the performance of two high performing proposed models on the private dataset. (FIG. 22A). This table summarizes the classification results of subjects with/without syndromal psychosis in two analysis groups (baseline and 2-year follow up). In each analysis group, dual stream SE-VGG-11BN using whole brain TIW scans and aCBV maps outperforms SE-VGG-11BN only using aCBV maps in terms of accuracy (at optimal threshold, OP) and AUROC. The difference between normal subjects and CHR_C subjects in baseline or 2-year follow-up evaluated by t-test (t-score and p-value) is significant. From baseline to 2-year follow-up, t-score and p-value gets smaller, this may indicate that after two years, there are more abnormalities in the brain in CHR_C subjects. (FIG. 22B). This table summarizes the classification result of CHR subjects with/without conversion to syndromal psychosis in two analysis groups (baseline and 2-year follow up). The first analysis group is CHR_NC vs CHR_C (baseline), the second one CHR_NC vs CHR_C (2-year follow-up). The model classification performance is evaluated in terms of accuracy and AUROC using only whole brain aCBV scans and whole brain TIWaCBV scans. The difference between normal subjects and CHR_C subjects in baseline or 2-year follow-up is evaluated by t-test (t-score and p-value). (FIG. 22C). This table summarizes the correlation between the prodromal schizophrenia model prediction score and the relevant symptoms. Whether in positive or negative symptoms, the significant correlation between the symptoms and the model prediction score exists in general in the total scale and most sub-scales. CHR_NC: subjects of clinical high risk do not convert to syndromal psychosis. CHR_C: subjects of clinical high risk convert to syndromal psychosis, 2-year follow up: revisit some of CHR_C subjects after two years.

FIGS. 23A-23D illustrate the architecture details of the two proposed models' architecture. FIGS. 23A and 23B correspond to a proposed SE-VGG-11BN model. The feature extraction part include five independent 3D convolution blocks. The classifier includes three dense layers, followed by softmax activation. FIGS. 23C and 23D correspond to a proposed dual stream SE-VGG-11BN. The two streams have the same architecture as the feature extraction part in SE-VGG-11BN. The classifier also includes three dense layers and one softmax activation.

FIGS. 24A-24C illustrate a neurological class activation maps of synthesized aCBV maps of CHR dataset at follow-up stage. (FIG. 24A). The global averaged 2D class activation maps of CHR dataset from a high performing dual stream SE-VGG-11BN. (FIG. 24B). The highly-weighed region in 2D class activation maps of CHR dataset from a high performing dual stream SE-VGG-11BN. (FIG. 24C). A highly-weighed region in 3D class activation maps of CHR dataset from a high performing dual stream SE-VGG-11BN. Feature information comes from both medial temporal and parietal-occipital lobe. FIGS. 17-24 relate to Examples 13-15 set forth hereinbelow.

FIG. 25 shows how glutamate and GABA are metabolically coupled. Glutamate can be transported out of the extracellular space into either astrocytes or neurons. In astrocytes, α-ketoglutarate, which is a component of the tricarboxylic acid (TCA) cycle, is converted into glutamate by glutamate-oxaloacetate transaminase (GOT); meanwhile, glutamate dehydrogenase (GDH; GLUD1) converts some glutamate back to α-ketoglutarate. Subsequently, the glutamate further reacts with ammonia and generates glutamine-glutamate is converted into glutamine by glutamine synthetase (GS) in astrocytes, released into the extracellular space, taken up by neurons and converted back into glutamate by phosphate activated glutaminase (GLS1). In neurons, glutamate can serve as a source of GABA by conversion via glutamic acid decarboxylase (GAD).

FIG. 26 shows that GLX+GABA levels are elevated Clinical High-Risk (CHR) patients. Hippocampal pathophysiology of clinical high-risk patients vs. control subjects. Compared with control subjects, patients were found to have dominant elevations of glutamate+glutamine (GLX) (upper panel, 1st graph) and GLX+GABA (upper panel, 2nd graph) as well as elevations in CA1 cerebral blood volume (CBV) (upper panel, 3rd graph). No difference was found for CA1 volume (upper panel, 4th graph). Bars indicate standard error of the mean. *p<0.05; **p<0.01; ***p<0.001.

FIG. 27 shows that GLX+GABA levels are associated with both positive and negative symptoms. GLX+GABA levels were found to correlate positively to most scores of the positive symptoms including P1, P2, P4, P5 and P-total (PTOT). GLX+GABA levels were also found to correlate positively to most scores of the negative symptoms including N3, N5, N6 and N-total (NTOT). Positive symptoms and negative symptoms are outlined in the Structured Interview of Psychosis-risk Syndromes (SIPS).

FIG. 28 shows that GABA levels are decreased in GLS1lox/lox mice of GLS1 Inhibition. Adult GLS1lox/lox mice (male, n=5) received AAV5-creGFP injections in the right HIPP, CA3 region, at about P120, and were imaged 30 days later. (A) Magnetic resonance spectroscopy measured hippocampal glutamate+glutamine (GLX) and GABA. The voxel placed over the unilateral hippocampus (indicated in red) is shown for both control side and the injected side. Example spectra of the control side hippocampus (B) and injected side hippocampus (C) illustrating GABA reductions due to the GLS1 inhibition and no difference in GLX and creatine (Cr). (D) Paired t-test shows significant GABA/Cr reductions in the injected side hippocampus compared to the contralateral control side hippocampus. (E) Paired t-test shows no statistically significant changes of GLX/Cr in the injected side hippocampus compared to the control side hippocampus. *p<0.05; **p<0.01.

### DETAILED DESCRIPTION OF THE INVENTION

Embodiments of the inventions described herein leverage machine learning models to support improvements in scan analyses and/or the detection of brain conditions. Several embodiments are provided that implement a variety of machine learning model(s), analyses workflows, and other variations in scan analyses. Machine learning model architectures implemented in some embodiments include convolutional neural networks, dual stream convolutional neural networks, and transformers. For example, brain scans (e.g., magnetic resonance imaging scans) can be combined with other related data (e.g., artificial cerebral blood volume maps), and these pieces of data can be input to a trained machine learning model to generate predications and/or estimations. One or more machine learning models can be trained to perform data correction, such as frequency and phase correction for magnetic resonance spectroscopy data, in some embodiments. Implementations can generate a brain condition prediction, such as a likelihood of early-stage schizophrenia, a metabolite (e.g., glutamate/glutamine, GABA, and the like) quantification estimation, or other suitable scan analyses can be performed.

Some embodiments relate to the detection (e.g., early-stage detection) of brain conditions, such as schizophrenia, using brain scan(s). The natural history of brain disorders occurs in stages, including premorbid, prodromal, and syndromal onset. In Alzheimer's disease (AD), clinical criteria have been developed that define its prodromal phase as mild cognitive impairment, whereas the prodromal phase of schizophrenia is characterized predominantly by attenuated psychotic symptoms and termed clinical high risk (“CHR”). However, whereas the majority of patients with mild cognitive impairment progress to syndromal AD, only a minority of people identified as CHR progress to syndromal schizophrenia or related psychotic disorders within 2 to 3 years. The limited specificity of the CHR criteria impedes their clinical application for diagnosis and therapeutic intervention. Moreover, in contrast to AD, the pathophysiological mechanisms that mediate the onset and progression of the illness are unknown.

GABA is the primary inhibitory neurotransmitter in the human brain. A variety of studies of neurological and psychiatric disorders have shown its unique pathological characteristic in brain dysfunction. Among a wide range of methods for measuring GABA in vivo, MEGA-PRESS is currently a widely used magnetic resonance spectroscopy (MRS) technique. MEGA-PRESS is a J-difference editing (JDE) pulse sequence that separates GABA from overlapping metabolites such as creatine (Cr), which is present in much greater concentrations. This separation is based on selective induction and suppression of J-modulation of the GABA-H4 resonance.

¹HMRS spectral editing of GABA with MEGA-PRESS is seeing increasing popularity in both human and mouse studies thanks to the recent implementation of standard pulse sequences and processing algorithms. A major limitation in JDE pulse sequences is that they depend on the subtraction of edited “On Spectra” and “Off Spectra” to reveal the edited resonance in the “Diff Spectra”. As a result of the overlapping resonances being an order of magnitude larger in intensity than the GABA resonance, small changes in scanner frequency and spectral phase will lead to incomplete subtraction and distortion of the edited spectrum.

One approach in GABA editing is to apply frequency and phase drift correction (FPC) of individual frequency domain transients by fitting the Cr signal at 3 ppm. The major limitation of the Cr fitting-based correction method is that it relies strongly on sufficient SNR of the Cr signal in the spectrum. To overcome this limitation, a frequency domain spectral registration (SR) approach was recently proposed for FPC (e.g., released software package JET, http://doi.org/10.5281/zenodo.3967565), such as approaches that can accurately align single transients in the time domain or frequency domain. In the SR approach, the frequency and phase offsets can be estimated based on a nonlinear optimization numerical method to maximize the cross-correlation between each transient to a reference template.

These approaches also often rely upon the common information content of each transient in order to achieve alignment. There is often an implicit assumption that the way in which individual transients of the same acquisition differ is by some (e.g., small) frequency and phase shifts. The correction accuracy also depends on overall spectral SNR. It was noted that the performance of the Cr fitting-based correction method is limited when the spectral SNR is smaller than 10 dB, and the performance of the proposed method for drift correction is limited at the lowest SNR of 2.5 dB (when the spectrum is dominated by noise).

Deep learning is a common strategy to address a wide range of complex computational problems. Moreover, deep learning is an effective image processing approach that has been enthusiastically adopted in MR imaging but thus far has had a more modest impact on MRS. Multilayer perceptron (MLP), a class of feedforward artificial neural network, has been recently applied to single-transient FPC for edited MRS. MLP models used to be extensively applied in image processing and computer vision, now are succeeded by CNNs. For example, the utility of CNNs in this problem is they exploit spatial and temporal invariance in recognition of features such as the overall shape of the signal and its peaks. Weight sharing happens across the receptive field of the neurons to identify these characteristics. MLP, on the other hand, does not have a receptive field, thus, layers are independent of one another resulting in weights to be constantly updated to learn these features. Compared to traditional machine learning techniques, CNNs automatically learn features from data and acquire scores from the output while the user would need to manually extract the feature to train the model for machine learning techniques. In addition, a new technique is being proposed which harnesses the power of transformers to make sense out of sequences and images. The Transformer is a deep learning model introduced in 2017 that utilizes the mechanism of attention, weighing the influence of different parts of the input data. It is used primarily in the field of natural language processing (NLP) designed to handle 1D sequential data.

Embodiments implement trained convolutional neural networks, dual stream convolutional neural networks, and/or transformers to improve metabolite quantification using brain scans. For example, the DeepSPEC network architecture can be implemented to improve techniques for quantifying a metabolite (e.g., MEGA-PRESS). In some embodiments, a convolutional neural network model with sequential networks (e.g., frequency-model and phase-model) can be implemented to improve metabolite quantification techniques.

Some embodiments use metabolite quantification to detect brain conditions (e.g., detection of early-stage schizophrenia). Embodiments can also detect brain conditions, such as schizophrenia, using trained machine learning model(s) and combination(s) of input data (e.g., magnetic resonance imaging (“MRI”) scans and output from analyses of these scans, such as an artificial cerebral blood volume mapping).

Prior studies have used MRI to highlight structural differences indicative of schizophrenia development such as gray matter volume reductions in prefrontal, temporal, cingulate, and cerebellar cortices. This volumetric loss has been shown to not only mark the onset of schizophrenia, but also progress alongside the illness. Schizophrenia is characterized by other structural changes such as the enlargement of ventricles as well as alterations in white matter, including oligodendrocyte function and distribution. Additionally, changes in functional mappings such as cerebral blood volume (CBV) obtained through contrast-enhanced imaging techniques have also been associated with schizophrenia. Specifically, studies have found increased CBV levels within the hippocampus in schizophrenia patients.

Despite these documented changes, accurate and rapid detection of schizophrenia remains a challenge. While trained psychiatrists can identify the signs of schizophrenia post disease progression, symptoms often overlap with other mental disorders such as major depressive disorder, schizoaffective disorder, and post traumatic disorder, which can create challenges when differentiating between them. Therefore, an objective screening tool to diagnose schizophrenia would provide a benefit and potentially improve patient prognosis by allowing for an earlier intervention.

Various attempts have been proposed to take advantage of the structural and functional alterations present in schizophrenia for classification using neuroimaging data. Machine learning algorithms have historically presented the ability to classify psychiatric disorders in this manner. In particular, support vector machine (SVM), a supervised learning algorithm able to capture non-linear patterns in high-dimensional data, has been most prevalent in schizophrenia classification. Other popular machine learning algorithms for schizophrenia classification include multivariate pattern analysis, linear discriminant analysis, and random forest. While standard machine learning approaches have demonstrated compelling results, their performance highly depends on the validity of manually extracted features. Such features are traditionally extracted based on a combination of previously known disease characteristics and automatic feature selection algorithms. These features may not completely encode the subtle neurological differences associated with schizophrenia; alternatively, they may encode too much unnecessary information requiring additional feature reduction.

Deep learning has recently emerged as a new approach demonstrating superior performance over standard machine learning algorithms to classify schizophrenia using neuroimaging data. Specifically, Convolutional Neural Networks (CNNs) have the ability to learn and encode the significant features necessary for classification and have become popular in medical image analysis. Some studies have already demonstrated the utility of CNNs for schizophrenia classification. While other researchers have studied using 3D CNNs for schizophrenia classification based on structural MRI data, these models had notable deficiencies. As a consequence, both the generalization of trained models as well as the effective integration of multi-modal information remains a challenge.

Given that schizophrenia is characterized by functional and structural changes, deep learning models integrating both forms of information may achieve better performance. However, datasets containing structural and functional imaging for each participant are not readily available, making it difficult to train and evaluate deep learning models following this strategy. Moreover, such models are not as readily applicable given the difficulty of prospectively obtaining multi-modal imaging. One study has found success in Alzheimer's disease classification by incorporating artificial cerebral blood volume (aCBV) structural to functional mapping in addition to structural MRI as part of their classification pipeline. Embodiments incorporate aCBV mappings by generating them directly from structural MRI using a separate contrast-enhancing deep learning algorithm. This information fusion strategy can capture both the structural and functional abnormalities associated with schizophrenia solely based on widely available structural MRI input data.

As disclosed herein, combining synthesized aCBV functional mappings with structural MRI scans represents an effective and data-efficient method to improve deep learning schizophrenia classification performance. Embodiments include a 3D CNN using structural MRI scans to yield a better performance than the benchmark model for schizophrenia classification. In addition, embodiments combine T1W structural scans with synthesized aCBV maps in the model to boost the schizophrenia classification performance. Moreover, embodiments apply gradient class activation maps to localize the brain regions related to schizophrenia identification. Embodiments also demonstrate that the inclusion of functional aCBV drives prodromal schizophrenia classification ability as opposed to TIW scans alone.

While the inventions disclosed herein are embodied in many different forms, disclosed herein are specific illustrative embodiments thereof that exemplify the principles of these inventions. It should be emphasized that the inventions disclosed herein are not limited to the specific embodiments illustrated. Moreover, any section headings used herein are for organizational purposes only and are not to be construed as limiting the subject matter described.

Unless otherwise defined herein, scientific, and technical terms used in connection with the inventions disclosed herein shall have the meanings that are commonly understood by those of ordinary skill in the art. Further, unless otherwise required by context, singular terms shall include pluralities and plural terms shall include the singular. More specifically, as used in this specification and the appended claims, the singular forms “a,” “an” and “the” include plural referents unless the context clearly dictates otherwise. Thus, for example, reference to “a protein” includes a plurality of proteins; reference to “a cell” includes mixtures of cells, and the like.

In addition, ranges provided in the specification and appended claims include both end points and all points between the end points. Therefore, a range of 1.0 to 2.0 includes 1.0, 2.0, and all points between 1.0 and 2.0.

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of” “consisting essentially of,” when used in the claims, shall have its ordinary meaning as used in the field of patent law.

As used in the specification and in the claims, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively.

Generally, nomenclature used in connection with, and techniques of, cell and tissue culture, molecular biology, immunology, microbiology, genetics and protein and nucleic acid chemistry and hybridization described herein are those well-known and commonly used in the art. The methods and techniques of the present invention are generally performed according to conventional methods well known in the art and as described in various general and more specific references that are cited and discussed throughout the present specification unless otherwise indicated. Enzymatic reactions and purification techniques are performed according to manufacturer's specifications, as commonly accomplished in the art or as described herein. The nomenclature used in connection with, and the laboratory procedures and techniques of, analytical chemistry, synthetic organic chemistry, and medicinal and pharmaceutical chemistry described herein are those well-known and commonly used in the art.

### Metabolite Quantification Using Machine Learning: Quantifications for GLX Measured by ¹H-MRS

Embodiments relate to the detection of elevated glutamate/glutamine (“GLX”) using ¹H-MRS in the hippocampus of subjects having, or at risk for, schizophrenia using machine learning. Without wishing to be bound by theory, it is believed that glutamate hyperactivity, reflected by increased metabolic activity derived from functional magnetic resonance imaging in the CA1 hippocampal subregion and from proton magnetic resonance spectroscopy-derived hippocampal levels of glutamate/glutamine, represents early hippocampal dysfunction in CHR subjects.

Exemplary methods for quantifying GLX levels in the brain include: the use of a magnetic resonance spectroscopy (MRS) described herein and the use of DeepSPEC for frequency-and-phase correction (FPC) of MRS spectra. Either of these techniques can be used to identify indicia for schizophrenia, either alone or together, or to identify any other suitable indicia of a brain condition and/or quantify any other suitable metabolite.

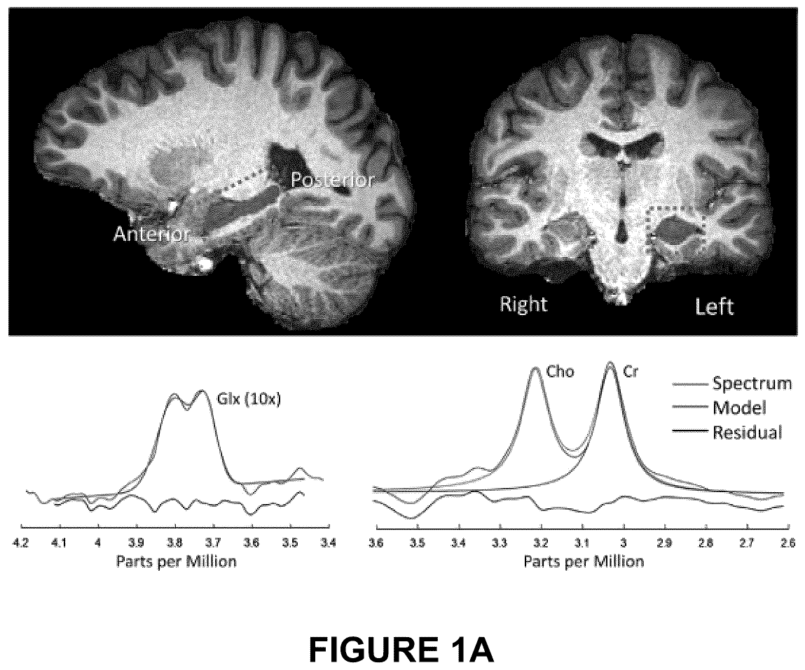

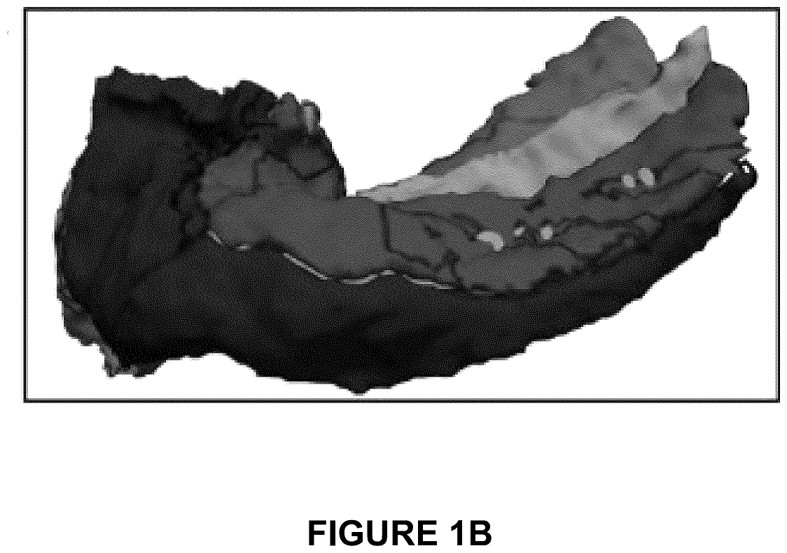

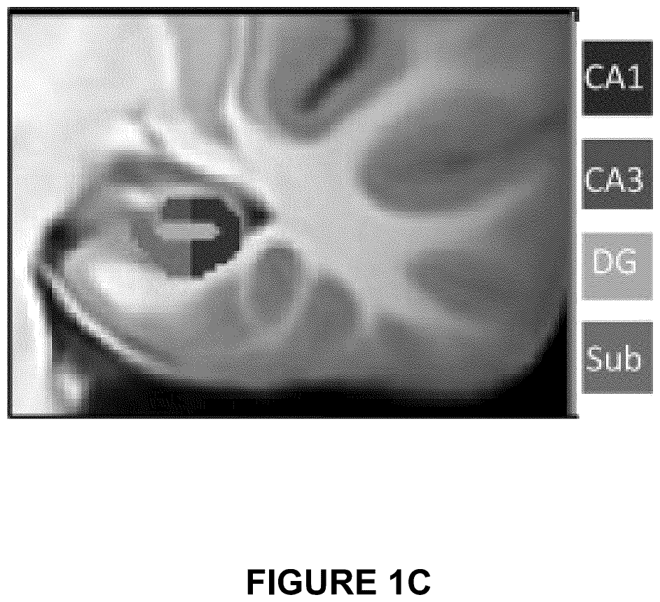

The first exemplary method is described in Examples 1-6 and FIGS. 1-4. Seventy-five CHR individuals with attenuated positive symptom psychosis-risk syndrome as defined by the Structured Interview for Psychosis-risk Syndromes were enrolled. Optimized magnetic resonance imaging techniques were used to measure three validated in vivo pathologies of hippocampal dysfunction−focal cerebral blood volume, focal atrophy, and evidence of elevated glutamate concentrations. Patients were imaged at baseline and were followed for up to 2 years to assess for conversion to psychosis. At baseline, compared with control subjects, CHR individuals had high glutamate/glutamine and elevated focal cerebral blood volume on functional magnetic resonance imaging.

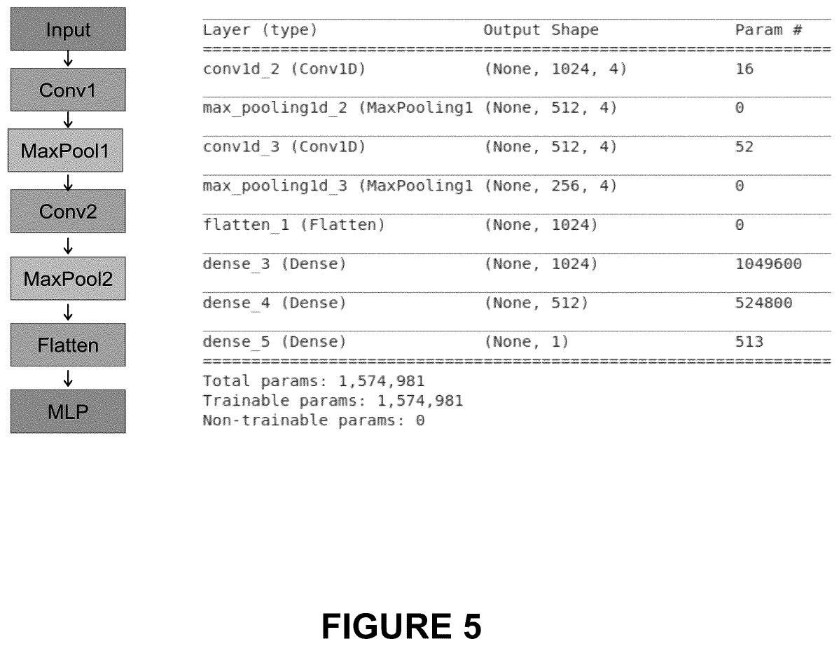

The second exemplary method is described in Examples 7 and 8 and FIGS. 5-10. The second technique uses DeepSPEC, a novel deep learning-based approach for frequency-and-phase correction (FPC) of MRS spectra.

DeepSPEC contains two deep learning frameworks where both Convolutional Neural Networks (CNNs) and Transformers are used to achieve fast and accurate FPC of single voxel PRESS MRS and MEGAPRESS data. In each deep learning framework, two neural networks, i.e., 1 for frequency correction, 1 for phase correction, were trained and validated using a published simulated PRESS and MEGAPRESS MRS dataset with wide-range artificial frequency and phase offsets applied. DeepSPEC was subsequently tested and compared to the current benchmark—a “vanilla” neural network approach using multilayer perceptrons (MLP). Additional noise was added to these simulated datasets to further investigate performance at different signal-to-noise ratio (SNR) levels. The testing showed that DeepSPEC has the a high level of performance and is more robust to noise. The DeepSPEC CNN framework was capable of correcting frequency offset with 0.01 Hz and phase offset with 0.14° absolute errors on average for unseen simulated data with moderate signal-to-noise ratio (SNR) (15 dB) and correcting frequency offset with 0.06 Hz and phase offset within 0.49° absolute errors on average with very low SNR (2.5 dB). These results demonstrate that CNNs and Transformers can be used for pre-processing MRS data and demonstrate that DeepSPEC accurately predicts frequency and phase offsets at varying noise levels with the state-of-the-art performance.

Embodiments implement CNNs and/or Transformers for frequency and phase correction (PFC) of the single voxel MEGAPRESS MRS data. To deal with issues related to motion and main magnet field drifts in MEGA-PRESS acquisition, two novel deep learning frameworks were implemented for automatic PFC with CNNs and Transformers. These DeepSPEC models were tested with a published simulated dataset against the benchmark—a “vanilla” neural network approach using MLP. DeepSPEC achieved state-of-the-art performance and nearly optimal correction efficiency. The effect of additional noise on the FPC performance was further investigated to further demonstrate that DeepSPEC is a robust solution when dealing with spectra with low signal-to-noise ratio (SNR).

These findings have therapeutic implications. Schizophrenia patients have a reliable increase in both glutamate-glutamine (GLX) and GABA, which, in the context of schizophrenia, is signature of pathway dysfunction. GLX+GABA is distinct from other MRS measures in that it correlates with the schizophrenia's full clinical phenotype, from positive through negative symptoms. Further, GLX+GABA is abnormally elevated in those CHR patients who progress to psychosis at follow up.

While increases in synaptic glutamate levels are the source of schizophrenia's pathophysiological state, the root cause(s) of this increase remain unknown. One early idea was proposed from observations in animal models who were acutely overdosed with the drugs that inhibit the receptors, and where increased glutamate was measured directly and exclusively in the synapse's extracellular synaptic cleft. The observed glutamate increase in the synaptic cleft was hypothesized to occur by receptor inhibition somehow leading to a ‘compensatory’ release of presynaptic stores of glutamate into the synaptic cleft. While never tested in schizophrenia, by inference, this mechanism was proposed to exist in the disorder as well. The idea that synaptic glutamate increases in schizophrenia is mediated by this mechanism is, in retrospect, unlikely. The inference from acute drug toxicity in animal models to the chronic human disorder was articulated before magnetic resonance spectroscopy documented increased hippocampal glutamate in schizophrenia. MRS is effectively blind to an intracellular-to-extracellular redistribution of glutamate and can only detect a net increase in synaptic glutamate. Furthermore, this recent realization might retrospectively help explain why the numerous clinical trials, testing drugs that were designed to correct the proposed glutamate redistribution, have largely failed.

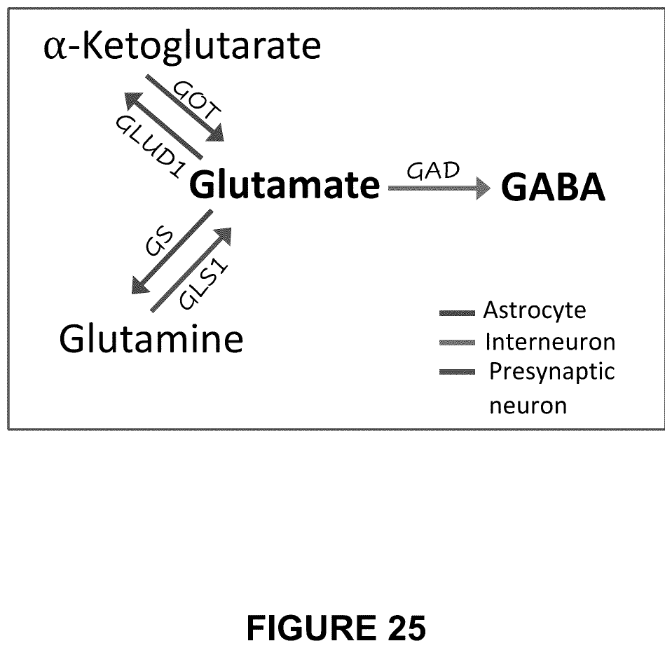

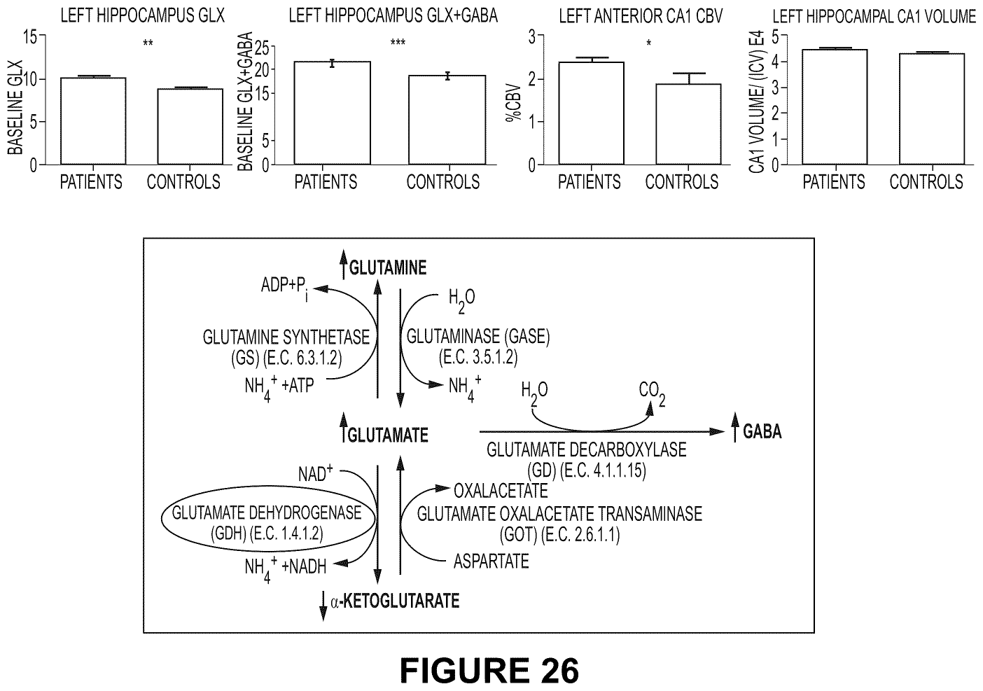

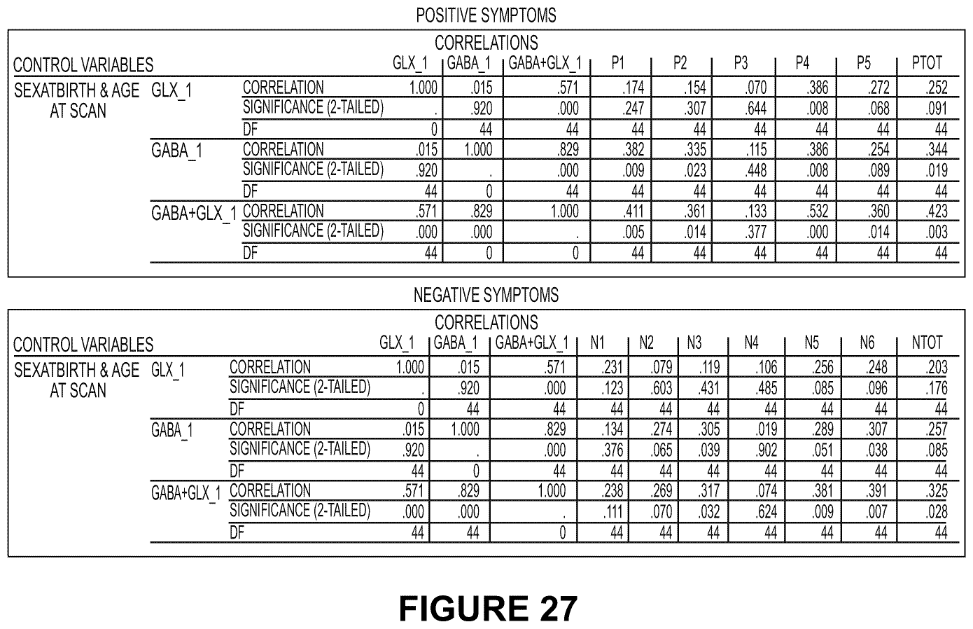

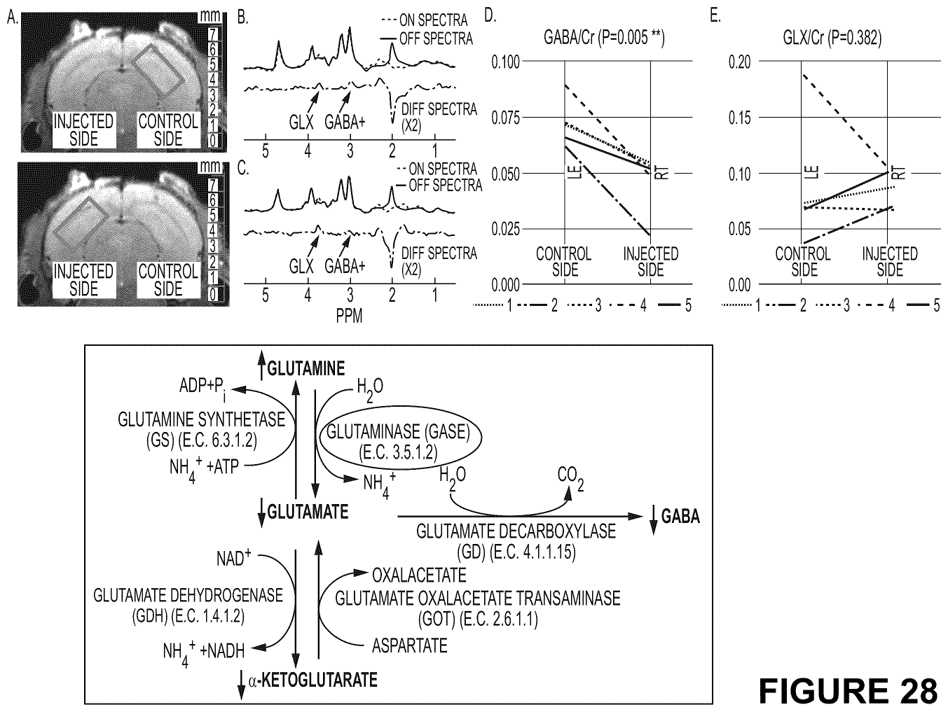

Without wishing to be bound by theory, the more plausible mechanism that can explain a net increase in glutamate levels are defects in the ‘glutamate metabolic cycle’, a metabolic pathway that is primarily dedicated to regulating net synaptic glutamate levels (see FIGS. 25-28). This metabolic pathway, sometimes called the ‘glutamate/GABA-glutamine cycle’, begins in the synapse's astrocytes, where glutamate synthesis is proximally regulated by GOT, an enzyme that converts alpha-ketoglutarate to glutamate, or GLUD1 (glutamate dehydrogenase 1) an enzyme that converts glutamate back to alpha-ketoglutarate. In the astrocyte, glutamate can also be converted to glutamine via GS (glutamine synthetase), and the astrocyte can then deliver glutamine to the presynaptic neuron, where GLS1 (glutamate synthetase) converts glutamine back to glutamate. Once the presynaptic neuron releases glutamate into the synaptic cleft it can ‘cycle’ back to the astrocyte, or ‘cycle’ to the synapse's inhibitory interneuron, where glutamate can be converted to GABA by GAD (glutamate decarboxylase).

This putative mechanism is supported by multiple indirect lines of evidence. First, many enzymes of the pathway are enriched in the hippocampus, accounting for why manipulating these enzymes in animal models typically affects glutamate and activity levels selectively in the hippocampus. Second, gene expression studies performed in postmortem CA1 hippocampal samples of schizophrenia patients have identified deficiencies in GLUD1, a deficiency that has been shown to increase hippocampal activity and glutamate in model systems. Third, mouse models with deficiencies in GLS1 show an inverse effect on the hippocampal glutamate and activity and have been shown to manifest a schizophrenia ‘resilient’ phenotype. Guided by observations that typify patients, the mice are found resilient to amphetamine-induced hyperactivity and downstream dopamine release and are resilient to ketamine-induced downstream frontal cortex hyperactivity. Additionally, in contrast to what is observed in patients, the GLS1 deficient mice show an enhancement in clozapine-induced potentiation of latent inhibition.

Based on the data and teachings disclosed herein, one of ordinary skill would conclude that the glutamate metabolic cycle is defective in schizophrenia and that MRS can be used to probe this pathway, diagnostically and therapeutically.

### EXAMPLES

The following examples have been included to illustrate aspects of the inventions disclosed herein. In light of the present disclosure and the general level of skill in the art, those of skill appreciate that the following examples are intended to be exemplary only and that numerous changes, modifications, and alterations may be employed without departing from the scope of the disclosure.

### Example 1

### Materials and Methods for Examples 2-6

Seventy-five help-seeking patients 15 to 30 years of age were assessed using the Structured Interview for Psychosis-risk Syndromes (SIPS) (Miller et al. 2003) at the Columbia Center of Prevention and Evaluation at the New York State Psychiatric Institute.

Patients met criteria for attenuated positive symptom psychosis-risk syndrome, defined as having ≥1 positive symptoms scored 3 to 5 that are new or have worsened by ≥1 points in the past year and never having reached a score of 6 on a positive symptom. As per the SIPS, a diagnosis of psychosis is associated with a 6 on ≥1 positive symptoms at a frequency of 1 hour daily for 4 days per week for a month or that a positive symptom is severely disorganizing or endangers oneself or others.

CHR participants were seen for follow-up visits including clinical interviews and SIPS evaluations every 3 months for up to 2.5 years or whenever a diagnosis of psychosis was suspected. SIPS interviewers were certified and established interrater reliability. Syndromal psychosis diagnoses were confirmed by a consensus of SIPS-certified clinicians.

CHR participants were able to receive treatment (medication management and psychotherapy) during their participation. At baseline, participants also underwent a diagnostic interview [either the Diagnostic Interview for Genetic Studies (Nurnberger et al. 1994) or the Structured Clinical Interview for DSM-IV Axis I Disorders, Patient Edition (First et al. 2002).

Nineteen control subjects were also recruited. Eligibility criteria for these subjects were the same as for the CHR subjects with the exception that none scored higher than a 2 on any SIPS positive symptom or met criteria for a past or current DSM Axis I disorder at baseline.

Subjects were medically healthy; free of asthmatic symptoms for at least 3 years if they previously had asthma; and had creatine clearance values of at least 50 mL/min/1.73 m². Exclusion criteria were any history of renal disease or hypertension, current substance abuse or dependence, or a medical condition known to affect the central nervous system.

The study protocol was reviewed and approved by the New York State Psychiatric Institute Institutional Review Board before initiating research. Adult subjects provided written informed consent, and minors provided written assent with written informed consent given by one or both parents. Statistics were analyzed using SAS 9.4 (SAS Institute Inc., Cary NC).

Imaging: Subjects were scanned at the MRI Center at the Neurological Institute of Columbia University Medical Center with a 3.0T Achieva (Philips Healthcare, Cambridge, MA) MRI scanner using an 8-channel SENSE head coil (Philips Healthcare). Before scanning, estimated glomerular filtration rate (eGFR) in subjects was analyzed using a handheld eGFR and creatine StatSensor (Nova Biomedical, Waltham, MA). A registered nurse or physician was present to start an intravenous line that was used in conjunction with a controllable MRI-compatible autoinjector that was fitted with a body weight-adjusted dose (0.1 mm/kg) of gadobenic acid (MultiHance; Bracco Imaging S.p.A., Milan, Italy). The scan sequences included ¹H-MRS, a T1-weighted turbo field echo scan, and a pair of T1-weighted scans acquired in the oblique coronal plane to the long axis of the hippocampus. The ¹H-MRS sequence was added to the protocol during the course of the study and thus was acquired in only a subset of patients. The bolus injection of gadolinium was started after the penultimate scan, followed by a 4-minute pause and then the second image of the pair.

Volume: The T1-weighted turbo field echo images (repetition time=6.7 seconds, echo time=3.1 seconds, field of view=240×240×192 mm³, voxel dimensions 0.9×0.9×0.9 mm³) were processed with FreeSurfer v6.0 pipeline (Fischl et al. 2002) and a recently improved hippocampal subfield segmentation module (Iglesias et al. 2015; Whelan et al. 2016). CA1 volumes and estimated total intracranial volumes were extracted from the volumetric segmentations. The CA1 volumes were normalized by intracranial volumes via proportional scaling to account for overall head size in a matter consistent with previous subfield studies in this field (Ho et al. 2017; Papiol et al. 2017).

Cerebral Blood Volume: Raw CBV images were generated using previously reported techniques (Brickman et al. 2014; Khan et al. 2014) using a pair of T1-weighted turbo field echo images (repetition time=6.7 seconds, echo time=3.1 seconds, field of view=240×196×162, voxel dimensions 0.68×0.68×3 mm³) before and after a bolus injection of contrast agent. A broad population template was generated using brain-extracted pre-contrast images utilizing the same acquisition parameters on the same scanner and protocol. This template represented a broad population of 50 pre-contrast scans that were co-registered using Advanced Normalization Tools (Avants et al. 2011; Pluta et al. 2009). Onto this template a trained rater drew 4 canonical hippocampal subregions in the anterior hippocampus—the CA1, CA3, dentate gyrus, and subiculum. Using a majority voting technique based on 5 separate drawings, a unified template space region of interest was generated. Once a subject's CBV image was generated, the precontrast T1-weighted image was then co-registered using a diffeomorphic co-registration technique along with the CBV image and a mask excluding epicortical vasculature (Khan et al. 2014). The mean values for each of the hippocampal subregions were generated in the group-template space and filtered for large vessels using a mask applied to the total brain volume.

Glutamate/Glutamine: For the detection of glutamate/glutamine (GLX), ¹H-MRS spectra were selectively acquired from a 40×25×20 mm³ voxel of interest positioned at the left hippocampus (FIG. 1A). The anatomical T1-weighted magnetization prepared rapid acquisition gradient-echo scan was acquired for aid in the single voxel placement. J-difference-edited ¹H-MRS spectra were acquired using the MEGA-PRESS (Meshcher-Garwood point resolved spectroscopy) method (Mescher et al. 1998). A total of 60 spectral repetitions with the number of averages of 8 were acquired for each subject with a repetition time of 2000 ms and an echo time of 68 ms. There were 30 OFF and 30 ON spectra (OFF first) collected in an interleaved fashion. MEGA editing was achieved using the 14-ms Gaussian editing pulses applied at 1.9 ppm (ON) and 7.5 ppm (OFF) in alternating spectral lines. An unsuppressed water spectrum was acquired with 8 averages, and the water suppression was achieved using the variable power and optimized relaxation delay technique. Second-order pencil beams automated shimming was conducted to reduce the magnetic field inhomogeneities.

The quality criteria used to accept the data for the analysis included both requiring a desirable full width at half maximum (of water) <20 Hz to ensure good shimming quality, reshimming if larger, and using normalized fitting residual to reject scans for analysis. The ¹H-MRS voxel encompassed both white and gray matter but was dominated by the gray matter, and no between-group differences in the voxel content was discovered. The GLX level was normalized by the total creatine (tCr) level in each voxel. The preprocessing and the frequency and phase drift correction of ¹H-MRS spectra were performed using a previously reported tool (Guo et al. 2018) (with a standard exponential line broadening of 4 Hz), followed by the ¹H-MRS spectral quantitation using the GannetFit module from the Gannet toolkit (Edden et al. 2014). Fitted peak areas in the frequency domain were used to quantify the GLX peaks at 3.75 ppm in the difference spectra (i.e., ON and OFF) and the tCr peaks at 3 ppm in the OFF spectra. GLX/tCr ratios were calculated for each subject. GLX/tCr provides a reliable GLX concentration estimation and reduces the intersubject variability, as tCr level is considered stable. tCr also has the advantage over water because it was acquired simultaneously with gamma-aminobutyric acid from the same voxel, which has no chemical shift displacement artifact.

### Example 2

### Patient Demographics

One example study enrolled 75 patients and 19 healthy control subjects (Table 1). Patients were followed longitudinally for up to 2.5 years (30 months). Consistent with the rate of conversion to syndromal psychosis in a previous study (Schobel et al. 2018), and in contrast to the relative lower rate of conversion in other groups (Cannon et al. 2008), 33% (n=25) of patients converted to schizophrenia or another psychotic disorder during the follow-up period (Table 1) in a mean and median of 9.5 months and 10 months, respectively.

Patients were seen in clinic visits for follow-up assessments or assessments were done by teleconference if patients were unable to come in person.

Four patients and three control subjects were excluded from the CBV analyses owing to missing imaging information, failed processing, or poor image quality. Of the 55 patients and 17 control subjects for whom we acquired usable ¹H-MRS data, 11 patients and 4 healthy control subjects had insufficient spectral quality and failed the spectral fitting. Those participants were excluded from the GLX analyses. Two patients were excluded from the structural analysis owing to missing imaging or failed processing.

TABLE 1
Demographics of Control Subjects and Patients and Converters and Nonconverters

| | Healthy | | | | | |
|---|---|---|---|---|---|---|
| | Control | | | | | |
| | Subjects | Patients | p | Converters | Nonconverters | p |
| | (n = 19) | (n = 75) | Value^{a} | (n = 25) | (n = 50) | Value^{a} |
| Sex, n (%) | | | | | | |
| Male | 14 (73.7%) | 52 (69.3%) | .711 | 22 (88.0%) | 30 (60.0%) | .013^{b} |
| Female | 5 (26.3%) | 23 (30.7%) | | 3 (12.0%) | 20 (40.0%) | |
| Age, Years, | 23.3 6 3.5 | 21.2 6 3.9 | .029^{b} | 20.4 6 3.8 | 21.663.9 | .206 |
| Mean 6 SD | | | | | | |
| Age Groups, n (%) | | | | | | |
| 15-18 | 0 (0%) | 22 (29.3%) | .034^{b} | 11 (44.0%) | 11 (22.0%) | .134 |
| 19-22 | 8 (47.1%) | 28 (37.3%) | | 8 (32.0%) | 20 (40.0%) | |
| 23-29 | 9 (52.9%) | 25 (33.3%) | | 6 (24.0%) | 17 (38.0%) | |
| Race, n (%) | | | | | | |
| White | 8 (42.1%) | 36 (48.0%) | .004^{b} | 8 (32.0%) | 28 (56.0%) | .269 |
| Black | 4 (21.1%) | 14 (18.7%) | | 6 (24.0%) | 8 (16.0%) | |
| Asian/Pacific | 6 (31.6%) | 4 (5.3%) | | 2 (8.0%) | 2 (4.0%) | |
| Islander | | | | | | |
| Mixed | 1 (5.3%) | 21 (28.0%) | | 9 (36.0%) | 12 (24.0%) | |
| Race | | | | | | |
| White/Nonwhite, | | | | | | |
| n (%) | | | | | | |
| White | 8 (42.1%) | 36 (48.0%) | .646 | 8 (32.0%) | 28 (56.0%) | .0499^{b} |
| Nonwhite | 11 (57.9%) | 39 (52.0%) | | 17 (68.0%) | 22 (44.0%) | |
| Ethnicity | | | | | | |
| Hispanic | 4 (21.1%) | 24 (32.0%) | .351 | 10 (40.0%) | 14 (28.0%) | .294 |
| Non-Hispanic | 15 (78.9%) | 51 (68.0%) | | 15 (60.0%) | 36 (72.0%) | |

^{a}p Value from c² test (or t test for continuous age) difference between groups.
^{b}p, .05.

### Example 3

### Hippocampal Pathophysiology of Attenuated Psychosis Symptoms

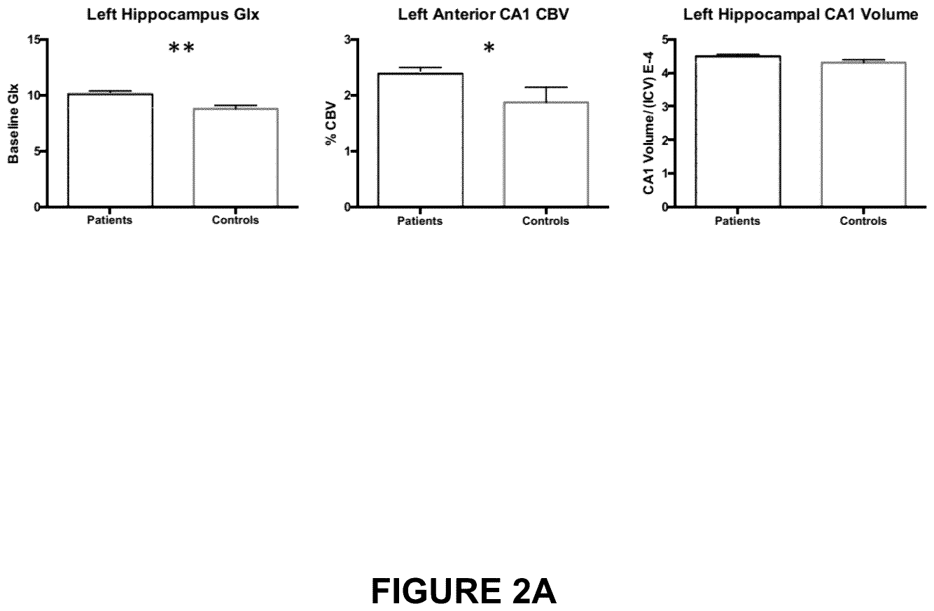

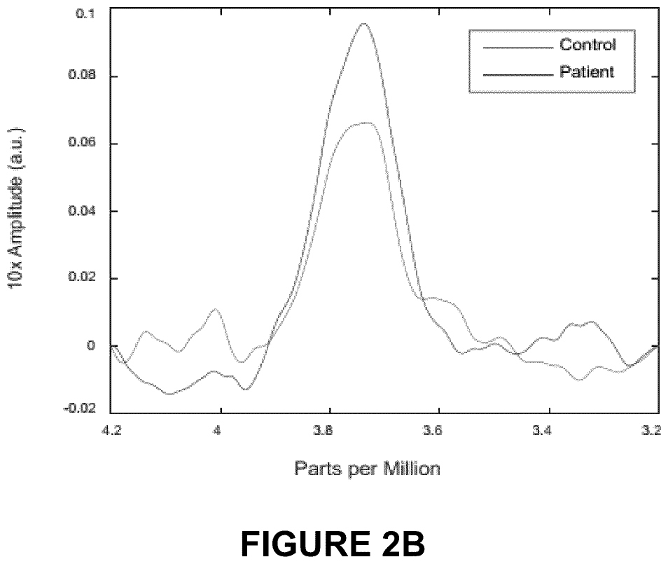

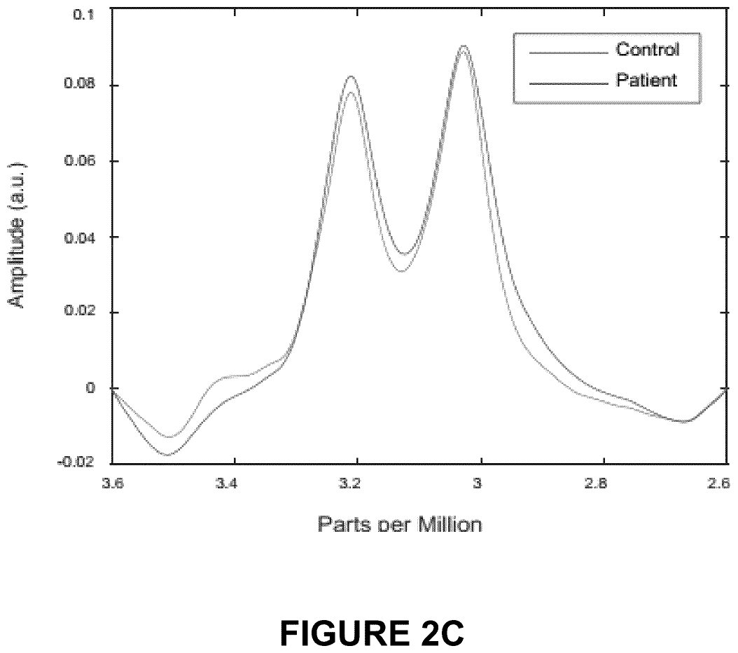

CHR individuals and control subjects were compared on the 3 MRI-derived variables (hippocampal GLX, CA1 CBV, CA1 volume) using linear regressions. Specifically, 3 separate regressions were used, one for each MRI variable as the outcome was predicted by a dichotomous indicator of CHR versus control subjects, age, and sex as covariates (FIG. 2A). Patients and control subjects differed on hippocampal GLX (mean for control subjects=8.8, mean for CHR patients=10.1; Cohen's d effect size [ES]=0.995, p=0.0007) and CA1 CBV (mean for control subjects=1.9, mean for CHR patients=2.4; ES=0.531, p=0.052 for 2-sided hypothesis, p=0.0261 for 1-sided hypothesis). No differences between CHR patients and control subjects were observed for CA1 volume (mean for control subjects=4.3, mean for patients=4.5; ES=0.351, p=0.14). A post hoc analysis confirmed the anatomical specificity of the CBV finding within the hippocampal circuit. Namely, CHR patients were not significantly different from control subjects in the hypothesized directions for volume or CBV of the other hippocampal regions.

### Example 4

### Hippocampal Pathophysiology and Predictors of Syndromal Psychosis

Cox proportional hazards models were fit to examine the association between each baseline imaging measure separately and time to conversion to a syndromal psychotic disorder. The time to event for CHR patients who converted was taken to be the time between the baseline scan and the date of known conversion (mean time to conversion, 9.5 months; range, 1-29 months), and the time to censoring for CHR patients who did not convert was taken to be the time between the baseline scan and the date of last known follow-up assessment without psychosis (average time to last follow-up, 14.6 months; range, 1-30 months). Separate Cox proportional hazards models were fit for each of the 3 baseline imaging application measures and controlled for age and sex.

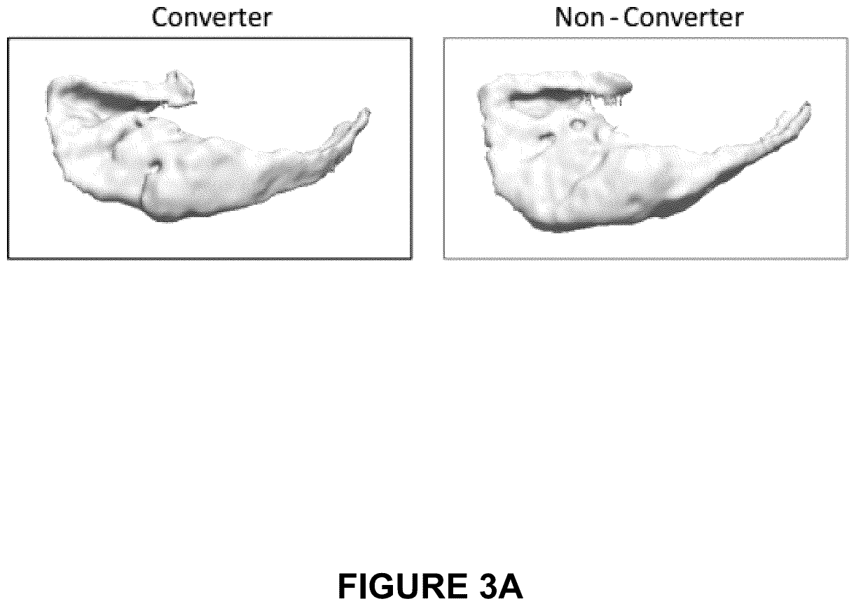

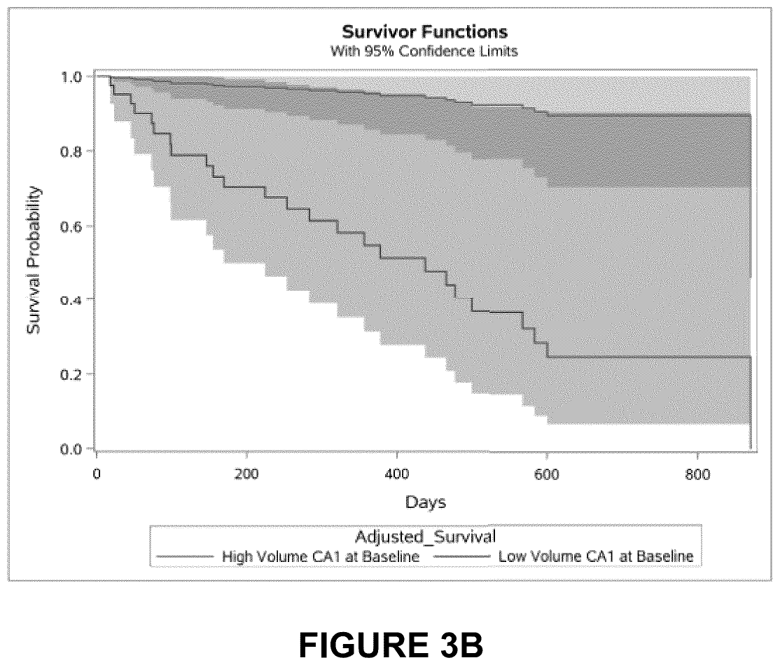

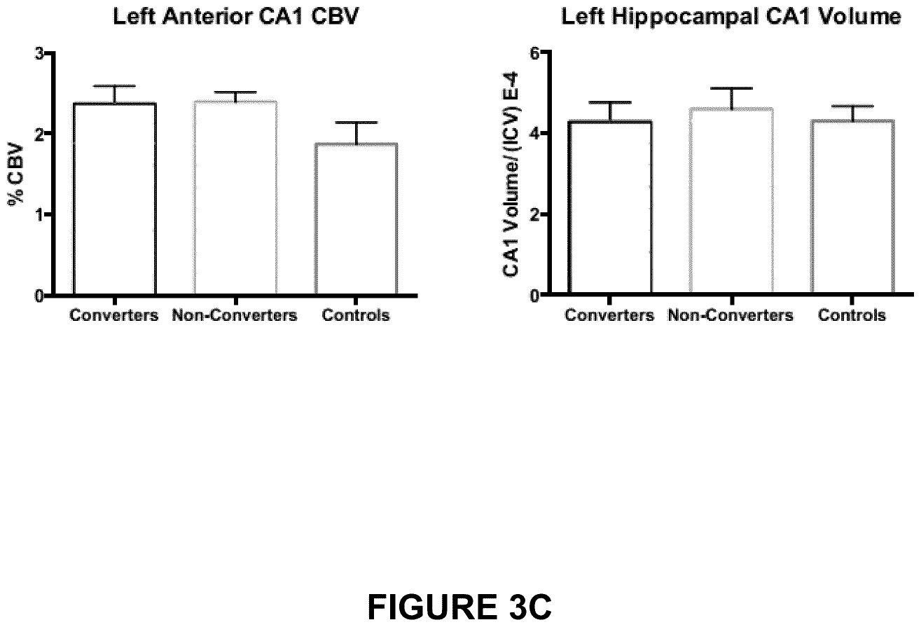

Lower baseline CA1 volume increased the hazard for conversion to syndromal psychotic disorders (log hazard ratio=21.245, SE=0.604, c2=4.250, and reached statistical significance p=0.0392). FIG. 3A depicts the smallest rendered left CA1 subfield (a converter) compared with the largest CA1 subfield (a nonconverter). FIG. 3B shows the adjusted survival curve for a subject with minimum and maximum observed baseline CA1 volume (CA1 volume, minimum=3.6, maximum=5.7). This analysis was also run controlling for medication (noted as taking medication or not) with similar results (log hazard ratio=21.201, SE=0.607, c2=3.901, and reached statistical significance p=0.0483).

### Example 5

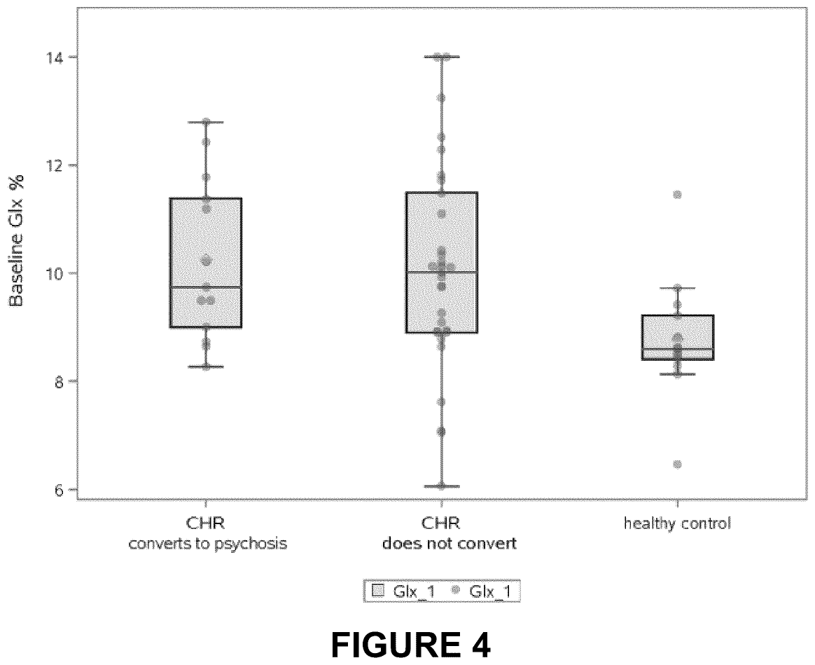

### Hippocampal Pathophysiology Characterizes Attenuated Psychosis

Whereas hippocampal GLX and CA1 CBV in the converters versus nonconverters did not differ (FIG. 3C) in separate linear regressions controlling for age and sex, hippocampal GLX distinguished both converters and nonconverters from control subjects (mean for control subjects =8.8, mean for nonconverters=10.1, mean for converters=10.2; controlling for sex and age, regression adjusted mean difference from control subjects for nonconverters=1.76, SE=0.55, p=0.001, ES=1.1, and mean differences from controls for converters=1.75, SE=0.63, p=0.006, ES=1.1). Moreover, 61% of the nonconverters had hippocampal GLX higher than the highest non-outlying value for healthy control subjects (19 of the 31 nonconverters with GLX data available) indicating clear evidence for elevated glutamate (FIG. 4A). A trend for elevation in CA1 CBV was also observed for nonconverters and converters compared with control subjects (mean for control subjects=1.9, mean for nonconverters=2.4, mean for converters=2.4; controlling for sex and age, regression adjusted mean difference from control subjects for nonconverters=0.51, SE=0.28, p=0.065, for 2-sided hypothesis, p=0.033 for 1-sided hypothesis, ES=0.54, and mean differences from control subjects for converters=0.54, SE=0.32, p=0.088 for 2-sided hypothesis, p=0.044 for 1-sided hypothesis, ES=0.57).

### Example 6

### Hippocampal Pathophysiology and Psychopathology

There were no significant associations between the 3 imaging measures and SIPS total positive symptoms at baseline using bivariate Pearson's or Spearman's correlation coefficient (p>0.10). For individual scores, a significant (p<0.05) negative Spearman's correlation between GLX and Suspiciousness/Persecutory Ideas (P2) scores and CA1 volume and Expression of Emotion (N3) scores was observed, although neither survives correction for multiple comparisons (11 specific symptoms tested).

### Example 7

### Methods for Magnetic Resonance Spectroscopy Spectral Frequency and Phase Correction Using Convolutional Neural Networks and Transformers Simulated Dataset

As no ground truth of frequency and phase offsets for an in vivo dataset is available, MEGAPRESS training, validation and test transients were simulated using the FID-A toolbox (version 1.2), with the same parameters as described in the previous work [8]. A training set for DeepSPEC CNN model is allocated for 36,000 OFF+ON spectra, 4,000 for the validation set, and 1,000 for the test set. For DeepSPEC Transformer model, a training set has 32,000 spectra, validation set has 8,000 spectra, and 1,000 for the test set. Furthermore, additional spectra with lower SNRs (at 10 dB, 5 dB and 2.5 dB) were generated by adding random Gaussian noise to the published simulated dataset respectively.

Network architecture (DeepSPEC CNNs): A CNN model was evaluated to compare its accuracy in frequency and phase offset prediction (FIG. 5). The model was implemented as sequential networks (first frequency, then the phase). Each network includes a channel with 1024 nodes as an input layer, and a one-dimensional convolutional layer followed by a one-dimensional max pooling layer. The layer will then be connected to another series of a one-dimensional convolutional layer followed by a one-dimensional max pooling layer. The convolutional layer has 4 kernels with a size of 3 and the max-pooling layer has a pool size of 2 with a stride of 2. Furthermore, a fully-connected layer with 1024, 512 were used and a final fully-connected linear output layer of 1 node was designed. Each hidden layer is followed by a rectified linear unit activation function to introduce nonlinearity. An Adam optimizer was used to train the neural network. The output from each network is either the predicted offset of frequency or phase.

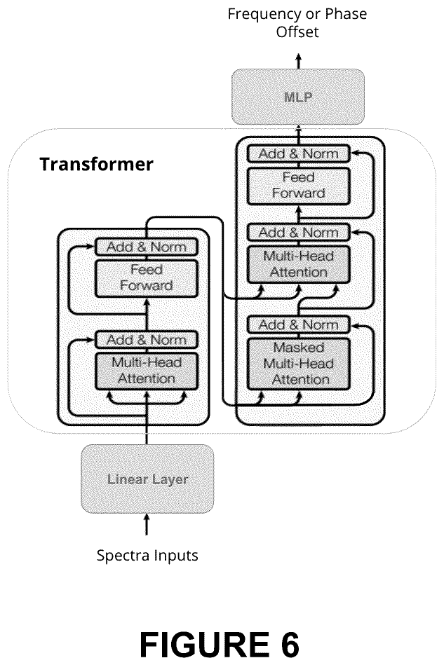

Network architecture (DeepSPEC Transformers): A custom Transformer model architecture is implemented in order to predict frequency and phase offsets separately (FIG. 6). This model comprises an encoder-decoder structure [9]. The encoder is a layer composed of a multi self-attention mechanism and a position wise fully connected feed-forward network. Both components are accompanied by a residual connection and a normalization layer. Layers produce outputs of dimension 1024. The decoder is a layer composed of two multi-head attention blocks and a position wise fully connected feed-forward network. Residual sum and normalization are applied at each block/layer.

In some embodiments, an embedding layer (often used for converting the input into tokens) is replaced by a linear layer, positional encoding which makes use of the order of the sequence was completely removed, and instead of applying attention to the entire sequence, an attention window was created to focus on a few data points at a time, as modeled by some transformers (https://timeseriestransformer.readthedocs.io). For example, the attention function associated with the model mimics the mapping of a query and a set of key-value pairs to an output. The dimensions of the query and key-value vectors are set to 32 and the attention window size is 128. As opposed to the original Transformer model, the decoder output is input into a multilayer perceptron composed of two hidden fully connected layers with 1024 and 512 nodes respectively and a fully connected linear output layer with 1 node in some embodiments. Each hidden layer is followed by a rectified linear unit activation. The Adam optimizer was used to train both frequency and phase Transformer models. Other suitable architectures, hyperparameters, and configurations can be implemented.

Training procedure: Training set and validation set were generated by manipulating the simulated data with frequency and phase offsets (e.g., in uniform distribution). Example artificial frequency and phase offsets ranged from −20 to 20 Hz and −90° to 90° and were defined as the ground truth for the network. Before feeding the network, central 1024 data points of spectra were selected to prevent overfitting of noise at the frequency limits of the spectra. In order to mitigate the effect of other offsets from the spectra when training a network, the input for frequency correction models was modified to magnitude mode to neglect the influence of phase offsets. Similarly, real spectra were used as the input when training the phase correction models to be blind to the frequency offsets.

For the DeepSPEC CNN model, individual training for both networks was performed with a constant learning rate of 0.001 for 300 epochs, with mean absolute error as the loss function, and with a batch size of 64. For the DeepSPEC Transformer model, individual training for both networks was performed with a constant learning rate of 0.0001 for 500 epochs, with mean absolute error as the loss function, and with a batch size of 8. Also, 20% of dropout rate was applied in the fully connected layer of the Transformer model. To prevent models from overfitting of the training dataset, early stopping was employed in both DeepSPEC frameworks together with the Adam optimizer which stops training once the model performance stops improving on a hold-out validation dataset within 40 epochs. Other suitable training techniques can be implemented.

### Example 8

### Results for Magnetic Resonance Spectroscopy Spectral Frequency and Phase Correction Using Convolutional Neural Networks and Transformers

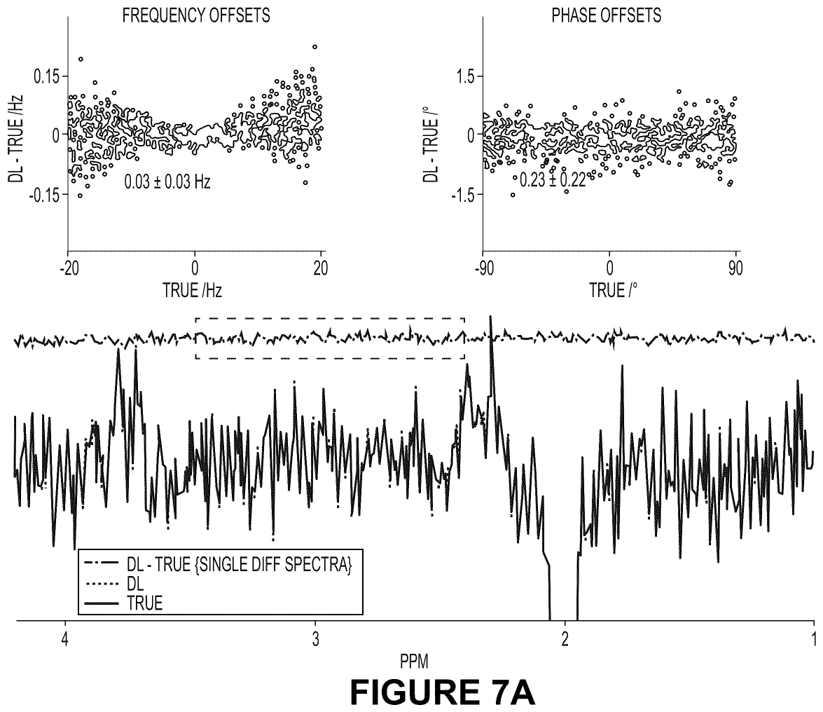

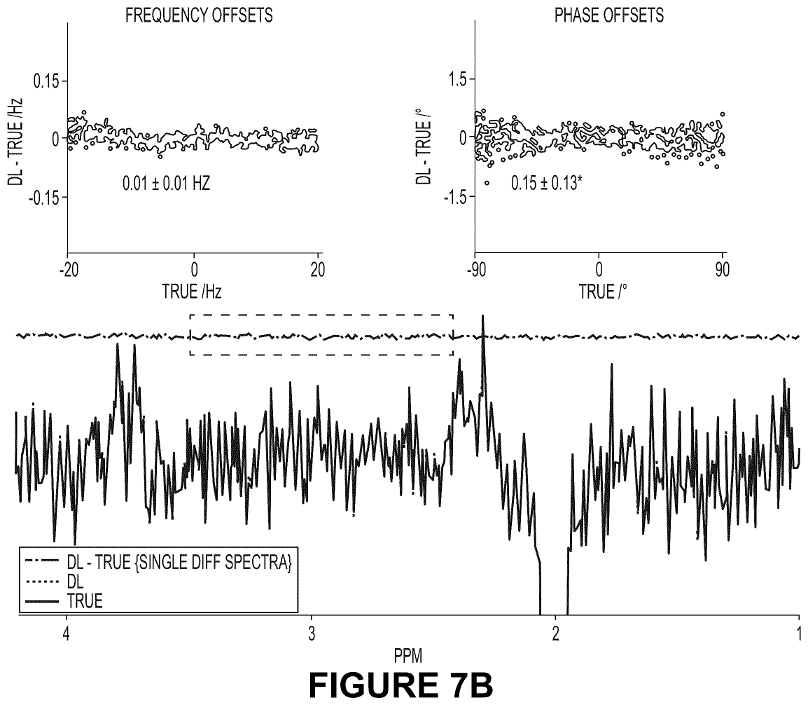

The performance of the MLP-based approach (A) and the proposed CNN-based approach (B) for frequency and phase correction of the “Off Spectra” using the published simulated dataset were visualized as previously described (see BRIEF DESCRIPTION OF THE SEVERAL VIEWS OF THE DRAWINGS, FIG. 7). When visualizing the results generated from a single transient “Diff Spectra” example, it is clear that the CNN-based approach has smaller residues (i.e., the difference between the model prediction and the ground truth) highlighted in the dotted blue boxes (e.g., FIG. 7C, zoom in view of the residues between the ground truths and the MLP model prediction; FIG. 7D, zoom in view of the residues between the ground truths and the CNN model prediction).

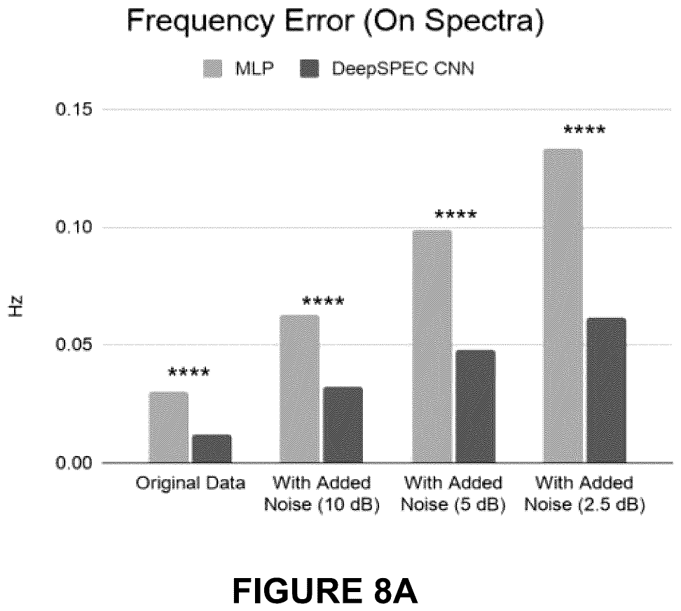

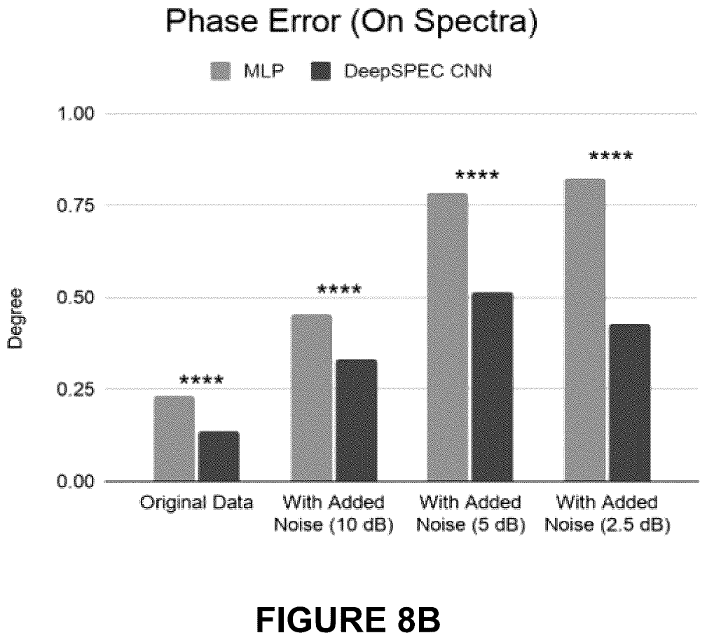

A further comparison of the MLP-based approach and the proposed CNN-based approach for frequency and phase correction of the “On Spectra” was carried out as previously described (see BRIEF DESCRIPTION OF THE SEVERAL VIEWS OF THE DRAWINGS, FIG. 8). This comparison is further detailed in Tables 2 and 3 below.

TABLE 2
Details of FIG. 8A.

| On Spectra | | | | |
|---|---|---|---|---|
| Frequency Error | Original Data | SNR = 10 dB | SNR = 5 dB | SNR = 2.5 dB |
| MLP (MAE) | 0.0291 | 0.0632 | 0.0995 | 0.1329 |
| DeepSPEC CNN | 0.0111 | 0.0324 | 0.0482 | 0.0616 |
| (MAE) | | | | |
| MLP (STD) | 0.0289 | 0.0550 | 0.0874 | 0.1134 |
| DeepSPEC CNN | 0.0092 | 0.0239 | 0.0352 | 0.0459 |
| (STD) | | | | |

TABLE 3
Details of FIG. 8B.

| On Spectra | | | | |
|---|---|---|---|---|
| Phase Error | Original Data | SNR = 10 dB | SNR = 5 dB | SNR = 2.5 dB |
| MLP (MAE) | 0.2262 | 0.4522 | 0.7859 | 0.8208 |
| DeepSPEC CNN | 0.1456 | 0.3338 | 0.5131 | 0.4277 |
| (MAE) | | | | |
| MLP (STD) | 0.2198 | 0.4036 | 0.6921 | 0.7055 |
| DeepSPEC CNN | 0.1295 | 0.2343 | 0.3873 | 0.3164 |
| (STD) | | | | |

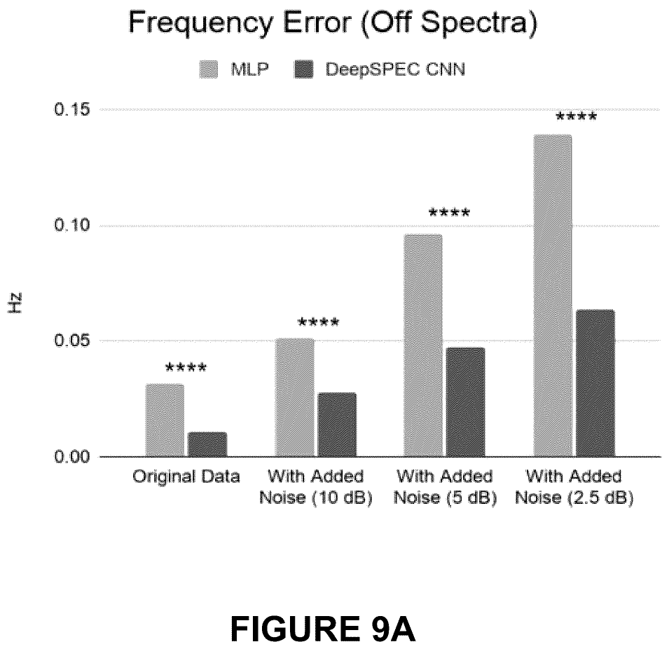

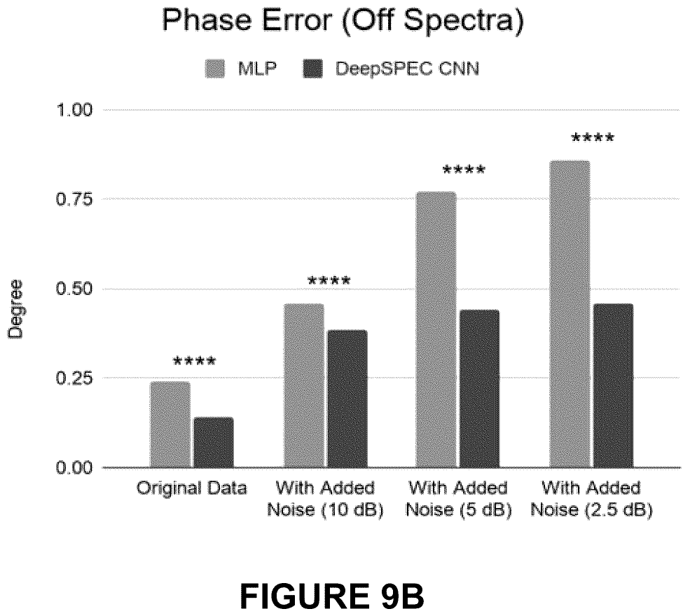

Still another comparison of the MLP-based approach and the proposed CNN-based approach for frequency and phase correction of the “Off Spectra” was carried out as previously described (see BRIEF DESCRIPTION OF THE SEVERAL VIEWS OF THE DRAWINGS, FIG. 9). This comparison is further detailed in Tables 4 and 5 below.

TABLE 4
Details of FIG. 9A.

| Off Spectra | | | | |
|---|---|---|---|---|
| Frequency Error | Original Data | SNR = 10 dB | SNR = 5 dB | SNR = 2.5 dB |
| MLP (MAE) | 0.0314 | 0.0648 | 0.0985 | 0.1385 |
| DeepSPEC CNN | 0.0113 | 0.0324 | 0.0439 | 0.0634 |
| (MAE) | | | | |
| MLP (STD) | 0.0321 | 0.0574 | 0.0794 | 0.1150 |
| DeepSPEC CNN | 0.0087 | 0.0239 | 0.0336 | 0.0474 |
| (STD) | | | | |

TABLE 5
Details of FIG. 9A.

| Off Spectra | | | | |
|---|---|---|---|---|
| Phase Error | Original Data | SNR = 10 dB | SNR = 5 dB | SNR = 2.5 dB |
| MLP (MAE) | 0.2251 | 0.4579 | 0.7644 | 0.8559 |
| DeepSPEC CNN | 0.1483 | 0.4139 | 0.4419 | 0.4588 |
| (MAE) | | | | |
| MLP (STD) | 0.2153 | 0.4036 | 0.6391 | 0.7239 |
| DeepSPEC CNN | 0.1247 | 0.2713 | 0.3523 | 0.3463 |
| (STD) | | | | |

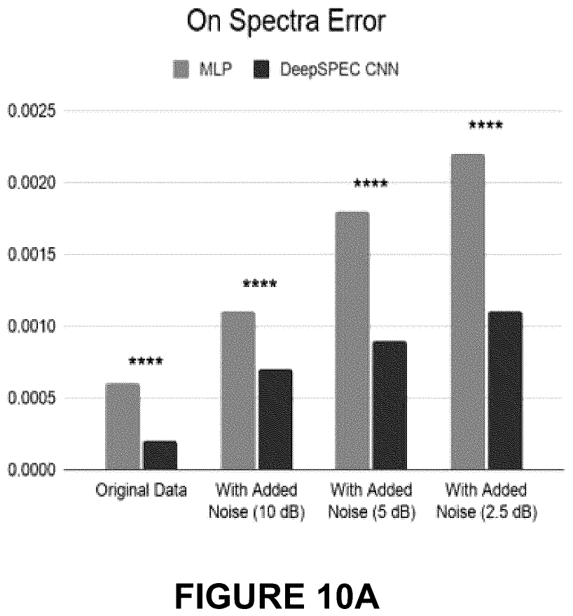

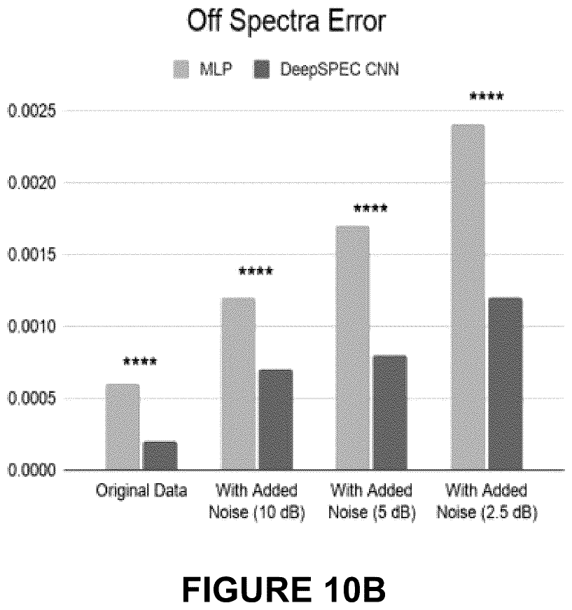

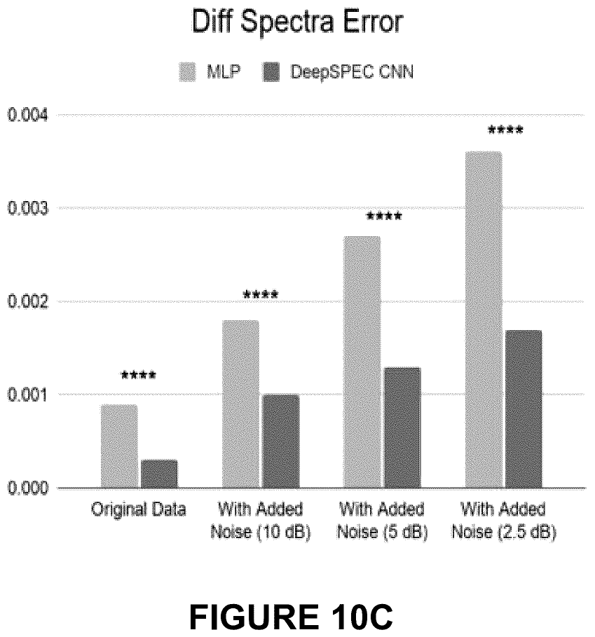

Yet another comparison between the MLP-based approach and the proposed CNN-based approach for frequency and phase correction of both the “On Spectra” and the “Off Spectra” was carried out as previously described (see BRIEF DESCRIPTION OF THE SEVERAL VIEWS OF THE DRAWINGS, FIG. 10). This comparison is further detailed in Tables 6-8 below.

TABLE 6
Details of FIG. 10A.

| On Spectra | | | | |
|---|---|---|---|---|
| Error | Original Data | SNR = 10 dB | SNR = 5 dB | SNR = 2.5 dB |
| MLP (MAE) | 0.00054 | 0.00113 | 0.00175 | 0.00224 |
| DeepSPEC CNN | 0.00023 | 0.00068 | 0.00091 | 0.00115 |
| (MAE) | | | | |
| MLP (STD) | 0.00050 | 0.00093 | 0.00140 | 0.00170 |
| DeepSPEC CNN | 0.00016 | 0.00040 | 0.00061 | 0.00077 |
| (STD) | | | | |

TABLE 7
Details of FIG. 10B.

| Off Spectra | | | | |
|---|---|---|---|---|
| Error | Original Data | SNR = 10 dB | SNR = 5 dB | SNR = 2.5 dB |
| MLP (MAE) | 0.00057 | 0.00110 | 0.00174 | 0.00238 |
| DeepSPEC CNN | 0.00023 | 0.00063 | 0.00081 | 0.00120 |
| (MAE) | | | | |
| MLP (STD) | 0.00056 | 0.00098 | 0.00132 | 0.00171 |
| DeepSPEC CNN | 0.00015 | 0.00040 | 0.00060 | 0.00080 |
| (STD) | | | | |

TABLE 8
Details of FIG. 10C.

| Diff Spectra | | | | |
|---|---|---|---|---|
| Error | Original Data | SNR = 10 dB | SNR = 5 dB | SNR = 2.5 dB |
| MLP (MAE) | 0.00088 | 0.00175 | 0.00274 | 0.00360 |
| DeepSPEC CNN | 0.00035 | 0.00099 | 0.00131 | 0.00178 |
| (MAE) | | | | |
| MLP (STD) | 0.00060 | 0.00106 | 0.00132 | 0.00184 |
| DeepSPEC CNN | 0.00017 | 0.00046 | 0.00066 | 0.00085 |
| (STD) | | | | |

DeepSPEC is a novel deep learning-based approach for frequency-and-phase correction (FPC) of MRS spectra. Embodiments of DeepSPEC contains two deep learning frameworks that employ both Convolutional Neural Networks (CNNs) and Transformers, to achieve fast and accurate FPC of single voxel PRESS MRS and MEGAPRESS data. In each deep learning framework, two neural networks, i.e., 1 for frequency correction, 1 for phase correction, can be trained and validated using a published simulated PRESS and MEGAPRESS MRS dataset with wide-range artificial frequency and phase offsets applied. DeepSPEC was subsequently tested and compared to the current benchmark—a “vanilla” neural network approach using multilayer perceptrons (MLP). Additional noise was added to these simulated datasets to investigate performance at different signal-to-noise ratio (SNR) levels.

The testing showed that DeepSPEC had a high level of performance and was more robust to noise. The DeepSPEC CNN framework was capable of correcting frequency offset with 0.01 Hz and phase offset with 0.14° absolute errors on average for unseen simulated data with moderate signal-to-noise ratio (SNR) (15 dB) and correcting frequency offset with 0.06 Hz and phase offset within 0.49° absolute errors on average with very low SNR (2.5 dB). These results demonstrate that CNNs and Transformers can be effectively implemented for pre-processing MRS data and demonstrated that DeepSPEC accurately predicts frequency and phase offsets at varying noise levels with the state-of-the-art performance.

### Example 9

### Implementation of CNNs for FPC (e.g., Automatic FPC) of Single Voxel MEGA-PRESS MRS Data.

The proposed CNN approach was tested on a published simulated dataset and an in vivo dataset against the benchmark neural network approach using MLP (18). The model achieved state-of-the-art performance and nearly optimal correction efficiency. The effect of additional noise of SNR=10, SNR=5, and SNR=2.5 on the FPC performance was investigated to further demonstrate that CNNs the efficacy of the proposed solution when dealing with spectra with a low signal-to-noise ratio (SNR). Additional offsets (small, moderate, large) were also applied to the in vivo dataset to demonstrate the utility of CNNs to accurately predict the spectral frequency and phase offsets in a real-life scenario.

Simulated Datasets: Embodiments simulate MEGA-PRESS training, validation, and test transients using the FID-A toolbox (version 1.2), with the same parameters as described in the previous work (18). The training set for the CNN model was allocated 36,000 OFF+ON spectra, the validation set was allocated 4,000, and 1,000 for the test set. Furthermore, additional spectra with lower SNRs (10, 5, and 2.5) were created by adding random Gaussian noise to the published simulated dataset respectively. The SNR values were computed by the ratio of the Cr peak signal relative to the noise standard deviation.

In vivo Datasets: In vivo data was retrieved from the publicly available Big GABA repository. Thirty-three MEGA-edited datasets were collected in total. 320 transients OFF+ON were used and tested on the proposed CNN model (DeepSPEC), all of which were acquired using a water suppression method (VAPOR) that generated positive water residual in the spectra.

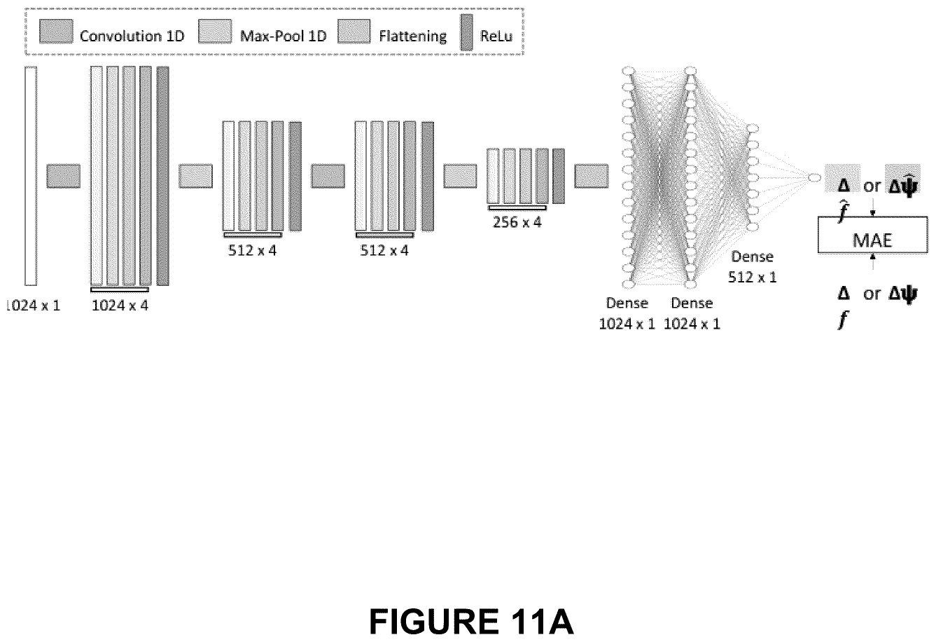

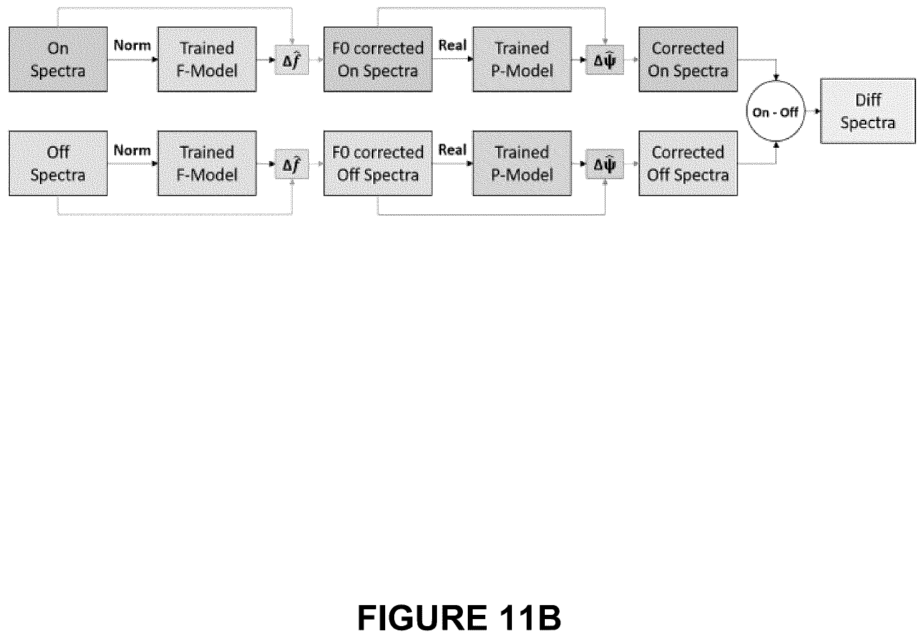

Network architecture: A CNN model was evaluated to compare its accuracy in frequency and phase offset prediction (FIG. 11A). Embodiments of the model are implemented as sequential networks (e.g., F-model, then P-model) where for each model, the same architecture is used. In other embodiments, the sequential networks may include different architectures. In an example, a magnitude spectrum can be used as input for the F-model and a real spectrum can be used as input for the P-model. Other suitable input for each model can be similarly implemented. In some embodiments, each network includes a channel with 1024 nodes as an input layer and a one-dimensional convolutional layer followed by a one-dimensional max-pooling layer. The latter layer can be subsequently connected to another series of one-dimensional convolutional layer followed by a one-dimensional max-pooling layer. The convolutional layer can include 4 kernels with a size of 3, and a max-pooling layer with a pool size of 2 with a stride of 2. A fully-connected layer (FC) with 1024, 512 can be used and a final fully-connected linear output layer of 1 node can be designed. Each hidden layer can be followed by a rectified linear unit (Relu) activation function to introduce non-linearity. An Adam optimizer can be used to train the neural network (e.g., with a 0.001 learning rate, or any other suitable learning rate). The output from each network can be the predicted offset of frequency and/or phase. In some implementations, each model was trained for 300 epochs with a batch size of 32, and the mean absolute error was used for the loss function. Other suitable architectures, hyperparameters, and configurations can be similarly implemented.

Network testing: On the scale of −20 to 20 Hz and 90° to 90°, uniformly distributed artificial offsets were first added into random pairs, including a frequency offset and a phase offset. Gaussian distributed noise was added to the dataset right before inputting into the network. The random pairs were then applied to the time-domain simulated transient. FIG. 11B demonstrates the mechanism of the network. In some implementations, the manipulation of the CNN networks for ON and OFF spectra was the same. For example, first, a Fast Fourier transform was applied to the uncorrected data and normalized them to the maximum signal in the spectrum. The peripheral 1024 samples were then cropped off, and the central 1024 samples were selected and the absolute value was taken to feed the network. Subsequently, the predicted frequency offset (Δf) was applied to the original transient to perform frequency correction. Next, a Fast Fourier transform was applied and frequency-corrected transient was normalized in the time domain. The central 1024 samples were selected and the absolute values was taken into the phase-offset-prediction network. Embodiments of the network predicted the phase offset (Δϕ) and the prediction was used for phase correction for the frequency-corrected transient. Finally, by subtracting the corrected OFF transients from the ON transients, an average difference spectrum was obtained. Other suitable techniques for correcting frequency and/or phase using implementations of the CNN network(s) can be similarly implemented.

Evaluation and comparison using in vivo dataset: The thirty-three MEGA-edited datasets were used as the test set of the CNN network. For a first comparison to the performance of the CNN model, SR performed FPC in the time domain. ON and OFF transients were registered to a single template, and the first n points of the signal were used, where n was the last point at which the SNR was higher than 5. The noise was computed from the bottom quarter of the signal, and n was set to a value larger than 100. The real and imaginary parts of the first n points were concatenated as a real vector and registered to the median transient of the dataset using MatLab function nlinfit (version 2019a, MathWorks, Natick, MA). The starting parameters for the subsequent transient were the same as the fitted parameters from 1 transient. The initial starting values for the offsets were 0 Hz and 0 degrees. In order to correct for the residual frequency and phase offsets, the transients were averaged, and global FPC was performed using Cr/Cho modeling (nlinfit) of this averaged spectrum after registration. Beyond SR, the performance of CNN and

MLP were also compared to the published model-based SR (mSR) result. Unlike SR, mSR uses a noise-free model as the template instead of the median transient of the dataset. Noise-free ON and OFF FID models were created in Osprey (version 1.0.0), an open-source MatLab toolbox, following peer-reviewed preprocessing recommendations. As another comparison for the CNN model, a benchmark neural network using MLP containing 3 FC layers (1024, 512, 1 node(s)) was tested. In this network, each hidden FC layer was followed by a ReLU activation function, and a linear activation function followed the output layer.

To test the network in different environments, in addition to the random offsets, additional artificial offsets were added to the in vivo data. There were 3 different kinds of additionally added offsets: 1. 0≤|Δf|≤5 Hz and 0°≤|Δϕ|≤20°; 2. 5≤|Δf|≤10 Hz and 20°≤|Δϕ|≤45°; 3. 10≤|Δf|≤20 Hz and 45°≤|Δϕ|≤90°. All additional offsets were sampled from a uniform distribution and added as random pairs of frequency and phase to each transient.

Hardware and software: Implementations were achieved using an Intel (R) Xeon (R) CPU E5-2650 v4 @ 2.20 GHz processor. The memory of the device was 125 GB and a GPU with a memory of 24 GB was used to train and assess the models.

Performance measurement: In the simulated dataset, the artificial offsets were set as the ground truth, and the mean absolute error between the ground truth and predicted value was used as the criteria to measure the network's performance. Moreover, the difference value between the true spectra and the corrected spectra was calculated and plotted using SR, MLP, and CNN. A Q score (18) was used to determine the performance strengths of each different methods, and it is defined as Q=1−σ²/(σ²+σ²), where σ₂ is the variance of the choline subtracted artifact in the average difference spectrum. If the Q score is greater than 0.5, it indicates that the first method performs better than the second method and vice versa.

### Example 10

### Spectra Analysis Between the MLP-Based Approach and the CNN-Based Approach for Varying SNRs

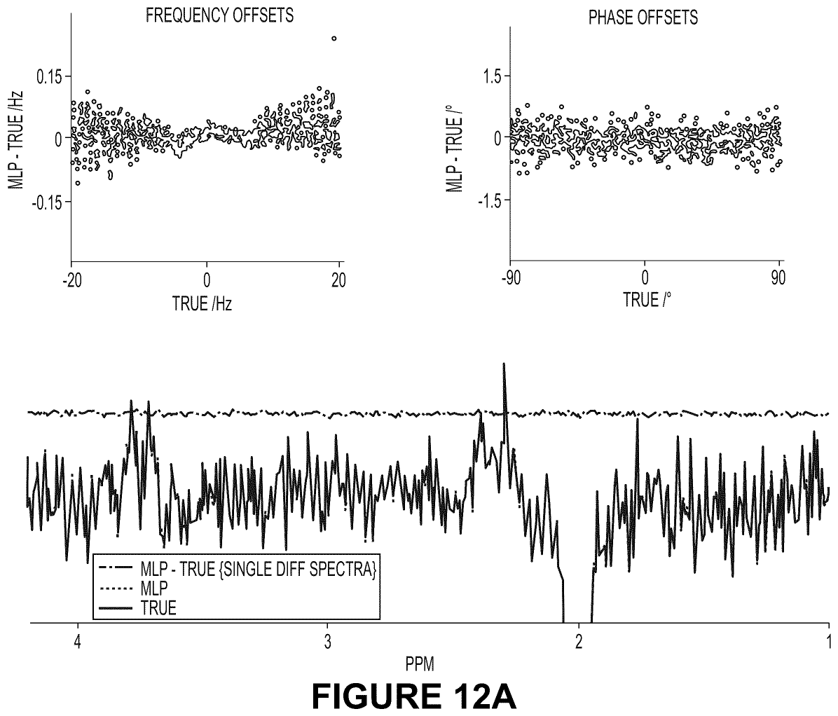

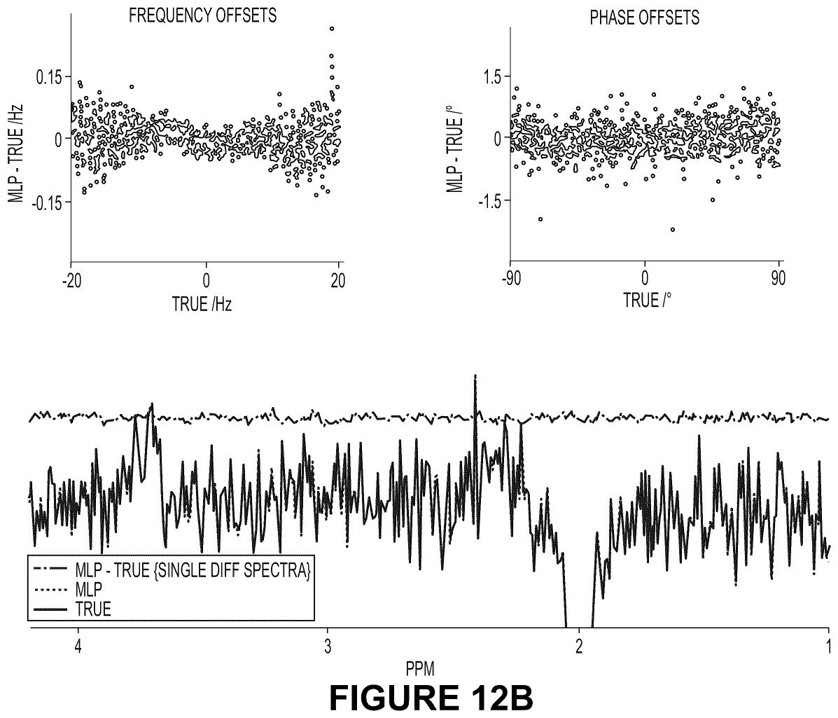

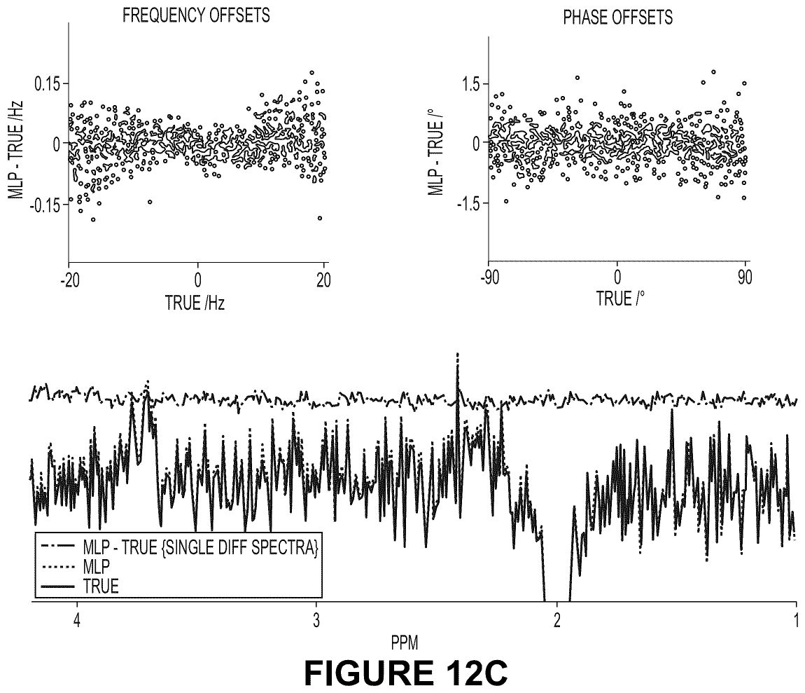

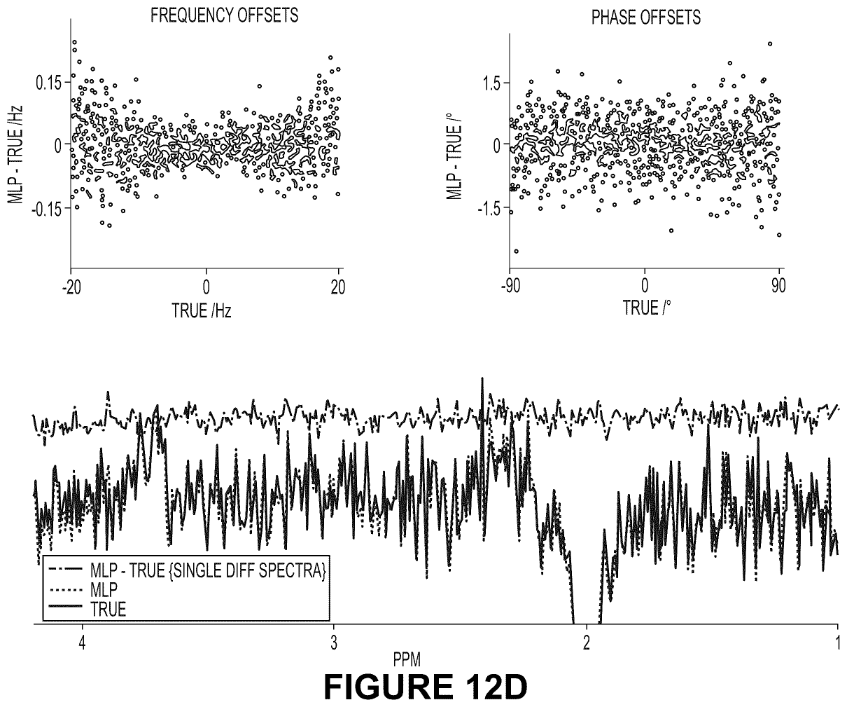

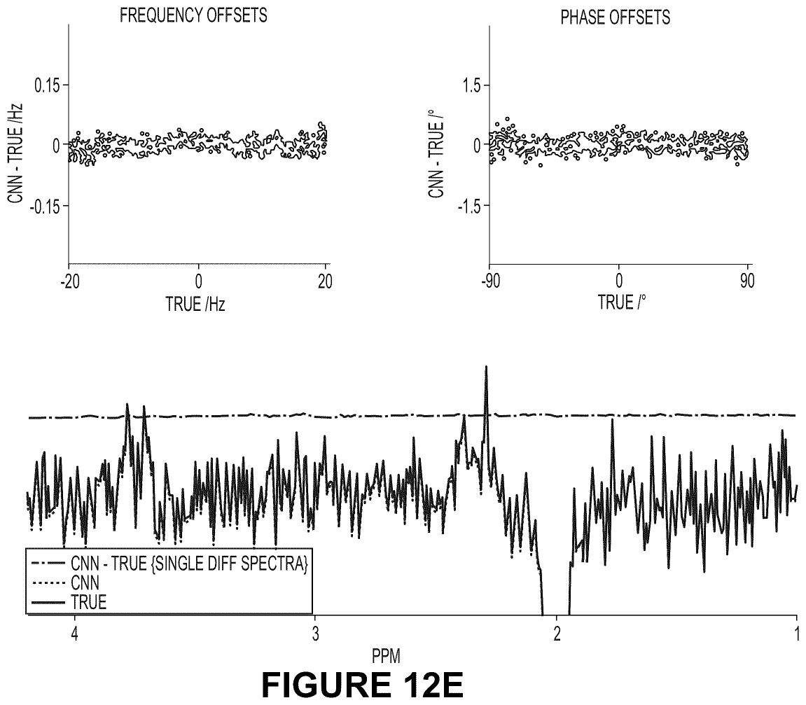

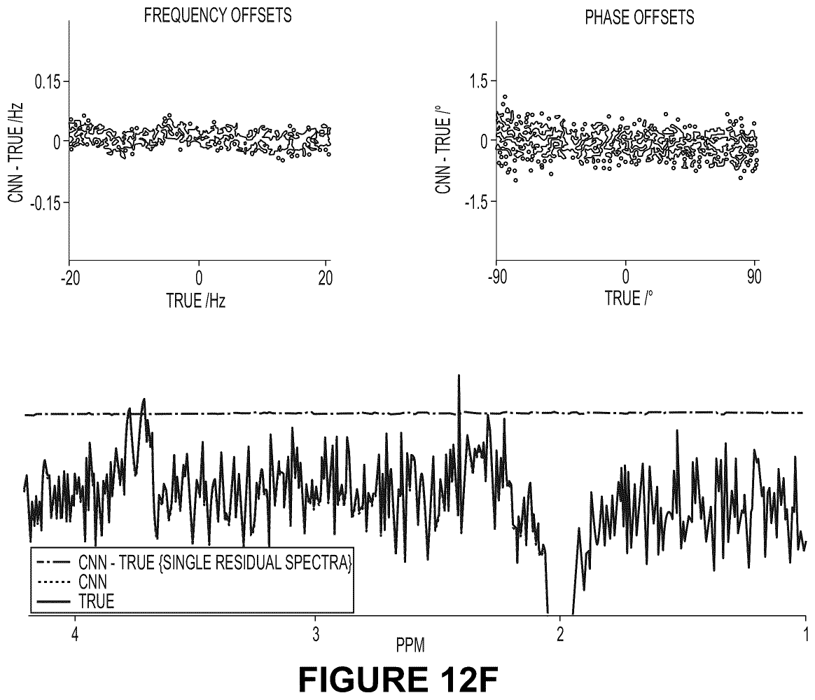

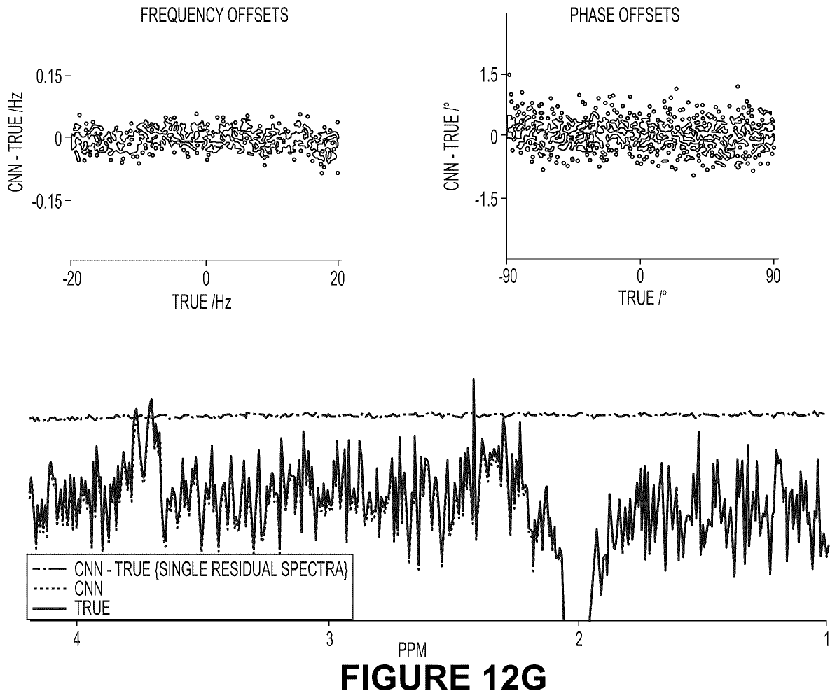

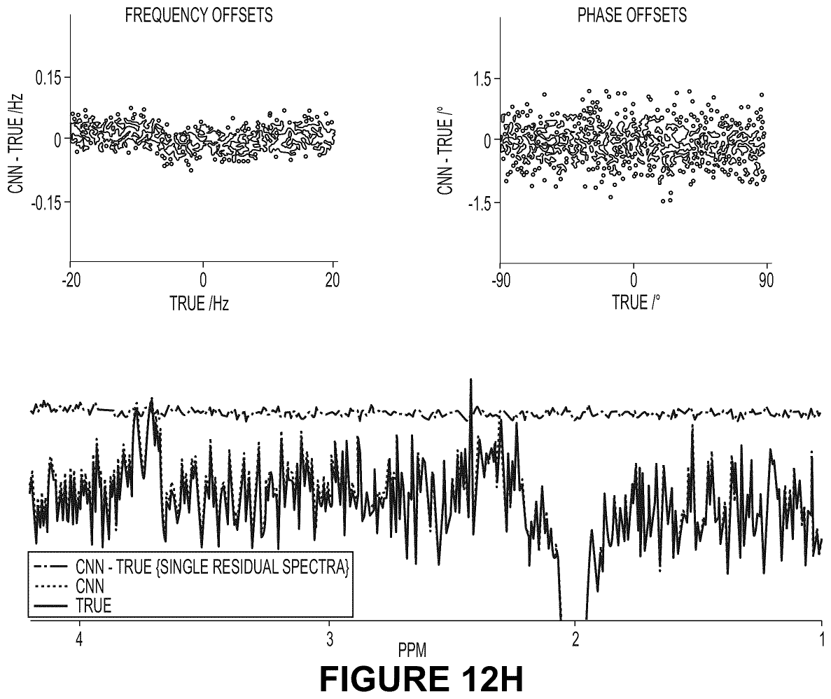

FIGS. 12A-12D illustrate results of an MLP-based approach on the 1000 transients (500 ON, 500 OFF) of the simulated test set as well as of the test set with lower SNR of 10, 5, and 2.5. FIGS. 12E, 12F, 12G, and 12H show the results of an embodiment of the CNN model on the same simulated test set as well as of the test set with lower SNR of 10, 5, and 2.5.

In each subfigure of FIG. 12, the frequency offset errors are plotted against their corresponding correct values, the phase offset errors are plotted against their corresponding correct values, the model-corrected difference spectrum and the difference spectrum corrected by the true offsets are plotted together, and the residues between the difference spectra are shown. For the original test set, the mean frequency offset error was 0.02±0.02 Hz for the MLP-based approach and 0.01±0.01 Hz for the CNN-based approach, and the mean phase offset error was 0.19±0.17° for the MLP-based approach and 0.12±0.09° for the CNN-based approach.

With a lower SNR of 10, the mean frequency offset error was 0.00±0.04 Hz for the MLP-based approach and 0.00±0.02 Hz for the CNN-based approach, and the mean phase offset error was 0.02±0.36° for the MLP-based approach and −0.08±0.29° for the CNN-based approach. With a lower SNR of 5, the mean frequency offset error was 0.00±0.05 Hz for the MLP-based approach and −0.01±0.02 Hz for the CNN-based approach, and the mean phase offset error was 0.01±0.41° for the MLP-based approach and 0.01±0.34° for the CNN-based approach. With an even lower SNR of 2.5, the mean frequency offset error was 0.00±0.05 Hz for the MLP-based approach and 0.01±0.02 Hz for the CNN-based approach, and the mean phase offset error was 0.02±0.61° for the MLP-based approach and −0.07±0.44° for the CNN-based approach. FIG. 12 shows that the CNN-based approach had smaller errors within the frequency and phase ranges for all SNR levels tested.

### Example 11

### CNN-Based Approach and MLP-Based Approach Error Comparison

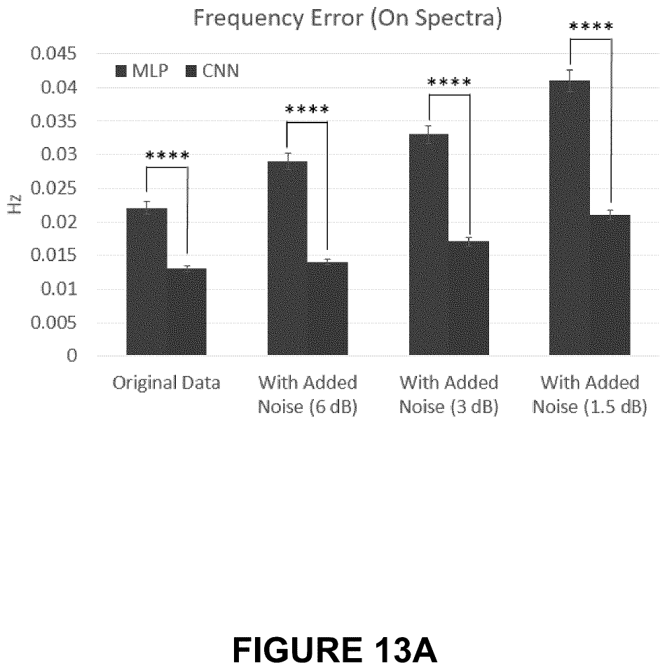

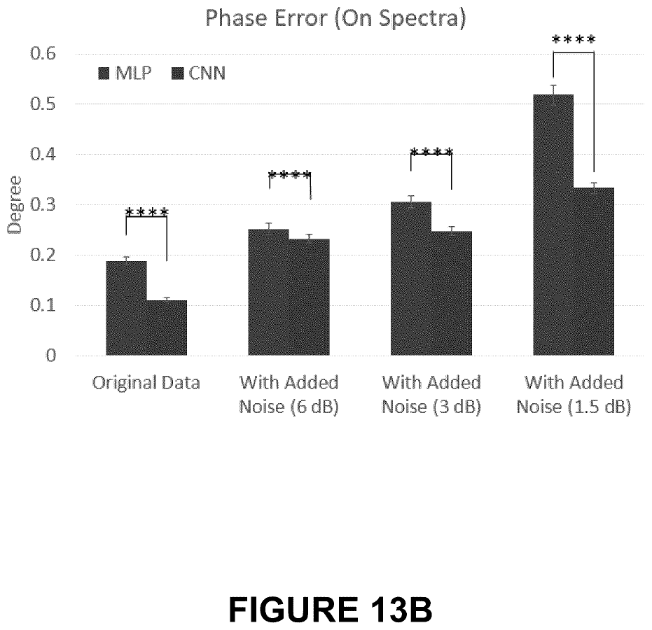

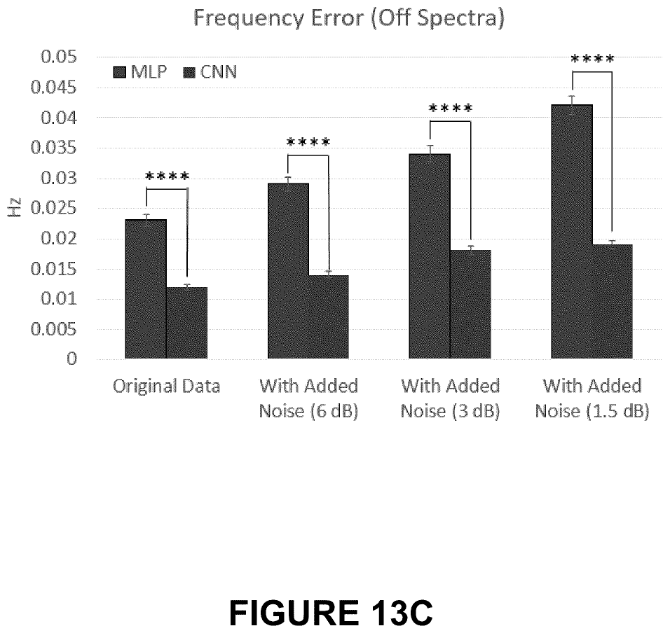

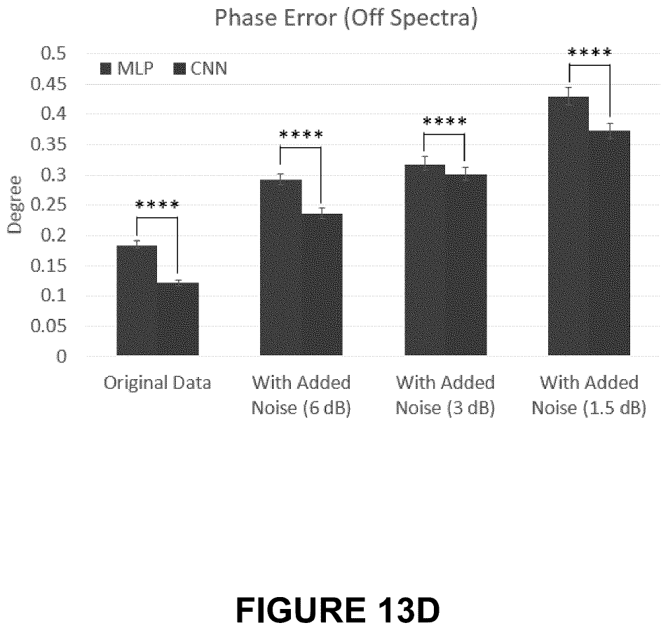

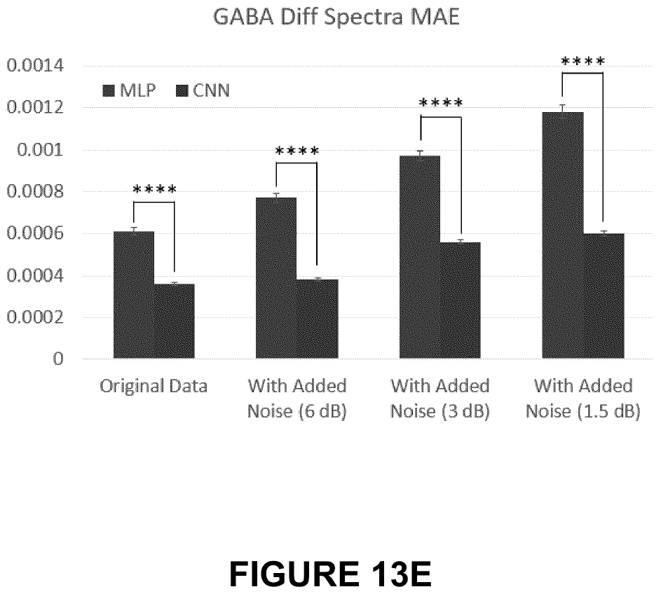

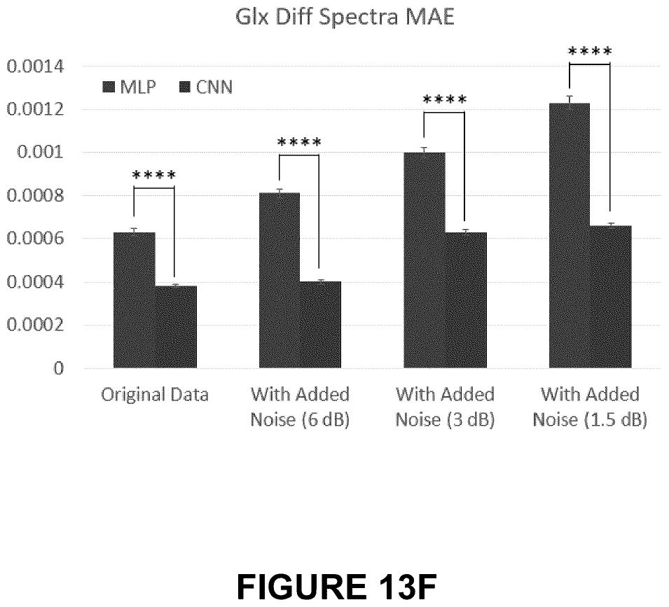

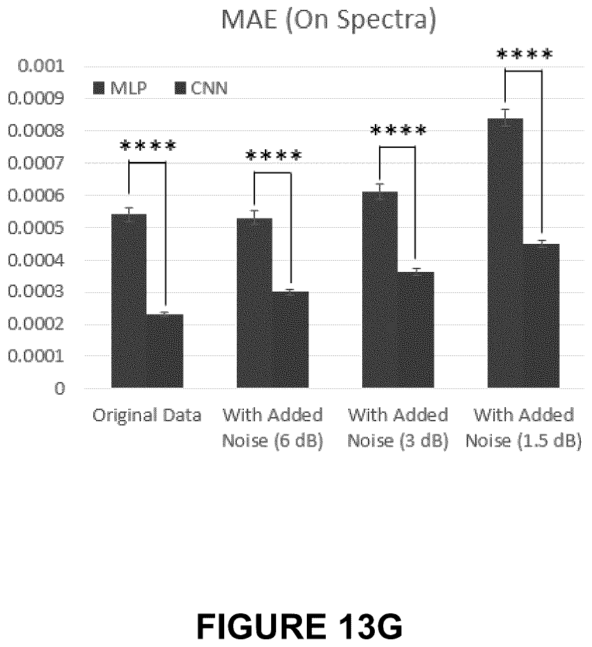

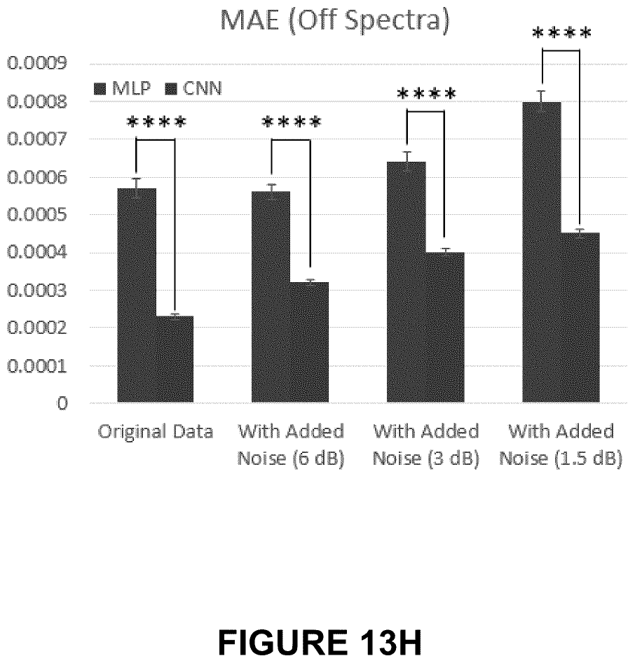

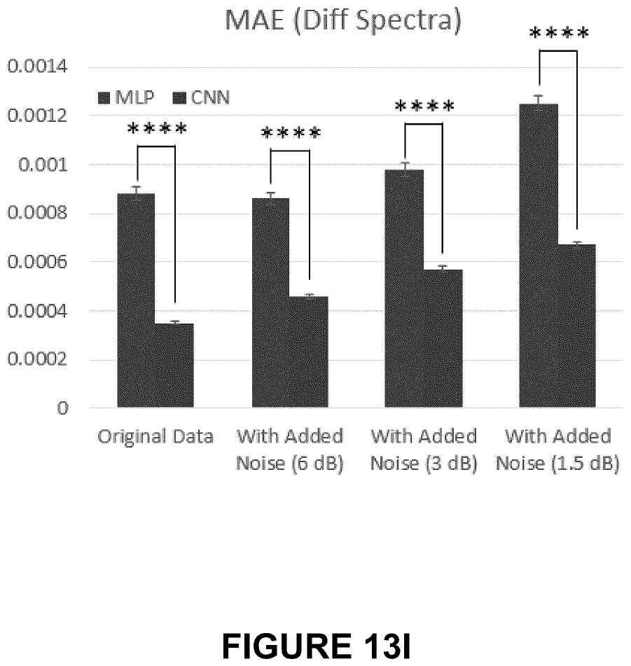

FIG. 13 illustrates a comparison of results of the MLP-based approach and the CNN-based approach for FPC of both the Off spectra and the On spectra of the simulated test set for varying SNRs. The CNN model showed significantly lower frequency estimation errors than the MLP-based model for the On spectra at varying SNRs (FIG. 13A) and for the Off spectra at varying SNRs (FIG. 13C). For example, with the test set at a low SNR of 2.5, the mean frequency offset error for the Off spectra was 0.042±0.036 Hz for the MLP-based approach and 0.019±0.015 Hz for the CNN-based approach, and for the On spectra, it was 0.041±0.036 Hz for the MLP-based approach and 0.021±0.016 Hz for the CNN-based approach. Similarly, it showed significantly lower phase estimation errors than the MLP-based model for the On spectra at varying SNRs (FIG. 13B) and for the OFF spectra at varying SNRs (FIG. 13D).

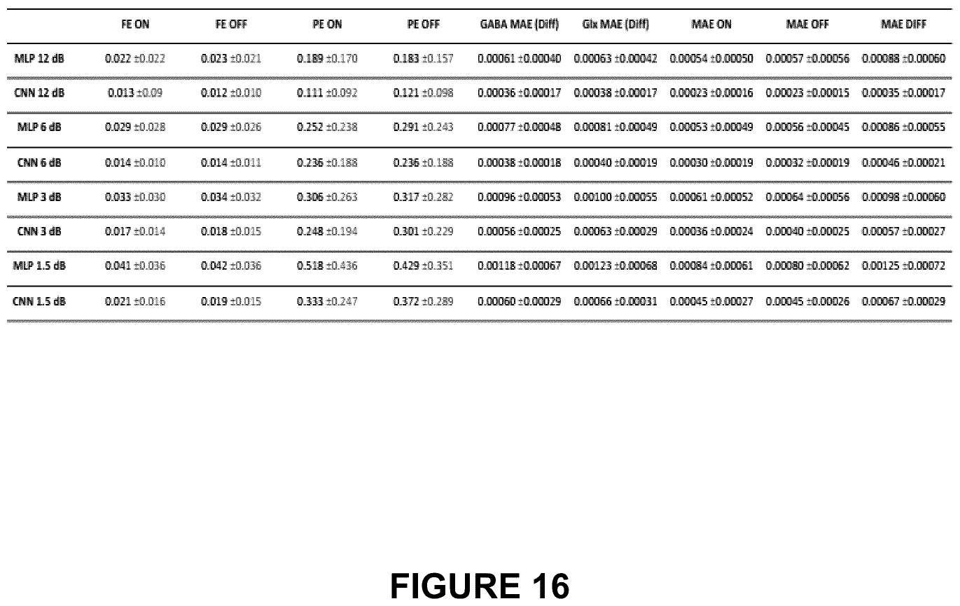

With the test set at a low SNR of 2.5, the mean phase offset error for the Off spectra was 0.429±0.351° for the MLP-based approach and 0.372±0.289° for CNN-based approach, and for the On spectra it was 0.518±0.436° for the MLP-based approach and 0.333±0.247° for the CNN-based approach. Additionally, by extracting the spectra interval corresponding to GABA (i.e., 2.8-3.2 ppm) and GLX (i.e., 3.55-3.95 ppm) from the derived mean difference spectra, these residual spectra errors were found to be lower with CNN model than the MLP-based approach (FIGS. 13E and 13F). Consequently, the residual spectra errors using CNN for the full spectra were significantly lower than those of the MLP-based model for the On spectra at varying SNRs (FIG. 13G), for the Off spectra at varying SNRs (FIG. 13H), and for the difference spectra between the MLP-based model and the CNN model at varying SNRs (FIG. 13I), indicating the overall higher performance of using CNNs with respect to MLPs as well as its robustness to noise (numerical results are shown in FIG. 16).

As observed in FIGS. 12 and 13, the original test set's results were better than the results of the test set with added noise of SNR=10, indicating that the noise level in the original test set must have been higher than SNR=10. Further computations confirmed that the test set's noise level was SNR=20.

### Example 12

### In Vivo Dataset

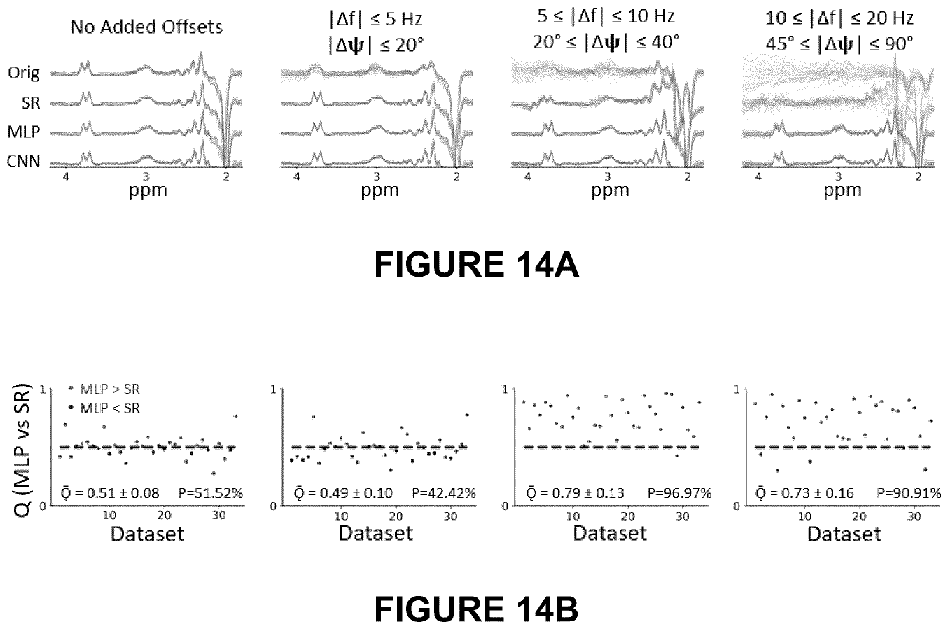

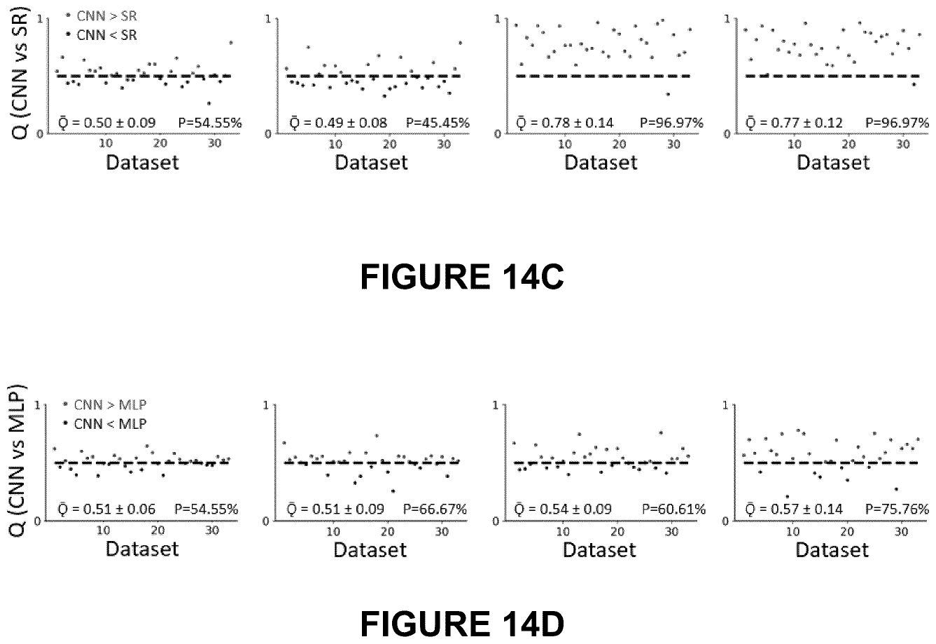

FIG. 14A illustrates the spectra resulting from the 33 in vivo datasets without (column 1) or with additional artificial offsets (columns 2-4) for no correction, MLP-based correction, CNN-based correction, and SR-based correction. When small offsets C1 were added, the three models performed similarly. The mean performance score of the CNN-based approach and the MLP-based approach was 0.51±0.09 (FIG. 14D, column 2) while it was 0.49±0.08 for the CNN-based approach and SR (FIG. 14C, column 2), and 0.49±0.10 for the MLP-based approach and SR (FIG. 14B, column 2).

The MLP-based approach performed better than SR for 42.42% of the 33 in vivo datasets, the CNN-based approach performed better than SR for 45.45% of the 33 in vivo datasets, and the CNN-based approach performed better than the MLP-based approach for 66.67% of the 33 in vivo datasets. As for medium offsets C2, the performance of the CNN-based approach and the MLP-based approach was comparable, but both models performed better than SR. The mean performance score of the CNN-based approach and the MLP-based approach was 0.54±0.09 (FIG. 14D, column 3) while it was 0.78±0.14 for the CNN-based approach and SR (FIG. 14C, column 3), and 0.79±0.13 for the MLP-based approach and SR (FIG. 14B, column 3).

The MLP-based approach performed better than SR for 96.97% of the 33 in vivo datasets, the CNN-based approach performed better than SR for 96.97% of the 33 in vivo datasets, and performed better than the MLP-based approach for 60.61% of the 33 in vivo datasets. When large offsets C3 were added, the performance of the CNN-based approach was better than the MLP-based approach and SR's. The mean performance score of the CNN-based approach and MLP-based approach was 0.57±0.14 (FIG. 14D, column 4) while it was 0.77±0.12 for the CNN-based approach and SR (FIG. 14C, column 4), and 0.73±0.16 for the MLP-based approach and SR (FIG. 14B, column 4).

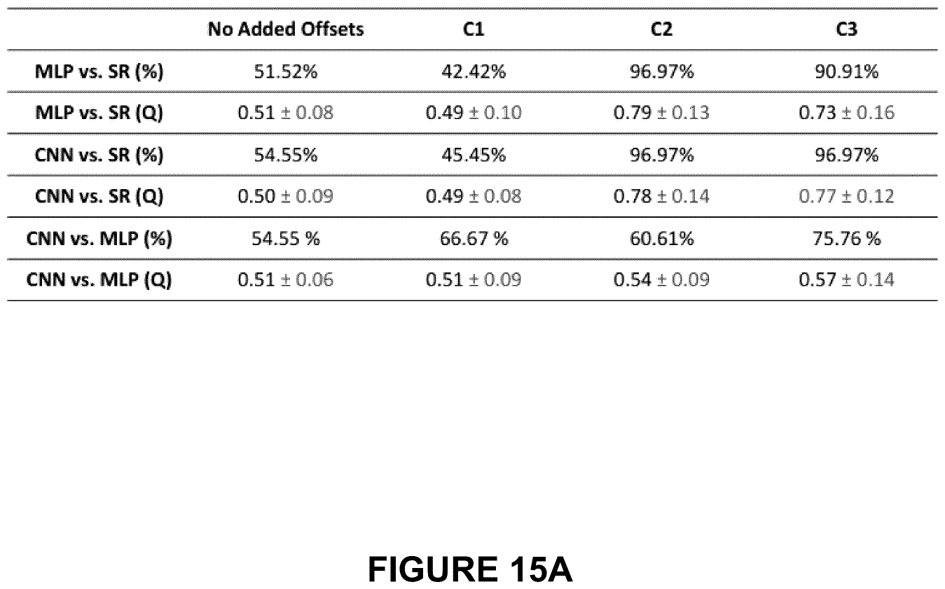

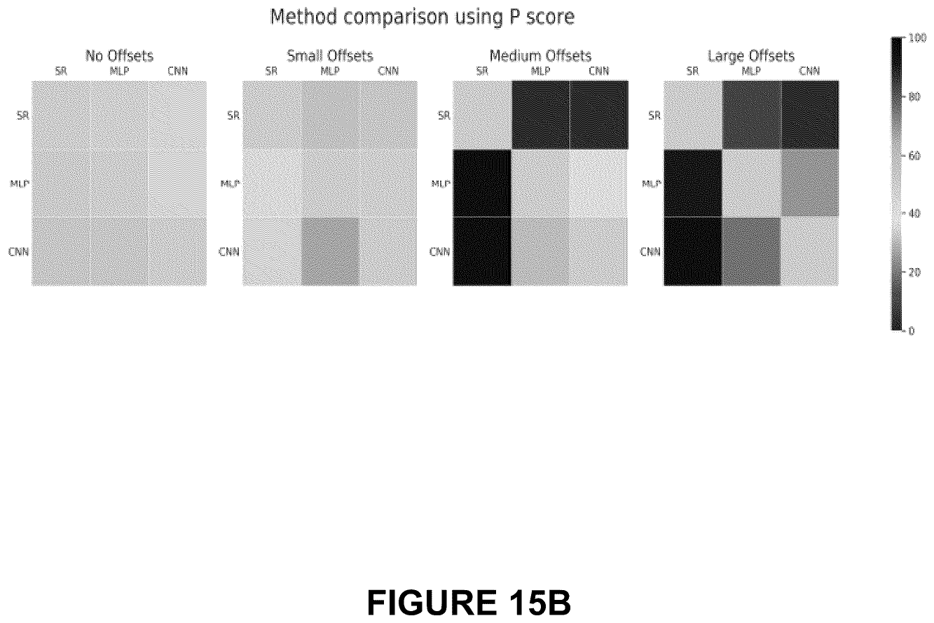

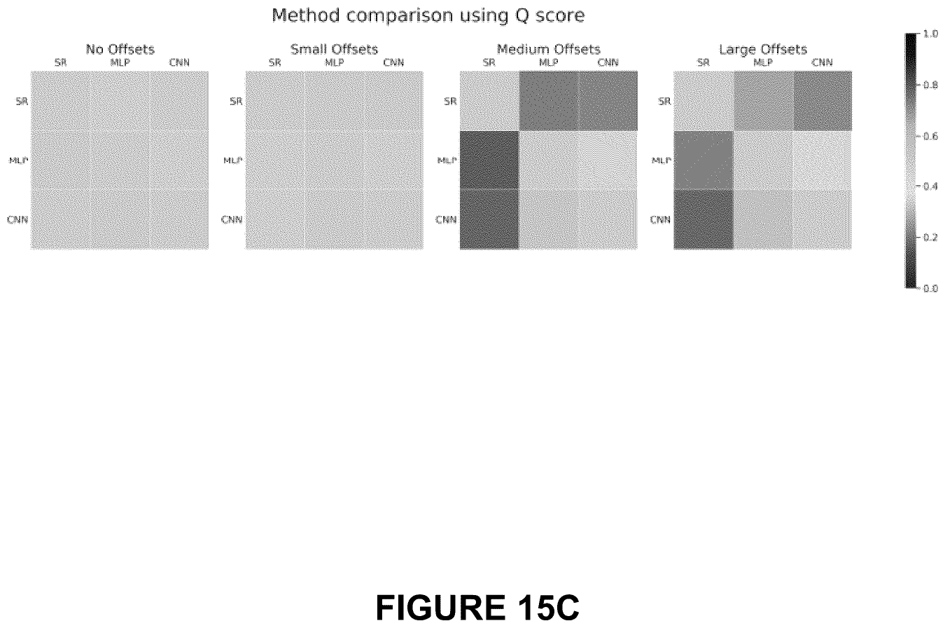

The MLP-based approach performed better than SR for 90.91% of the 33 in vivo datasets, the CNN-based approach performed better than SR for 96.97% of the 33 in vivo datasets, and performed better than the MLP-based approach for 75.76% of the 33 in vivo datasets. For small and medium offsets, CNN-corrected spectra, and MLP-corrected spectra (FIG. 14A, columns 2-3) are similar to the original spectra (FIG. 14A, column 1). However, for large offsets, the MLP-corrected spectra (FIG. 14A, column 4) slightly diverge from the original spectra, while the CNN-corrected spectra still are not noticeably different from the original spectra. The results are summarized in FIG. 15. Additionally, mSR exhibited the same performance pattern as the CNN-based approach with respect to the MLP-based approach, with a similar mean performance score of 0.51±0.13 for small offsets and of 0.57±0.11 for large offsets, and had a worse performance for medium offsets with a mean performance score of 0.52±0.13.

Frequency and phase correction can impact quantifying metabolites to analyze edited MRS data. For example, the resulting Diff spectra can impact the result for quantification. Many methodological options were considered, such as training a single network for FPC. Embodiments include separate networks to perform frequency-and-phase correction using a convolutional neural network to accommodate comparisons with the MLP-based approach. The inputs were kept consistent with a previous implementation as well, where the magnitude spectrum was used for the input for the frequency network and the real spectrum was used for the input for the phase network.

From FIGS. 12 and 13, it was determined that the CNN model performed better compared to the MLP-based model when using simulated data. FIGS. 12 and 13 show the CNN model has smaller correction errors (i.e., smaller mean absolute error and standard deviation) for both frequency and phase offset estimation compared to the MLP-based approach. Moreover, it can also be seen from FIG. 12 that for each offset, the subtraction of the prediction to the ground truth data points congregate near the y=0 line indicating the small deviation it had compared to the true value. In addition, the Diff spectra below also demonstrates that the CNN-based approach has smaller residual differences when the corrected spectra are subtracted from the truth spectra. The influence of noise was also found to have smaller effects in predicting the Diff spectra as smaller residues were observed when the spectra were subtracted. Especially at low SNRs (5 and 2.5), the difference was obvious, indicating that the MLP-based approach is not optimal for noisy data. From FIG. 12, a prediction of the innate SNR for the original dataset can be made.

By comparing FIG. 12A with other figures, it can be seen that 12E and 12F resemble each other. FIG. 12E shows a flat residual curve indicating the SNR could be greater than 10 and close to 20. Using the mean of the central data points of one of the truth spectra as the signal and the standard deviation of the remaining points as the noise, the SNR was computed to be approximately 20. Furthermore, FIG. 13 shows the mean absolute error to be smaller in all cases for the CNN-based approach with improved accuracy in larger offsets when compared to the MLP-based approach. This result can be seen for frequency, phase, and residual error where the two-tailed p-value shows the significance of this result. Moreover, using CNNs was found to be a better protocol when seeking complete residue subtraction. This can be seen from the smaller residual errors compared to the MLP-based approach when deriving the GABA and GLX spectra. This aspect can be impactful when a metabolite concentration needs to be quantified to determine a specific neurological disease, as a small difference may result into a wrong assessment.

From FIG. 14, the same conclusion can be made when using in vivo data. There is better performance in the CNN model as performance score P is higher and the output spectra are clearer compared to the MLP-based approach. This is well shown in the performance when we a large offset is added to the dataset, indicating the CNN-based approach can handle more varied offsets with higher accuracy. The benchmark was the comparison to SR, where both the MLP-based approach and the CNN-based approach performed better with no offset, C1, and C3 which show superior results with CNNs due to its larger P and Q value. When comparing the CNN-based approach to MLP directly (FIG. 14D), it can be shown that the CNN-based approach performed better than MLP in all cases for both performance score P and its Q value. Visual results can be seen in FIGS. 15B and 15C. Additionally, comparing the performance of mSR vs MLP (18), CNN vs MLP has a larger score for C1 and C2, indicating an improvement in performance for the small and moderate offsets for the CNN-based approach. Smaller standard deviation is also observed throughout the CNN-based approach performance which corresponds to its higher robustness.

CNNs demonstrated accurate quantification with training and validation for frequency and phase offset estimation in separate models. These observations show the utility the model has for MRS quantification. However, the magnetic field strength to produce the simulated dataset and to acquire the in vivo dataset was 3 T. CNN model performance over higher magnetic fields is yet unknown. In addition, different experimental conditions such as ex vivo, in situ, and in vitro should be assessed to further demonstrate CNN architecture utilities in MRS data preprocessing.

### Example 13

VGG-Based Models on the Classification of Schizophrenia Patients Using Structural Scans and Synthesized aCBV

Embodiments implemented the schizophrenia classification task with the benchmark model and the 887 structural whole-head (WH) TIW scans, following the same pre-processing and parameter settings as the implementation in prior studies. Embodiments also included a modified single-stream 3D VGG with batch normalization model (SE-VGG-11BN) to perform the schizophrenia (Schiz) vs. cognitive normal (CN) binary classification task with the input of only the 887 TlW structural whole brain (WB) scans. Eventually, the 887 TlW structural whole brain (WB) scans and the 887 CBV scans were fed into one modified double-stream 3D VGG model with batch normalization (dual stream SE-VGG-11BN) for schizophrenia classification. To demonstrate the effectiveness and generalization of the model, the benchmark model and dual stream SE-VGG-11BN were separately used for testing on a completely unseen private dataset named clinical high risk (CHR) which went through a data processing operation.

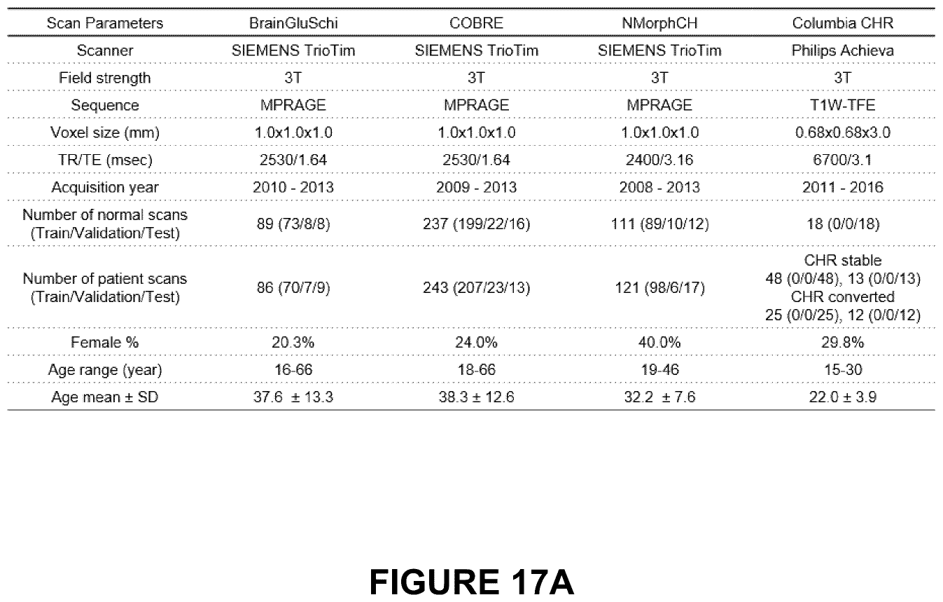

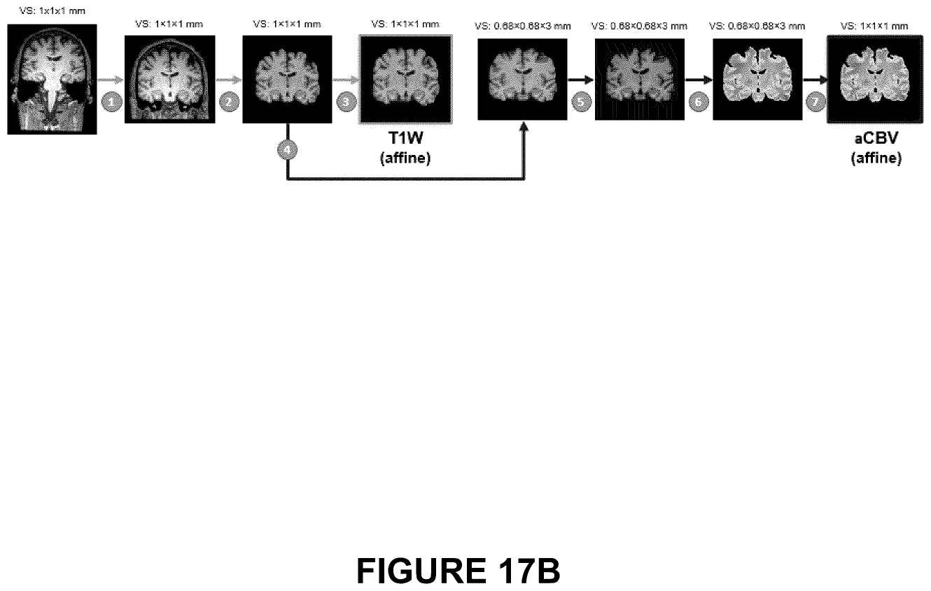

Data Selection and Pre-Processing: The neuroimaging data from patients with schizophrenia and normal subjects used in some implementations was downloaded from the SchizConnect database (http://schizconnect.org/). Data from three previous studies, COBRE (2015), NMorphCH (2016), and BrainGluSchi (2017), were collected and organized in this public database. This dataset was acquired to investigate the brain metabolism of patients with schizophrenia and includes structural and functional MRI images. The structural MRI images were obtained from 1998 to 2016, and the scanner field strength varied among datasets (1.5T and 3T). Images not applicable for training the deep network (e.g., those with excessive motion or noise or an image error) were excluded by visual inspection. In some implementations, data from the COBRE, NMorphCH, and BrainGluSchi, studies was fed into the candidate models since these scans were acquired under the same standard scanning machine (SIEMENS Trio) and field strength 3T. The data from these studies were high in quality and resolution, and the data acquisition time was relatively new, varying from 2008 to 2010. In addition, the data in these studies was abundant and appropriate for model training. Lastly, the data matched a standard input of the DeepContrast model since they were obtained under the 3T magnetic field. The detailed information of this data was illustrated in the FIG. 17A.

Data Pre-Processing: By pre-processing images, some confounding factors can be alleviated, enabling the model to handle entire images at once in some embodiments, and automatically determine the task-related pattern in the data. FIG. 11B illustrates a diagram of example pre-processing. In an example data pre-processing pipeline, firstly, the raw whole-head scans from three studies were registered to the MNI152 unbiased template by robust affine registration, which is denoted by step one. Following the whole-head scans registration, skull-stripping was applied on the whole head scans using Brain Extraction Tool to obtain whole brain (WB) MRI TIW scans, denoted by step two. In one path for standard MRI TIW scans, these whole brain MRI TIW scans were affine-registered to the MNI152 unbiased template, denoted by step three.

In another path, 1) the whole brain (WB) scans were affine-registered to the CU TIW MRI template to adapt the data to the standard input of DeepContrast model, denoted by step four, 2) the pixel intensity distribution was modified by dynamic histogram warping, denoted by step five, 3) the artificial CBV maps were generated from DeepContrast model, denoted by step six, 4) the generated CBV was resampled to match the resolution of prepared standard MRI TIW scans, denoted by step seven.

The MRI TIW scans were affine-registered and kept similar structures in roughly the same spatial location using one template as a standard. Thereby, the variance in brain features was reduced, such as the brain volume, while still preserving differences in local anatomy which may presumably reflect schizophrenia-related effects on brain structures. This operation could thus enable the model to focus on the decision-making patterns underlying the data.

After visual inspection of the preprocessed scans and removal of low quality scans on account of their potential negative effects on classification task, the prepared data with 887 WB MRI TIW scans and corresponding 887 synthesized CBV maps were selected and randomly assigned to 10 subsets, each subset with a similar number of samples. Randomization was performed on the subject level to prevent data leakage. To train and evaluate the model, eight out of ten subsets were randomly selected to make up the training set. Of the other two subsets, one was used as the validation set while the other was used as the test set. Consequently, the dataset was partitioned into the train/validation/test dataset by the ratio of approximately 8:1:1 in the subject level. The gender and age distribution in each subset are similar.

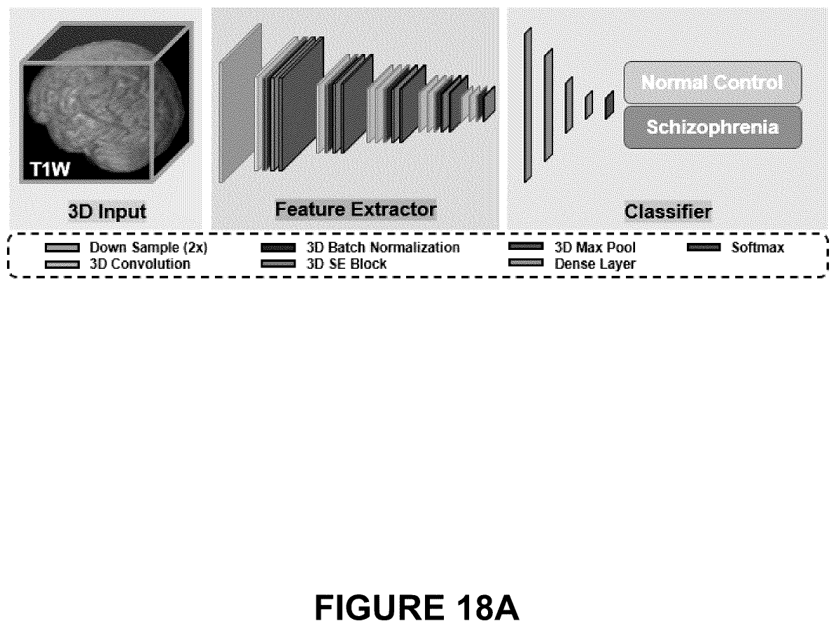

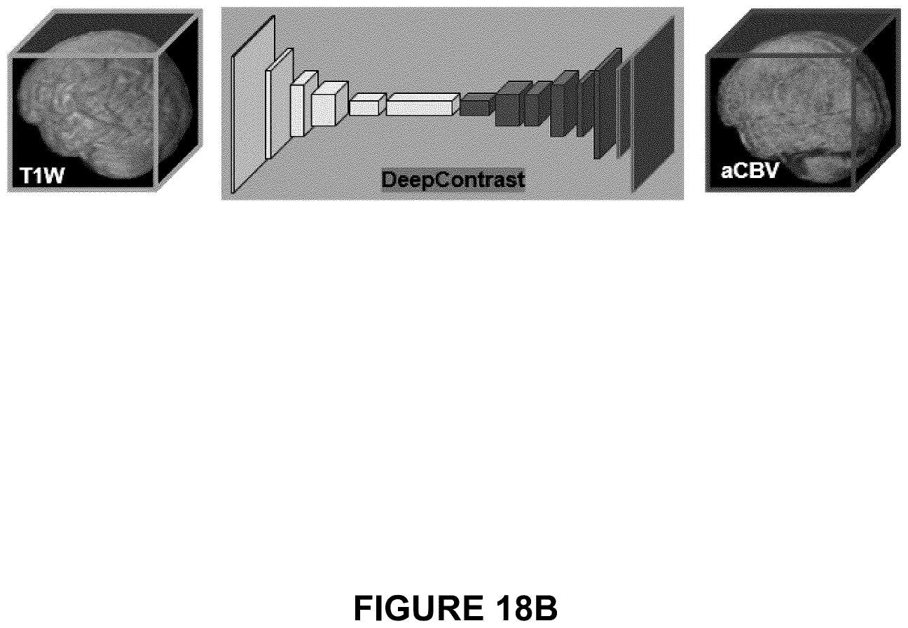

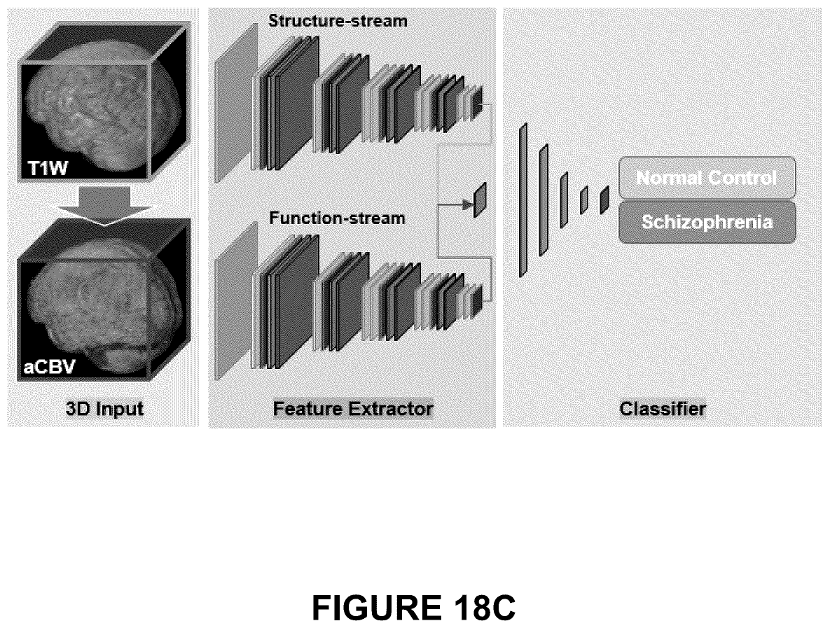

The DeepContrast Network: DeepContrast pre-trained network can be utilized to perform quantitative structural-to-functional mapping of MRI brain scans. DeepContrast takes in structural TIW scans and generates voxel-level predictions of the cerebral blood volume (CBV). The DeepContrast model (FIG. 18B) was applied on 887 MRI TIW scans and generated 887 corresponding artificial CBV (aCBV) maps.

Model Architecture and Implementation: For the schizophrenia classification tasks with one single input modality, the architecture 3D “VGG-11 with batch normalization” adapted from (VGG-19BN) was developed in the PyTorch platform (FIG. 18A). This modified single-stream 3D VGG model with batch normalization and squeeze-and-excitation block (SE-VGG-11BN) was composed of two basic components: a feature extractor and classifier. In the feature extraction part, there was one down-sampling operation followed by five 3D convolution blocks, with each block containing 3D convolution, 3D batch normalization, 3D squeeze-and-excitation (SE) operation and 3D max-pooling.

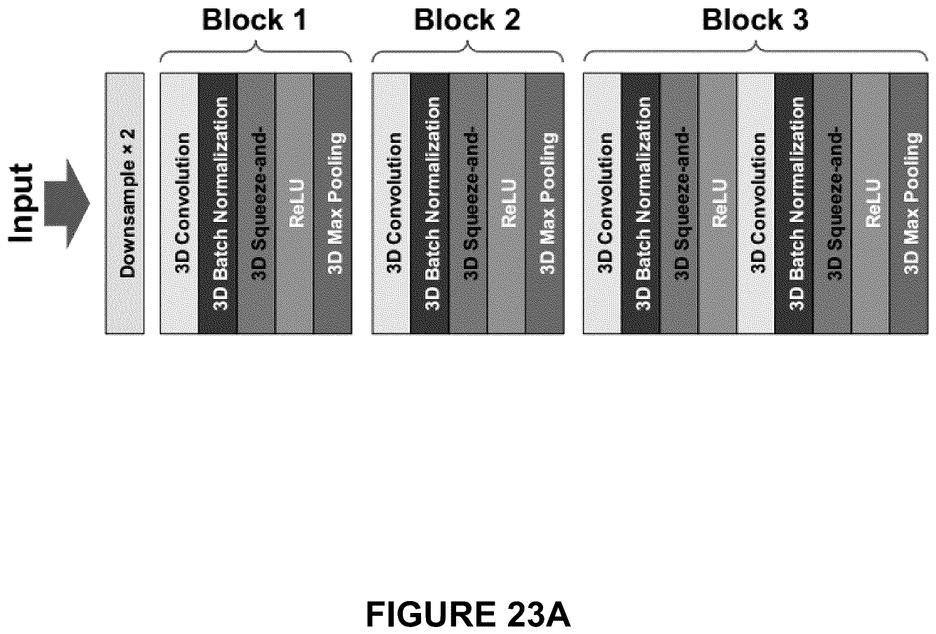

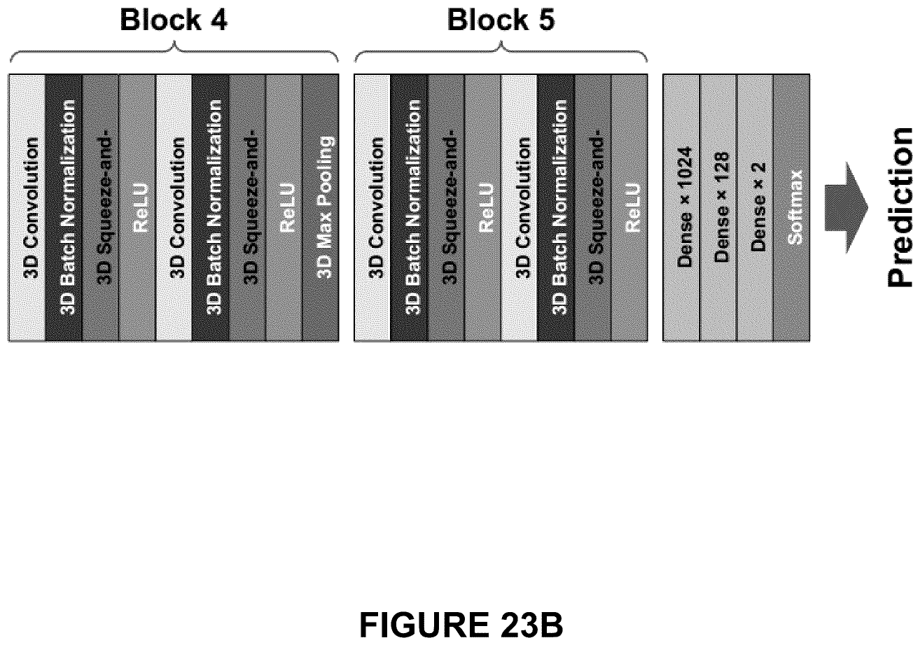

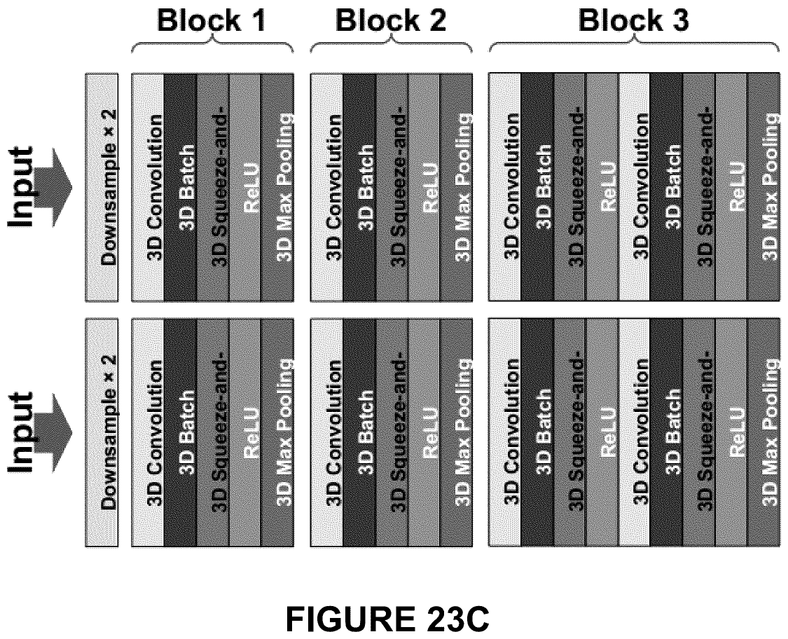

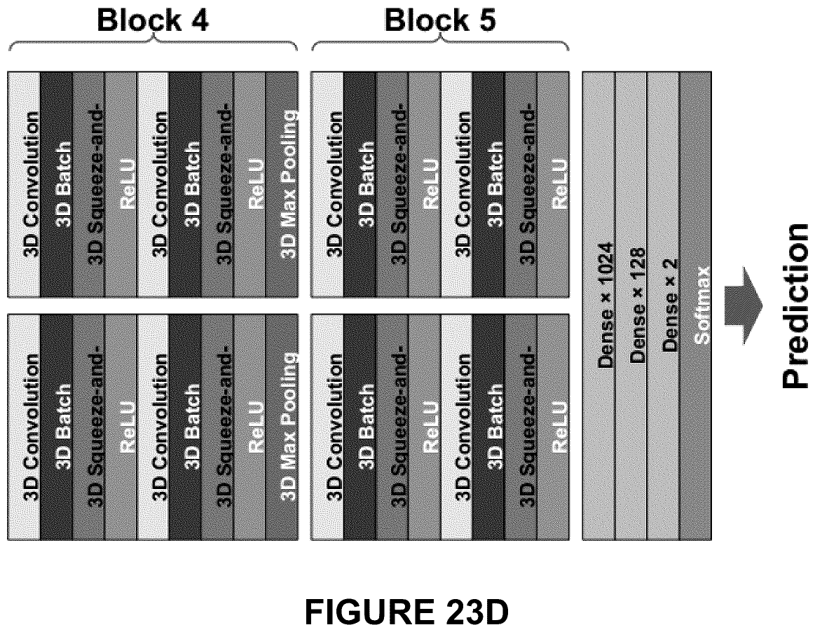

Details of the operations involved in the block were illustrated as follows. The kernel size was 3×3×3 and the padding and stride number were 1×1×1 in the 3D convolution. 3D batch normalization followed the convolution operation and could help accelerate deep network training by reducing internal covariate shift. An example difference of the modified 3D VGG models from a common VGG model lies in the introduction of the squeeze-and-excitation (SE) operation, which scales channels after convolution and batch normalization in each convolution block. This operation could improve channel inter-dependencies minimal additional computation cost in the existing architecture. A channel-to-channel ratio hyperparameter was set to 16 in the 3D SE operation. In the max-pooling, the kernel size and stride was 2×2×2. One slight difference from previous 3D convolution blocks was that the max-pooling in the last convolution block was omitted to support a larger receptive field to generate the class activation map. In the classifier portion, several dense layers were used to constitute the linear mapping. The activation functions in feature extraction and classifier were rectified linear units (ReLU) except for the classification output, which was a soft-max function. The details of the proposed models are illustrated in FIG. 23. Other suitable architectures, hyperparameters, and configurations can be similarly implemented.

Down-sampling X2 was applied on the input data with matrix size of 192×192×192 to preserve the image information while extending the possible training batch size. The aim of this operation was to achieve a balance between resolution and the batch size. In some implementations, when both the TIW scans and synthesized aCBV maps were used as the input, each as a three-dimensional (3D) volume, the two volumes were inputted into two same but independent VGG streams. In an example, the extracted feature vectors from the two streams can be concatenated before the fully-connected layers. The two streams can be combined with different weights learned by the model (FIG. 18C). In some implementations, For any of these two architectures, whether single stream or double streams, the input can include the relevant 3D scan(s) while the output can be a continuous-valued number representing the predicted schizophrenia-likelihood (e.g., score that corresponds to a schizophrenia condition prediction) In the training phase, the initial learning rate was set to 0.0001 and batch size was 5.

The setting of batch size was chosen considering convergence speed and the memory limit. The loss function was binary cross entropy loss, and the Adam method was used to optimize the model parameters. Early stopping strategy was introduced to the train phase to avoid over-fitting. The number of epochs was set to 300.

Performance evaluation of the model: To evaluate the descriptiveness of the predicted Schiz-likelihood, receiver-operating characteristics (ROC) studies can be conducted to analyze the concordance between the model-generated classification and ground truth Schiz/CN labels. The ROC curves, one for each trained classification model, represent the classification performances at each potential numerical threshold to binarize the predicted Schiz-likelihood score. The sensitivity and specificity (the sum of whom peaks at the operating point), as well as the total area under the ROC curve (AUROC), demonstrate the effectiveness of the classification method. The significance of the difference among these ROC curves was calculated using DeLong's test [DeLong et al., 1988].

Evaluation of the model generalization: To demonstrate the generalization of the models, data from COBRE and NMorphCH studies was selected to train the model and data from BrainGluSchi almost with a similar acquisition configuration was used for evaluating the capability of model generalization. The same training strategies and hyperparameter settings were maintained in the experiment.

Generalization of the model to private unseen dataset: One private dataset involving CHR subjects was also collected and used for trained models tested in the experiment. The data was obtained in two stages, baseline and 2-year follow-up. On the baseline stage, 25 subjects with CHR and conversion to schizophrenia and 48 subjects with CHR but no conversion to schizophrenia (CHR stable) were assessed using the structured interview for Psychosis-risk Syndromes (SIPS) at the Columbia Center of Prevention and Evaluation at the New York State Psychiatric Institute. MR scans of these subjects were obtained. On the follow-up stage, the participants in the baseline stage were seen for follow-up visits including clinical interviews and SIPS evaluations every 3 months for up to 2 years or whenever a diagnosis of schizophrenia was suspected. MR scans of 13 subjects with CHR but no conversion to schizophrenia and 12 subjects with CHR and conversion to schizophrenia were obtained at that time. The details of the data are illustrated in FIG. 17A. In addition, 18 healthy control subjects were recruited for obtaining MRI T1 structure scans using the same imaging protocol as the CHR dataset. The CHR dataset went through the same standard pre-processing pipeline as the public dataset.

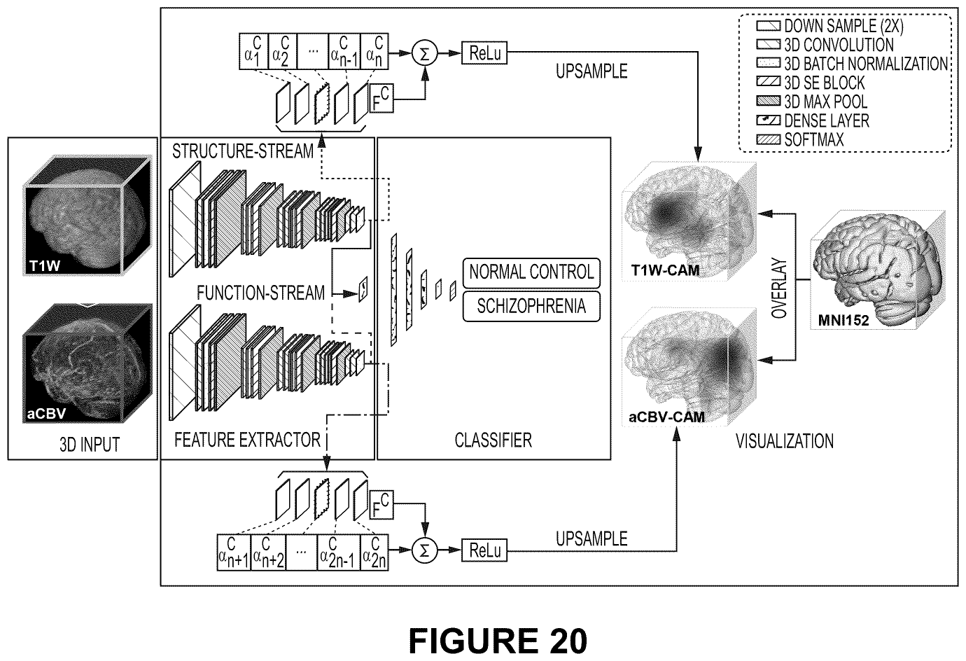

Explainability of Deep Learning Models with Grad-CAM: To validate the models, gradient class activation map (Grad-CAM) was introduced to check whether the model(s) focus on the task-related patterns instead of irrelevant information in the data. After excluding the possibility of the model focusing on meaningless regions in the data through applying a rough brain mask, the brain regions that had the most contributions to the schizophrenia classification task by were investigated visualizing the class activation maps (CAM). The process of generating aCBV maps is also illustrated in FIG. 20. The WB TIW scans and aCBV scans from all the subjects with schizophrenia were used to generate an averaged CAM for WB single-modality and dual modality input type.

### Example 14

Performance of 3D VGG-Based Models on the Classification of Schizophrenia Patients Using Structural Scans and Synthesized aCBV Maps

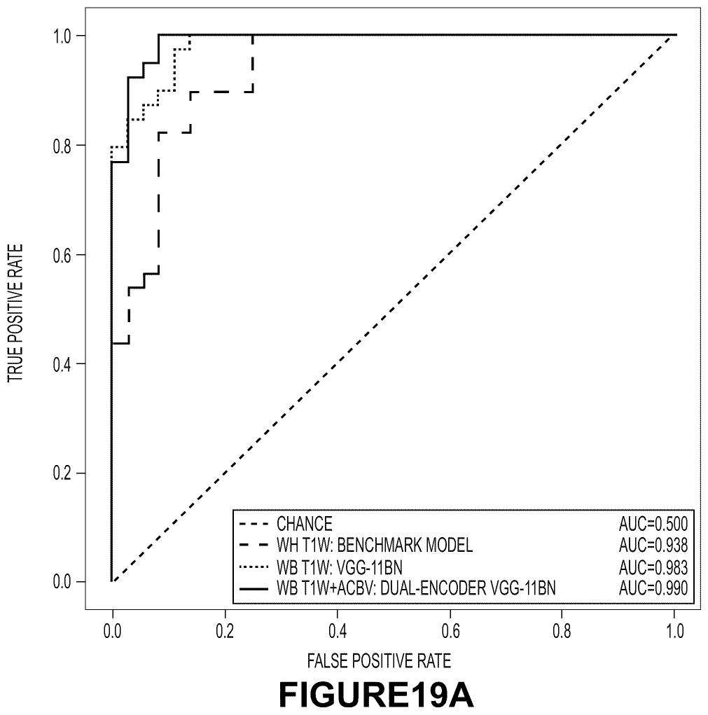

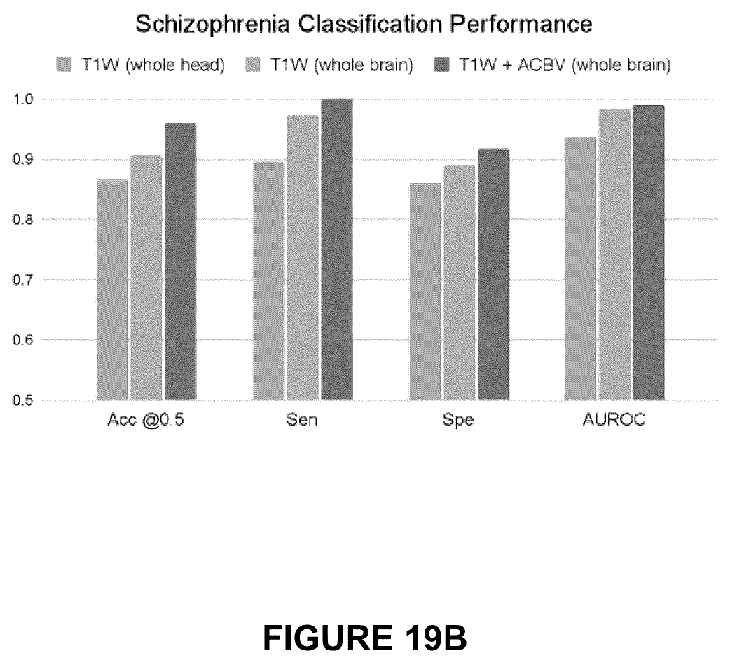

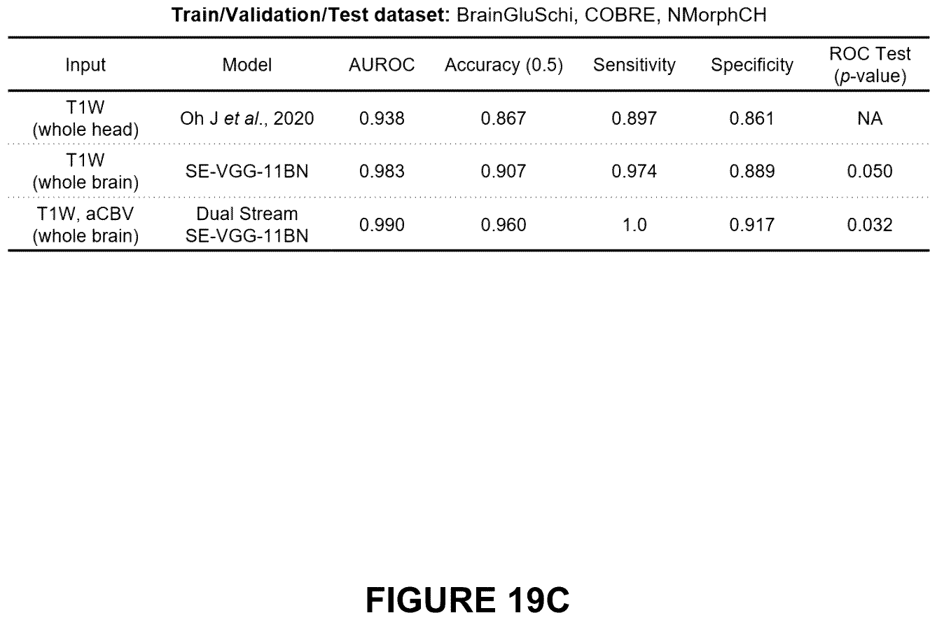

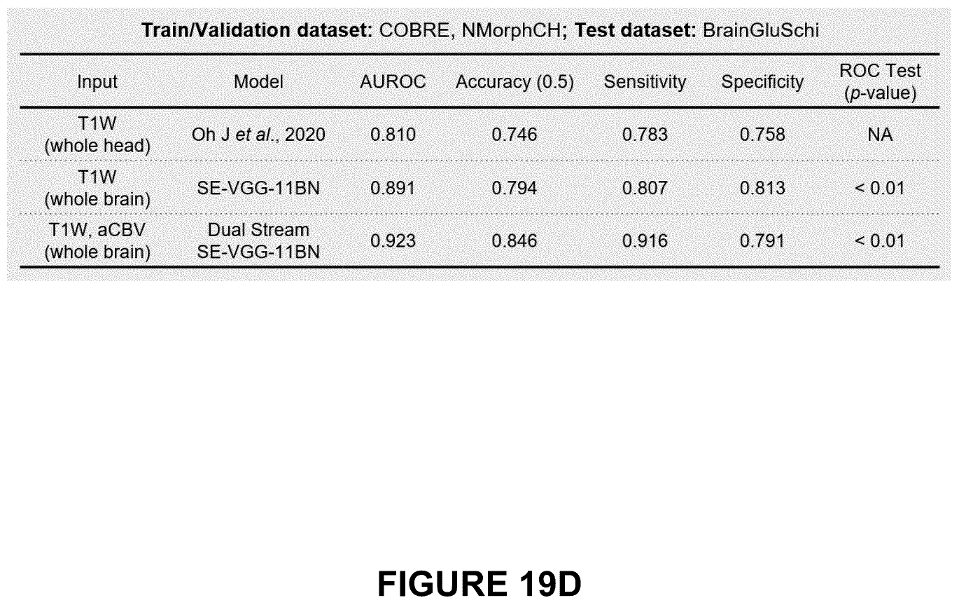

When training the model, it was discovered that the SE-VGG-11BN converged faster than the benchmark model on the training set and performed better than the benchmark model on the validation set. After training the models, the models were tested on the same stand-alone set of scans, 51 with schizophrenia and 49 without schizophrenia. Firstly, the SE-VGG-11BN model using structural T1 WB scans exhibited a better performance than the benchmark model across all metrics (Accuracy, Sensitivity, Specificity, AUROC). The quantitative performance metrics are summarized in FIGS. 19B and 19C. In addition, when inspecting the ROC curves (FIG. 19A), it can be seen that the dual stream SE-VGG-11BN model with the input of structural T1 WB scans and synthesized functional aCBV maps performed significantly better than the benchmark model only using structural T1 WH scans based on the DeLong's test at the level of p-value <0.01. Thirdly, superior AUROC performance of SE-VGG-11BN and dual stream SE-VGG-11BN over the benchmark model when the BrainGluSchi dataset was used only for test and the COBRE and NMorphCH datasets were used for the training and validation is demonstrated in FIG. 19D. These results validate the generality of SE-VGG-11BN and dual stream SE-VGG-11BN.

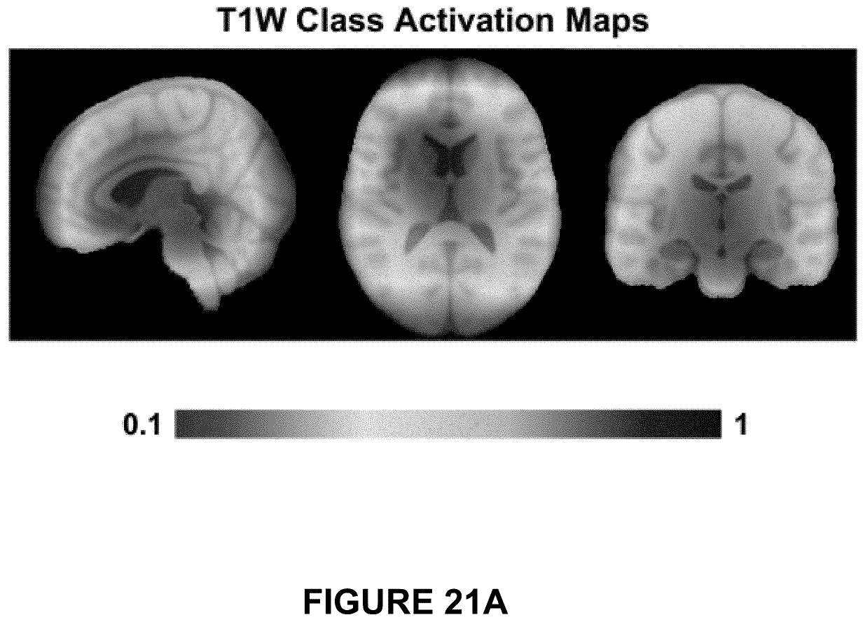

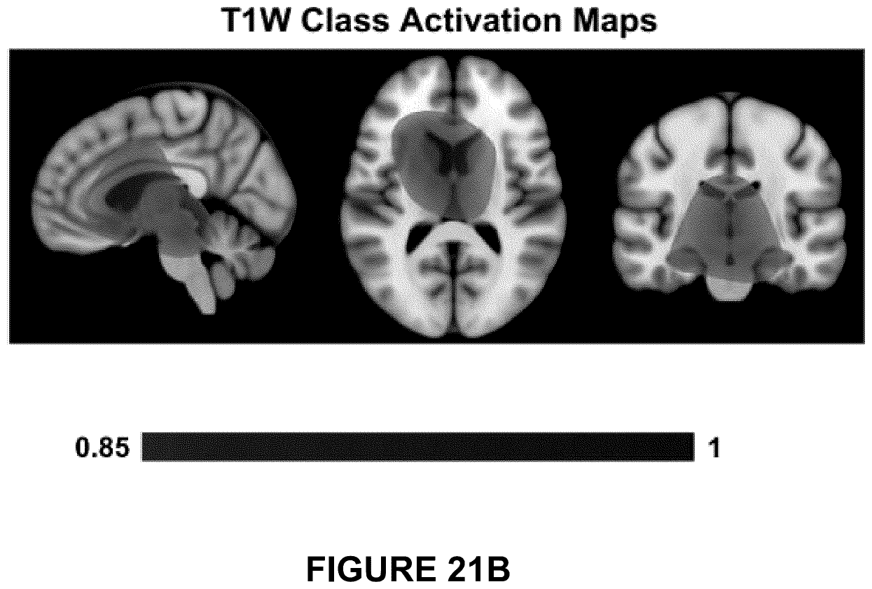

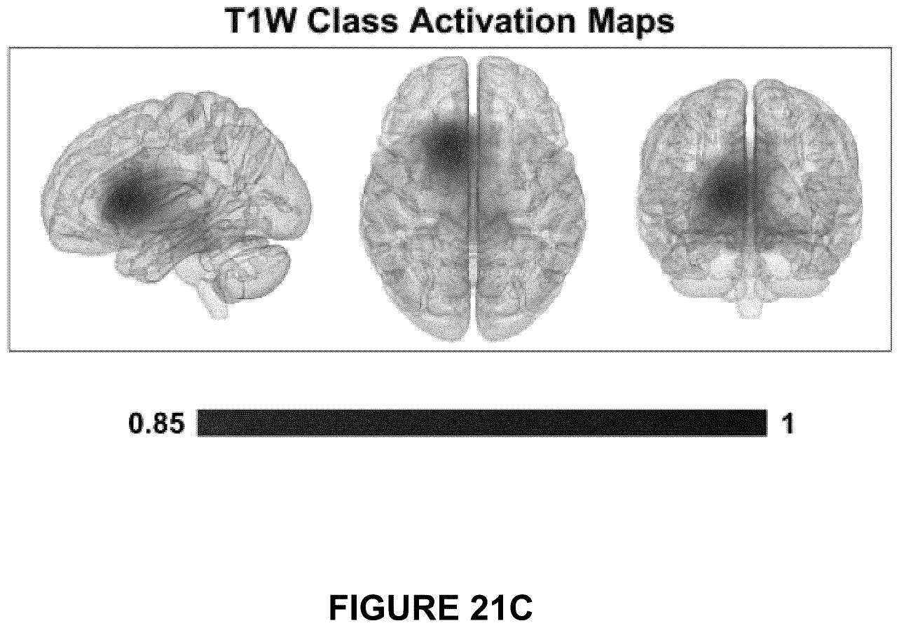

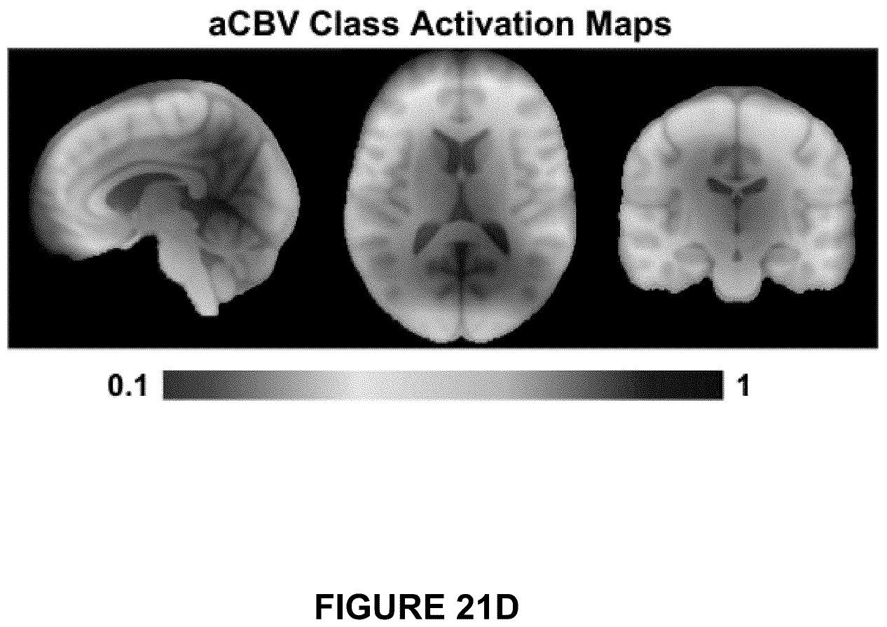

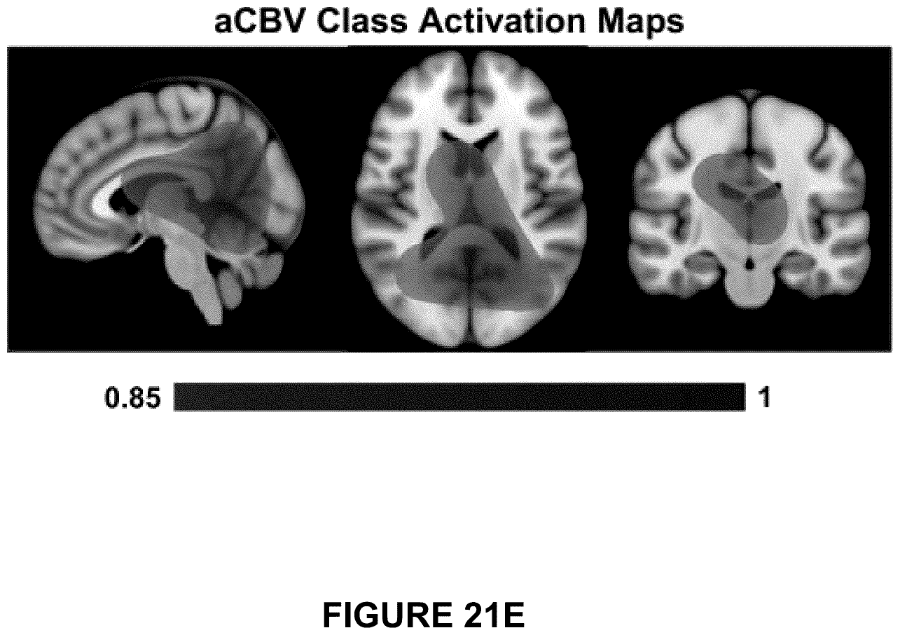

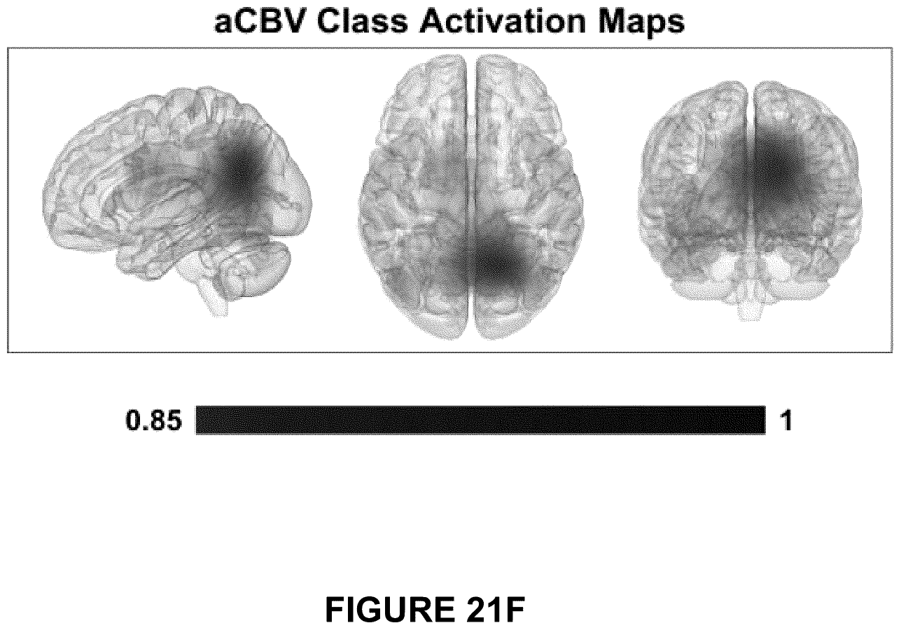

The class activation map of the best-performing classifier is illustrated in FIG. 21. The most highly contributing structural feature information comes from temporal and frontal lobe, while the most highly contributing functional feature information comes from parietal and occipital lobe and the ventricle area.

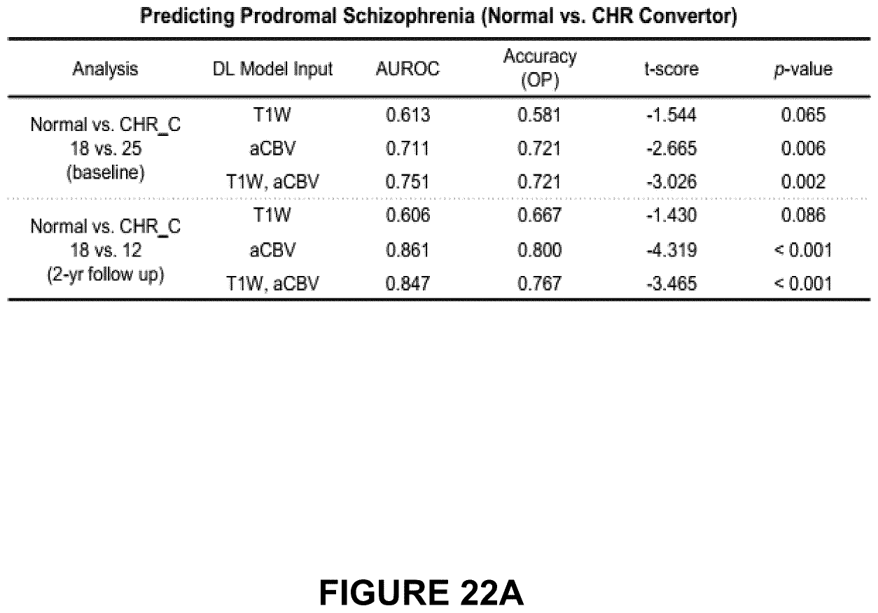

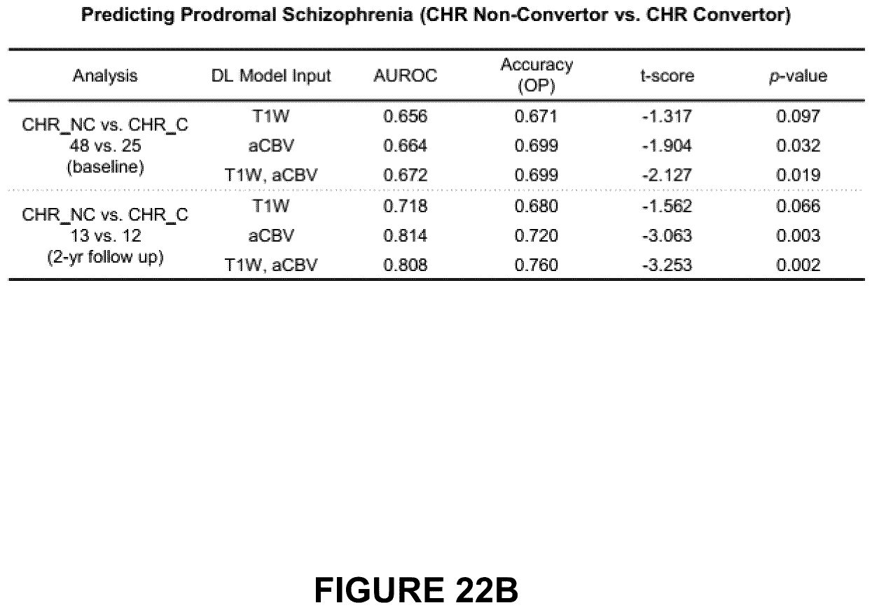

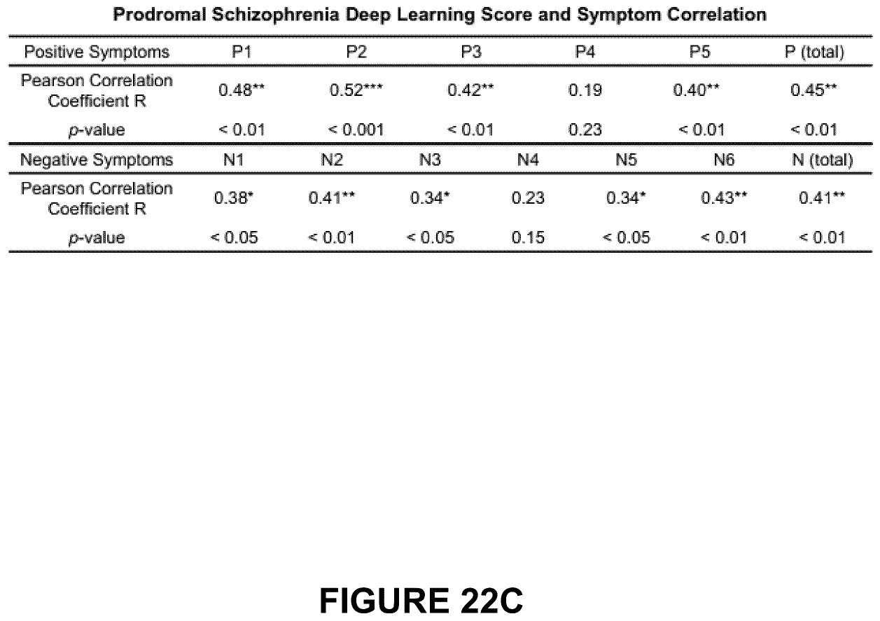

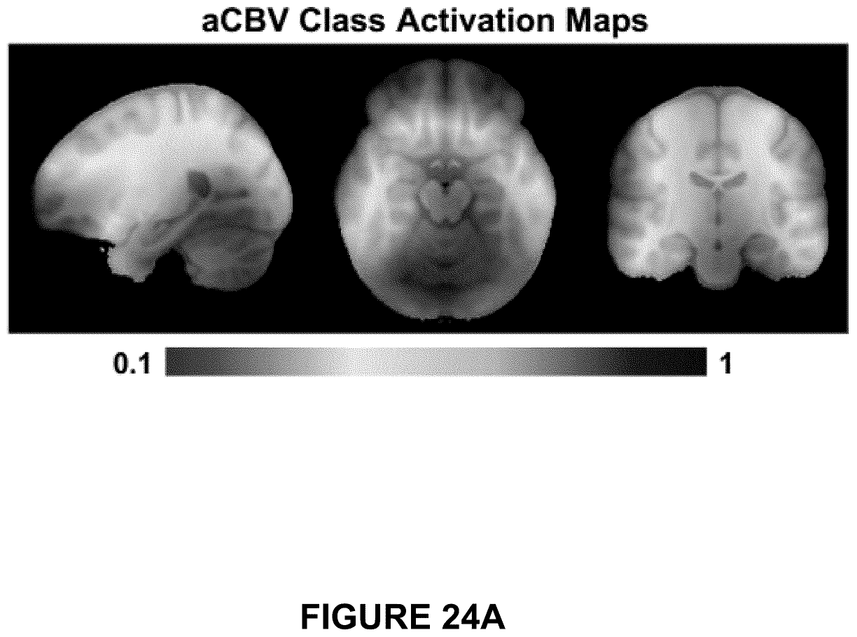

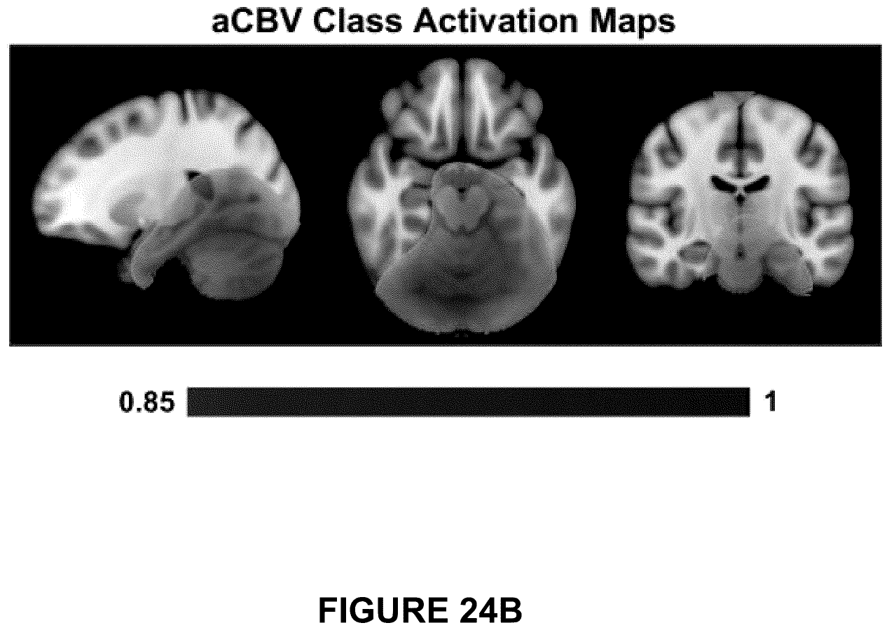

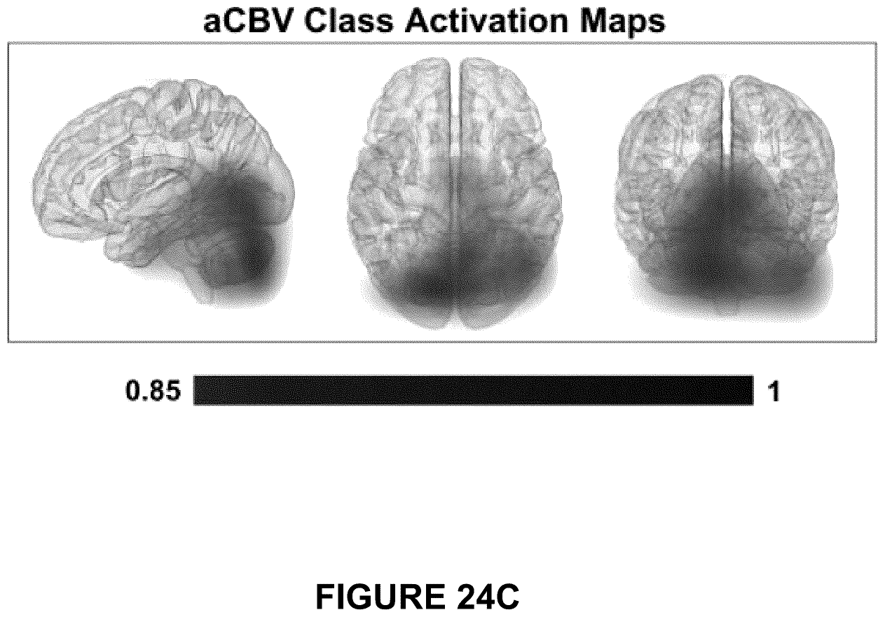

The classification results of the best-performing SE-VGG-11BN and dual stream SE-VGG-11BN models on the private CHR dataset are illustrated in FIG. 22. It was discovered that both the dual stream SE-VGG-11BN and the SE-VGG-11BN performed comparably whether testing on the group of Normal vs. CHR convertor or the group of CHR Non-convertor vs. CHR convertor in terms of AUROC at different stages. The performance of both models for schizophrenia classification noticeably improved after the two-year follow-up compared with the baseline stage. The class activation maps of synthesized aCBV maps from CHR dataset are provided in FIG. 24.

Pearson's correlation coefficients were calculated to compare clinical positive and negative symptom severity scores with deep learning predicted schizophrenia scores for the CHR dataset. The results were shown in FIG. 22C. The five positive symptoms are P1-unusual thought content/delusional ideas, P2-suspiciousness/persecutory ideas, P3-grandiose ideas, P4-perceptual abnormalities, P5-disorganized communication. The six negative symptoms are N1-social anhedonia, N2-avolition, N3-expression of emotion, N4-experience of emotion and self, N5-ideational richness, N6-occupational functioning. The subscale positive symptoms P1, P2, P3, P5 and the total scale positive symptoms were observed to significantly correlate with the prediction score though the Pearson correlation coefficient were relatively small. In addition, the subscale negative symptoms N1, N2, N3, N5, N6 and total scale negative symptoms were found to have a significant correlation with the prediction score in spite of small Pearson's correlation coefficients.

The proposed models (SE-VGG11-BN and dual stream SE-VGG11-BN) showcased superior performance over the benchmark model in terms of sensitivity, specificity, accuracy and AUROC on the independent testing dataset. It was also demonstrated that dual stream SE-VGG11-BN utilizing whole brain T1W structure scans and aCBV scans could outperform the SE-VGG11-BN only using whole brain TIW structure scans. Furthermore, the best-performing model, dual stream SE-VGG11-BN, was interpreted with gradient class activation maps to visualize the brain regions critical for classification. The some impactful regions for classification involved the temporal lobe, frontal lobe, ventricle area, and parietal-occipital lobe; these were in line with the findings in previous literature. Finally, the robustness and generality of the models was validated on a separate CHR dataset and found that the incorporation of aCBV drives prodromal schizophrenia classification ability in contrast to models using solely TIW structure scans.

Both SE-VGG-11BN and dual stream SE-VGG-11BN exhibited better performance than the benchmark model. Several factors may have contributed to this result. Firstly, in contrast to the benchmark model, the proposed model contains squeeze-and-excitation (SE) blocks, which can capture patterns across channels after each convolutional operation. Secondly, the input of the proposed model was only down-sampled by a factor of two as opposed to the benchmark model, which used a larger factor of eight. Severely down-sampling the data likely negatively impacted model performance as lower-resolution inputs may have lost important information relevant to schizophrenia classification. Thirdly, skull-stripping was applied as part of the data pre-processing pipeline for the SE-VGG-11BN and dual stream SE-VGG-11BN models given that the skull holds limited clinical correspondence to schizophrenia. The benchmark model used TIW WH scans, which may have confused the model with irrelevant features from the skull.

The dual stream SE-VGG11-BN integrating TIW structure data and synthesized functional aCBV data outperformed the SE-VGG11-BN only using TIW structure data across all metrics. The integrated features allow the model to better understand the neural substrates closely related to schizophrenia with complementary information mapping structural alterations to functional changes in cerebral blood volume. These improvements are achieved without compromising on data availability and practicality: aCBV functional mappings were artificially generated directly from TIW structure scans, meaning that this approach can be easily extended to other schizophrenia classification pipelines utilizing TIW structure scans. In addition to using two different inputs, dual stream SE-VGG11-BN has a complex topology that includes two information streams, where the functional and structural information is independently encoded. This approach allows for the effective extraction of relevant functional and structural features before merging both together.

### Example 15

### Interpretation of Gradient Class Activation Maps

The class activation map for the best-performing model (dual stream SE-VGG-11BN) reveals interesting patterns closely related to brain lobes. In the TIW structure stream, the temporal and frontal lobe provided many of the high-level feature information as depicted in the sub-stream. This result is consistent with previous studies which have indicated that temporal lobe and frontal lobe atrophy is one potential indicator of schizophrenia, and qualitative assessments of the regions may be used to monitor patients at risk of schizophrenia.

Additionally, it is notable that the hippocampus, found remarkably related to schizophrenia progression, is also included in the activation regions. Alternatively, in the functional aCBV stream, the parietal and occipital lobes were associated with activation for schizophrenia patients, which is consistent with findings such as decreased resting state neural activity in the parietal-occipital lobe. In addition, when the activation map from the T1W structure stream and that from the CBV functional stream are merged, this combined activation map closely overlaps with the default mode network of patients with schizophrenia characterized by hyperactivity in similar brain areas.

The classification of prodromal schizophrenia can be a difficult task as the neurological changes associated with it are subtle when compared to well-developed schizophrenia. Embodiments succeed in using deep learning for prodromal schizophrenia classification. Notably, the inclusion of aCBV mappings drives prodromal schizophrenia classification-models trained and tested using solely T1W structure scans could not perform adequately in contrast to models trained and tested using either aCBV mappings alone or aCBV mappings with T1W structure scans. CBV has been shown to capture distinct functional alterations in areas such as the hippocampus associated with prodromal schizophrenia that are not present within structural imaging. Therefore, while the inclusion of structure information can boost model performance, aCBV mappings also support the model performance by providing pertinent functional features.

1. A method for performing frequency and phase correction of magnetic resonance spectroscopy (MRS) data to quantify one or more metabolites, the method comprising:
receiving spectrum data related to a plurality of metabolites generated using magnetic resonance spectroscopy of a subject's brain;
generating corrected on-spectrum data and corrected off-spectrum data by inputting the received spectrum data to a trained machine learning model, wherein the trained machine learning model estimates frequency corrections and phase corrections for the input spectrum data; and
quantifying one or more of the metabolites according to the corrected on-spectrum data and corrected off-spectrum data.

2. The method of claim 1, wherein the trained machine learning model comprises a convolutional neural network with a plurality of convolutional layers.

3. The method of claim 1, wherein the trained machine learning model comprises a dual stream convolutional neural network.

4. The method of claim 3, wherein the dual stream convolutional neural network comprises a first stream for frequency correction and a second stream for phase correction.

5. The method of claim 4, wherein the first stream comprises a plurality of convolutional layers and the second stream comprises a plurality of convolutional layers.

6. The method of claim 4, wherein the first stream comprises a same architecture as the second stream.

7. The method of claim 4, wherein input to the first stream comprises magnitude spectrum data and input to the second stream comprises real spectrum data.

8. The method of claim 1, wherein the trained machine learning model comprises a transformer network with a plurality of multi-head attention blocks.

9. The method of claim 8, wherein the trained machine learning model comprises an encoder comprising a multi-head attention block and a decoder comprising at least two multi-head attention blocks.

10. The method of claim 1, wherein the received spectrum data comprises on-spectrum data and off-spectrum data.

11. The method of claim 10, wherein generating the corrected on-spectrum data and the corrected off-spectrum comprises:
applying the estimated frequency corrections to the received on-spectrum data and the received off-spectrum data; and
applying the estimated phase corrections to the received on-spectrum data and the received off-spectrum data.

12. The method of claim 11, wherein the estimated frequency corrections are applied to the received on-spectrum data and the received off-spectrum data, and the estimated phase corrections are applied to the on-spectrum data and the off-spectrum data with the applied frequency corrections.

13. The method of claim 1, wherein the received spectrum data comprises single voxel MEGA-PRESS MRS data.

14. The method of claim 1, wherein the quantified metabolite is quantified over at least a portion of the subject's brain.

15. The method of claim 1, wherein the quantified metabolite comprises GABA.

16. The method of claim 1, wherein the quantified metabolite comprises glutamate or glutamine.

17. The method of claim 16, wherein a therapeutic agent is administered to the subject based on the quantified glutamate or glutamine, wherein the therapeutic agent reduces, decreases or inhibit glutamate or glutamine.

18. The method of claim 1, wherein quantifying one or more of the metabolites according to the corrected on-spectrum data and corrected off-spectrum data comprises calculating a difference between the off-spectrum data and the on-spectrum data.

19. A system for performing frequency and phase correction of magnetic resonance spectroscopy (MRS) data to quantify one or more metabolites, the system comprising:
a processor; and
a memory storing instructions for execution by the processor, the instructions configuring the processor to:
receive spectrum data related to a plurality of metabolites generated using magnetic resonance spectroscopy of a subject's brain;
generate corrected on-spectrum data and corrected off-spectrum data by inputting the received spectrum data to a trained machine learning model, wherein the trained machine learning model estimates frequency corrections and phase corrections for the input spectrum data; and
quantify one or more of the metabolites according to the corrected on-spectrum data and corrected off-spectrum data.

20. (canceled)

21. A non-transitory computer readable medium having instructions stored thereon that, when executed by a processor, cause the processor to perform frequency and phase correction of magnetic resonance spectroscopy (MRS) data to quantify one or more metabolites, wherein, when executed, the instructions cause the processor to:
receive spectrum data related to a plurality of metabolites generated using magnetic resonance spectroscopy of a subject's brain;
generate corrected on-spectrum data and corrected off-spectrum data by inputting the received spectrum data to a trained machine learning model, wherein the trained machine learning model estimates frequency corrections and phase corrections for the input spectrum data; and
quantify one or more of the metabolites according to the corrected on-spectrum data and corrected off-spectrum data.

22-23. (canceled)
